(19) United States
(12) Patent Application Publication
(10) Pub. No.: US 2021/0328152 A1
(43) Pub. Date: Oct. 21, 2021

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Tae-Jin LEE, Gyeonggi-do (KR); Dong-Hyung LEE, Gyeonggi-do (KR); Bitnari KIM, Gyeonggi-do (KR); Hong-Se OH, Gyeonggi-do (KR); Hee-Ryong KANG, Gyeonggi-do (KR)

(21) Appl. No.: 16/492,647

(22) PCT Filed: Mar. 21, 2018
(86) PCT No.: PCT/KR2018/003245

§ 371 Date: Sep. 10, 2019

(30) Foreign Application Priority Data
Mar. 31, 2017 (KR) 10-2017-0042179
Mar. 14, 2018 (KR) 10-2018-0029725

(51) Int. Cl. H01L 51/00

(52) U.S. Cl. CPC H01L 51/0072; H01L 51/0067; H01L 51/0073; H01L 51/5004; H01L 51/006; H01L 51/0054; H01L 2251/552; H01L 51/0074

(57) ABSTRACT

The present disclosure relates to an organic electroluminescent device comprising a light-emitting layer and a hole transport zone. By the combination of the light-emitting layer comprising the compound according to the present disclosure and the hole transport zone comprising the compound having a specific HOMO energy level, the organic electroluminescent device having excellent luminous efficiency can be provided.

### TECHNICAL FIELD

The present disclosure relates to an organic electroluminescent device comprising a light-emitting layer and a hole transport zone.

### BACKGROUND ART

The first low molecular green organic electroluminescent device was developed by Tang, et al., of Eastman Kodak in 1987 by using TPD/ALq3 bi-layer consisting of a light-emitting layer and a charge transport layer. Thereafter, the development of organic electroluminescent devices was rapidly effected and the devices were currently commercialized. Current organic electroluminescent devices mostly use phosphorescent materials with excellent luminous efficiency for panel manufacture. For long-term use and high resolution of the display, a low driving voltage and high luminous efficiency are required.

Korean Patent Application Laid-Open No. 2015-0071685 discloses an organic electroluminescent device comprising a compound comprising a carbazole and a nitrogen-containing 10-membered hereroaryl, as a host. However, said reference does not specifically disclose a benzoindolocarbazole derivative, nor that the performance of an organic electroluminescent device can be improved by combining a host compound having a carbazole, and a specific material comprised in a hole transport zone.

### DISCLOSURE OF THE INVENTION

### Problems to be Solved

The objective of the present disclosure is to provide an organic electroluminescent device having excellent luminous efficiency while maintaining excellent lifespan and/or driving voltage characteristics, by combining a light-emitting layer comprising a compound of the present disclosure, and a hole transport zone comprising a compound having a specific HOMO (Highest Occupied Molecular Orbital) energy level.

### Solution to Problems

The conventional hole transport zone has limitations in improving the efficiency of a light-emitting layer. The hole transport zone requires a compound having a high HOMO energy level for fast hole mobility. If the compound has a high HOMO energy level, the driving voltage decreases, but the efficiency of a light-emitting layer also decreases. In contrast, if the compound has a low HOMO energy level, the efficiency of a light-emitting layer increases, but the driving voltage also increases, which makes it difficult to achieve a high luminous efficiency of a device.

As a result of studies on the improvement of luminous characteristic of an organic electroluminescent device comprising a compound represented by the following formula 1 in a light-emitting layer, the present inventors found that the combination with a hole transport zone comprising a compound having a specific HOMO energy level and/or an arylamine derivative containing a fluorene or a fused fluorene can solve the above problem.

Specifically, the above objective can be achieved by an organic electroluminescent device comprising a first electrode, a second electrode facing the first electrode, a light-emitting layer between the first electrode and the second electrode, and a hole transport zone between the first electrode and the light-emitting layer, wherein the light-emitting layer comprises a compound represented by the following formula 1:

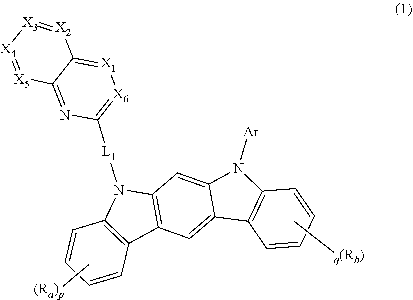

wherein,

L₁ represents a single bond, a substituted or unsubstituted (C6-C30)arylene, or a substituted or unsubstituted (5- to 30-membered)heteroarylene,

X₁ to X₆, each independently, represent N or CR_{c}, with a proviso that at least one of X₁ to X₆ represents N,

Ar represents a substituted or unsubstituted (C6-C30)aryl, or a substituted or unsubstituted (5- to 30-membered)heteroaryl,

Rₐ to R_{c}, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR_{f}R_{g}, —SiRₕRᵢRⱼ, —SRₖ, —ORₗ, a cyano, a nitro, or a hydroxyl, with a proviso that adjacent two Rₐ's or adjacent two R_{b}'s, each independently, are linked to each other for at least one pair of the adjacent two Rₐ's and the adjacent two R_{b}'s to form at least one substituted or unsubstituted benzene ring,

R_{f} to Rₗ, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (3- to 30-membered) alicyclic or aromatic ring, or a combination thereof, whose carbon atom(s) may be replaced with at least one heteroatom selected from nitrogen, oxygen, and sulfur,

p and q, each independently, represent an integer of 1 to 4, in which if p and q, each independently, are an integer of 2 or more, each of Rₐ and R_{b} may be the same or different, and

the heteroaryl(ene) or the heterocycloalkyl contains at least one heteroatom selected from B, N, O, S, Si, and P; and

the hole transport zone comprises an arylamine derivative containing a fluorene or a fused fluorene, and the HOMO energy level of the arylamine derivative satisfies the following equation 11:

−5.0 eV≤HOMO≤−4.65 eV (11).

### Effects of the Invention

The present disclosure provides an organic electroluminescent device having improved luminous efficiency, while maintaining excellent lifespan and/or driving voltage characteristics. The present disclosure also provides a display system or a lighting system using the same.

### EMBODIMENTS OF THE INVENTION

Hereinafter, the present disclosure will be described in detail. However, the following description is intended to explain the disclosure, and is not meant in any way to restrict the scope of the disclosure.

The organic electroluminescent device of the present disclosure may comprise a first electrode, a second electrode facing the first electrode, a light-emitting layer between the first electrode and the second electrode, a hole transport zone between the first electrode and the light-emitting layer, and an electron transport zone between the light-emitting layer and the second electrode. One of the first and second electrodes may be an anode, and the other may be a cathode.

The hole transport zone means an area in which holes move between the first electrode and the light-emitting layer, and may comprise, for example, at least one of a hole injection layer, a hole transport layer, a hole auxiliary layer, a light-emitting auxiliary layer, and an electron blocking layer. The hole injection layer, the hole transport layer, the hole auxiliary layer, the light-emitting auxiliary layer, and the electron blocking layer may be, respectively, a single layer or a multi-layer in which two or more layers are stacked. According to one embodiment of the present disclosure, the hole transport zone may comprise a first hole transport layer and a second hole transport layer. The second hole transport layer may be at least one layer of a plurality of hole transport layers, and may comprise at least one of a hole auxiliary layer, a light-emitting auxiliary layer, and an electron blocking layer. According to another embodiment of the present disclosure, the hole transport zone comprises a first hole transport layer and a second hole transport layer, in which the first hole transport layer may be placed between the first electrode and the light-emitting layer, the second hole transport layer may be placed between the first hole transport layer and the light-emitting layer, and the second hole transport layer may play a role as a hole transport layer, a light-emitting auxiliary layer, a hole auxiliary layer and/or an electron blocking layer.

The hole transport layer may be placed between the anode (or the hole injection layer) and the light-emitting layer, enables holes transferred from the anode to smoothly move to the light-emitting layer, and may block the electrons transferred from the cathode to confine electrons within the light-emitting layer. The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or hole transport, or for preventing the overflow of electrons. When the light-emitting auxiliary layer is placed between the cathode and the light-emitting layer, it can be used for promoting the electron injection and/or electron transport, or for preventing the overflow of holes. Also, the hole auxiliary layer may be placed between the hole transport layer (or hole injection layer) and the light-emitting layer, and may be effective to promote or block the hole transport rate (or hole injection rate), thereby enabling the charge balance to be controlled. Further, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. When an organic electroluminescent device includes two or more hole transport layers, the hole transport layer, which is further included, may be used as a hole auxiliary layer or an electron blocking layer. The light-emitting auxiliary layer, the hole auxiliary layer and/or the electron blocking layer may have an effect of improving the efficiency and/or the lifespan of the organic electroluminescent device.

The electron transport zone may comprise at least one of an electron buffer layer, a hole blocking layer, an electron transport layer, and an electron injection layer, preferably at least one of an electron transport layer and an electron injection layer. The electron buffer layer is a layer capable of improving the problem that the current characteristics in the device changes upon exposure to a high temperature in a panel fabrication process to cause deformation of light emission luminance, which can control the flow of charge.

The light-emitting layer emits light, and may be a single layer, or a plurality of layers in which two or more layers are stacked. The doping concentration of the dopant compound with respect to the host compound in the light-emitting layer is preferably less than 20 wt %.

The organic electroluminescent device according to the present disclosure comprises the compound represented by formula 1 in the light-emitting layer.

Hereinafter, the compound represented by formula 1 will be described in more detail.

In formula 1, L₁ represents a single bond, a substituted or unsubstituted (C6-C30)arylene, or a substituted or unsubstituted (5- to 30-membered)heteroarylene; preferably, a single bond, a substituted or unsubstituted (C6-C25)arylene, or a substituted or unsubstituted (5- to 25-membered)heteroarylene; more preferably, a single bond, a substituted or unsubstituted (C6-C18)arylene, or a substituted or unsubstituted (5- to 18-membered)heteroarylene; and, for example, a single bond, an unsubstituted phenylene, an unsubstituted naphthylene, or an unsubstituted pyridinylene.

In formula 1, X₁ to X₆, each independently, represent N or CR_{c}, with a proviso that at least one of X₁ to X₆ represents N. According to one embodiment of the present disclosure, at least one of X₁ and X₆ may represent N, and X₂ to X₅ may represent CR_{c}.

In formula 1, the structure of

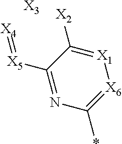

may represent a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl; preferably, a substituted or unsubstituted quinoxalinyl, or a substituted or unsubstituted quinazolinyl, and wherein, * represents a bonding site with L₁.

In formula 1, Ar represents a substituted or unsubstituted (C6-C30)aryl, or a substituted or unsubstituted (5- to 30-membered)heteroaryl; preferably, a substituted or unsubstituted (C6-C25)aryl, or a substituted or unsubstituted (5- to 25-membered)heteroaryl; more preferably, a substituted or unsubstituted (C6-C18)aryl, or a substituted or unsubstituted (5- to 18-membered)heteroaryl; and for example, an unsubstituted phenyl, an unsubstituted naphthyl, an unsubstituted biphenyl, a fluorenyl substituted with a dimethyl, an unsubstituted phenanthrenyl, or an unsubstituted pyridinyl.

In formula 1, Rₐ to R_{c}, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR_{f}R_{g}, —SiRₕRᵢRⱼ, —SRₖ, —ORₗ, a cyano, a nitro, or a hydroxyl; preferably, hydrogen, or a substituted or unsubstituted (C6-C25)aryl; and more preferably, hydrogen, or a substituted or unsubstituted (C6-C18)aryl. According to one embodiment of the present disclosure, Rₐ and R_{b}, each independently, may represent hydrogen, or an unsubstituted phenyl, and Rₑ may represent hydrogen, a phenyl unsubstituted or substituted with at least one methyl, an unsubstituted naphthyl, an unsubstituted biphenyl, an unsubstituted naphthylphenyl, a fluorenyl substituted with a dimethyl, or an unsubstituted phenanthrenyl. However, adjacent two Rₐ's or adjacent two R_{b}'s, each independently, are linked to each other for at least one pair of the adjacent two Rₐ's and the adjacent two R_{b}'s to form at least one substituted or unsubstituted benzene ring. For example, the number of the at least one substituted or unsubstituted benzene ring may be 1 to 6. Also, the adjacent two Rₐ's or the adjacent two R_{b}'s, each independently, are linked to each other to form a substituted or unsubstituted benzene ring, and preferably, an unsubstituted benzene ring. When X₁ or X₆ represents CR_{c}, Rₑ may represent a substituted or unsubstituted (C6-C18)aryl. Also, when X₂ to X₅ represent CR_{c}, Rₑ may represent hydrogen. R_{f} to Rₗ, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (3- to 30-membered) alicyclic or aromatic ring, or a combination thereof, whose carbon atom(s) may be replaced with at least one heteroatom selected from nitrogen, oxygen, and sulfur.

In formula 1, p and q, each independently, represent an integer of 1 to 4, and preferably an integer of 1 to 3. If p and q, each independently, are an integer of 2 or more, each of Rₐ and R_{b} may be the same or different.

Formula 1 may be represented by any one of the following formulas 2 to 7:

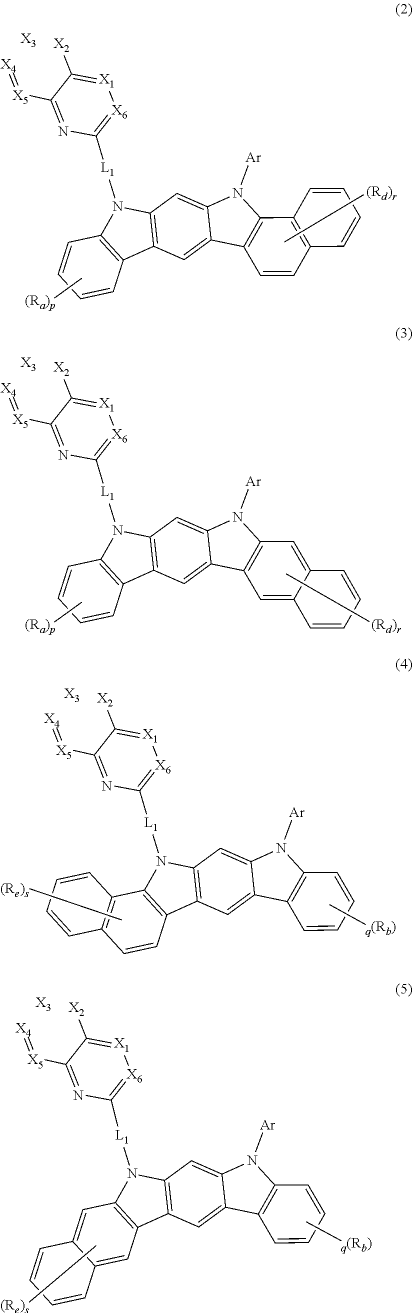

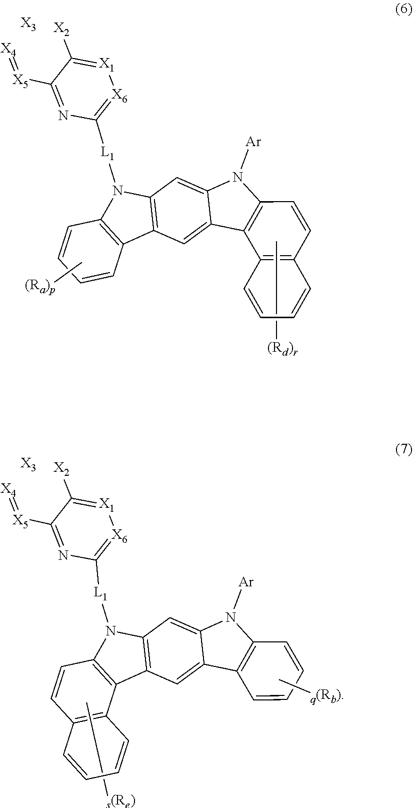

In formulas 2 to 7, L₁, Ar, Rₐ, R_{b}, X₁ to X₆, p, and q are as defined in formula 1; and Rd and Re are, each independently, identical to the definition of Rₐ.

In formulas 2 to 7, r and s, each independently, represent an integer of 1 to 6. If r and s are, each independently, an integer of 2 or more, each of Rd and Re may be the same or different.

According to one embodiment of the present disclosure, the arylamine derivative comprised in the hole transport zone, preferably the second hole transport layer, for example, at least one of the light-emitting auxiliary layer and the hole auxiliary layer may comprise the compound represented by the following formula 11:

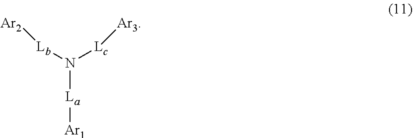

In formula 11, Ar₁ to Ar₃, each independently, represent a substituted or unsubstituted (C6-C30)aryl, or a substituted or unsubstituted (5- to 30-membered)heteroaryl; preferably, a substituted or unsubstituted (C6-C25)aryl, or a substituted or unsubstituted (5- to 25-membered)heteroaryl; and more preferably, an unsubstituted (C6-C18)aryl, or an unsubstituted (5- to 18-membered)heteroaryl. According to one embodiment of the present disclosure, Ar₁ to Ar₃, each independently, may represent a phenyl, a naphthyl, a biphenyl, a phenanthrenyl, a terphenyl, or a benzonaphthofuranyl. However, at least one of Ar₁ to Ar₃ is selected from the following formulas:

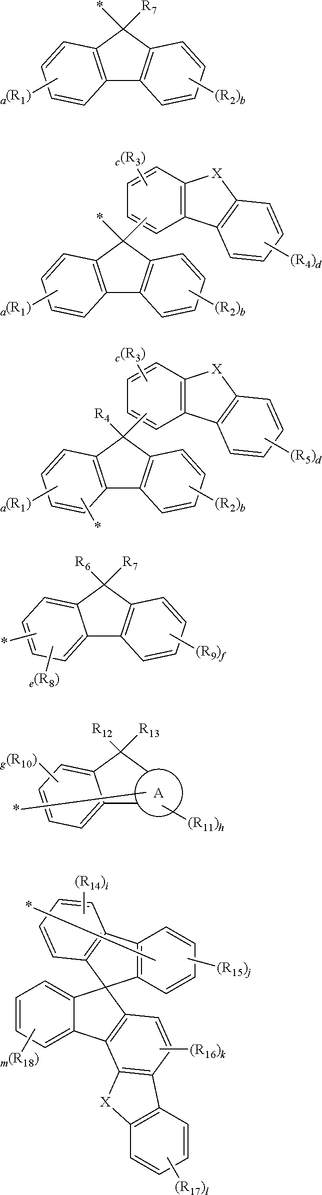

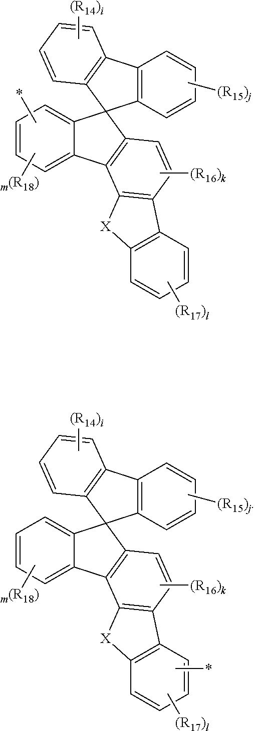

In formula 11, Lₐ to L_{c}, each independently, represent a single bond, or a substituted or unsubstituted (C6-C30)arylene; preferably, a single bond, or a substituted or unsubstituted (C6-C25)arylene; and more preferably, a single bond, or a (C6-C18)arylene unsubstituted or substituted with a di(C6-C18)arylamino. According to one embodiment of the present disclosure, Lₐ to L_{c}, each independently, represent a single bond, a phenylene unsubstituted or substituted with a diphenylamino, or an unsubstituted biphenylene.

In the above formulas, X represents O, S, or CR₁₉R₂₀.

In the above formulas, the A ring represents a substituted or unsubstituted C10 aryl, preferably an unsubstituted C10 aryl. According to one embodiment of the present disclosure, the A ring may represent a naphthalene ring.

In the above formulas, R₁ to R₂₀, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₂₁R₂₂, —SiR₂₃R₂₄R₂₅, —SR₂₆, —OR₂₇, a cyano, a nitro, or a hydroxyl; or may be linked to an adjacent substituent to form a substituted or unsubstituted, mono- or polycyclic, (3- to 30-membered) alicyclic or aromatic ring, or a combination thereof, in which the ring may include a spiro structure, and carbon atom(s) of the formed ring may be replaced with at least one heteroatom selected from nitrogen, oxygen, and sulfur. Preferably, R₁ to R₂₀, each independently, represent hydrogen, a substituted or unsubstituted (C1-C20)alkyl, a substituted or unsubstituted (C6-C25)aryl, a substituted or unsubstituted (5- to 25-membered)heteroaryl, or —NR₂₁R₂₂; or may be linked to an adjacent substituent to form a substituted or unsubstituted, mono- or polycyclic, (3- to 25-membered) alicyclic or aromatic ring, or a combination thereof, in which the ring may include a spiro structure, and carbon atom(s) of the formed ring may be replaced with at least one heteroatom selected from nitrogen, oxygen, and sulfur. More preferably, R₁ to R₂₀, each independently, represent hydrogen, an unsubstituted (C1-C10)alkyl, a (C6-C18)aryl unsubstituted or substituted with a di(C6-C18)arylamino, or —NR₂₁R₂₂; or may be linked to an adjacent substituent to form an unsubstituted, mono- or polycyclic, (3- to 18-membered) alicyclic or aromatic ring, or a combination thereof, in which the ring may include a spiro structure. According to one embodiment of the present disclosure, R₁ to R₂₀ may represent hydrogen; adjacent two R₂'s may be linked to each other to form a substituted or unsubstituted benzene ring; R₄ and R₁₀, each independently, may represent a biphenyl; R₈ may represent a phenyl substituted with a diphenylamino; R₆ and R₇, each independently, may represent a methyl, a phenyl, or a triphenylenyl, and may be the same or different; R₁₂ and R₁₃, each independently, may represent a methyl, and may be the same or different; R₁ and R₂₀, each independently, represent a methyl or a phenyl, and may be the same or different; R₆ and R₇, or R₁₂ and R₁₃ may be linked to each other to form a spiro structure, for example, a spiro[fluorene-fluorene] or spiro[fluorene-benzofluorene]structure.

In the above formulas, R₂₁ to R₂₇, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (3- to 30-membered) alicyclic or aromatic ring, or a combination thereof, whose carbon atom(s) may be replaced with at least one heteroatom selected from nitrogen, oxygen, and sulfur. Preferably, R₂₁ to R₂₇, each independently, may represent hydrogen, a substituted or unsubstituted (C6-C25)aryl, or a substituted or unsubstituted (5- to 25-membered)heteroaryl, more preferably, a (C6-C18)aryl unsubstituted or substituted with a (C1-C10)alkyl. According to one embodiment of the present disclosure, R₂₁ and R₂₂, each independently, may represent a phenyl, a naphthylphenyl, a biphenyl, or a dimethylfluorenyl.

In the above formulas, a, b, d, f, g, i, j, I, and m, each independently, represent an integer of 1 to 4; c and e, each independently, represent an integer of 1 to 3; h represents an integer of 1 to 6; and k represents 1 or 2. If a to m, each independently, are an integer of 2 or more, each of R₁ to R₁₇ may be the same or different. Preferably, a to m, each independently, are 1 or 2.

The heteroaryl(ene) or the heterocycloalkyl contains at least one heteroatom selected from B, N, O, S, Si, and P; and preferably, at least one heteroatom selected from N, O, and S.

Formula 11 may be represented by any one of the following formulas 12 to 18:

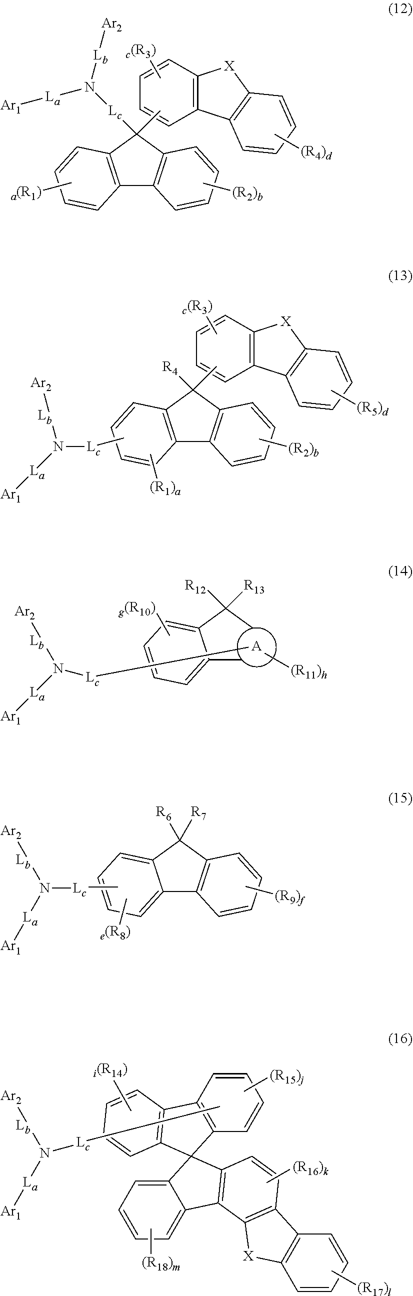

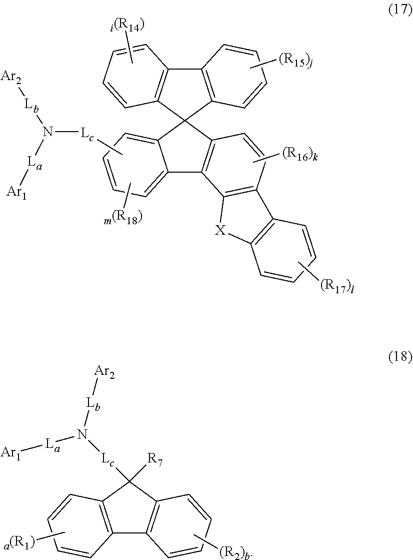

In formulas 12 to 18, R₁ to R₁₇, a to m, Lₐ to L_{c}, Ar₁, and Ar₂ are as defined in formula 11.

Herein, “(C1-C30)alkyl” is meant to be a linear or branched alkyl having 1 to 30 carbon atoms constituting the chain, in which the number of carbon atoms is preferably 1 to 20, more preferably 1 to 10, and includes methyl, ethyl, n-propyl, isopropyl, n-butyl, isobutyl, tert-butyl, etc. “(C2-C30)alkenyl” is meant to be a linear or branched alkenyl having 2 to 30 carbon atoms constituting the chain, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc. “(C2-C30)alkynyl” is meant to be a linear or branched alkynyl having 2 to 30 carbon atoms constituting the chain, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc. “(C3-C30)cycloalkyl” is meant to be a mono- or polycyclic hydrocarbon having 3 to 30 ring backbone carbon atoms, in which the number of carbon atoms is preferably 3 to 20, more preferably 3 to 7, and includes cyclopropyl, cyclobutyl, cyclopentyl, cyclohexyl, etc. “(3- to 7-membered)heterocycloalkyl” is meant to be a cycloalkyl having at least one heteroatom selected from the group consisting of B, N, O, S, Si, and P, preferably selected from the group consisting of O, S, and N, and 3 to 7 ring backbone atoms, preferably 5 to 7 ring backbone atoms, and includes tetrahydrofuran, pyrrolidine, thiolan, tetrahydropyran, etc. “(C6-C30)aryl(ene)” is meant to be a monocyclic or fused ring radical derived from an aromatic hydrocarbon having 6 to 30 ring backbone carbon atoms and may be partially saturated, in which the number of ring backbone carbon atoms is preferably 6 to 25, more preferably 6 to 18, may include a spiro structure, and includes phenyl, biphenyl, terphenyl, naphthyl, binaphthyl, phenylnaphthyl, naphthylphenyl, phenylterphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, etc. “(5- to 30-membered)heteroaryl(ene)” is meant to be an aryl group having at least one, preferably 1 to 4 heteroatoms selected from the group consisting of B, N, O, S, Si, and P, and 5 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); may include a spiro structure; and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzimidazolyl, benzothiazolyl, benzoisothiazolyl, benzoisoxazolyl, benzoxazolyl, isoindolyl, indolyl, benzoindolyl, indazolyl, benzothiadiazolyl, quinolyl, isoquinolyl, cinnolinyl, quinazolinyl, benzoquinazolinyl, quinoxalinyl, benzoquinoxalinyl, naphthyridinyl, carbazolyl, benzocarbazolyl, dibenzocarbazolyl, phenoxazinyl, phenothiazinyl, phenanthridinyl, benzodioxolyl, dihydroacridinyl, etc. “Halogen” includes F, Cl, Br, and I.

Herein, “substituted” in the expression “substituted or unsubstituted” means that a hydrogen atom in a certain functional group is replaced with another atom or another functional group, i.e. a substituent. Substituents of the substituted alkyl, the substituted aryl(ene), the substituted heteroaryl(ene), the substituted cycloalkyl, the substituted heterocycloalkyl, the substituted arylalkyl, the substituted benzene ring, and the substituted mono- or polycyclic, alicyclic or aromatic ring, or a combination thereof in L₁, Ar, Rₐ to R_{c}, R_{f} to Rₗ, Ar to Ar₃, Lₐ to L_{c}, A ring, and R₁ to R₂₇ of formulas 1 and 11, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3-to 7-membered)heterocycloalkyl; a (C6-C30)aryloxy; a (C6-C30)arylthio; a (5- to 30-membered)heteroaryl unsubstituted or substituted with a (C6-C30)aryl; a (C6-C30)aryl unsubstituted or substituted with a (5- to 30-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino unsubstituted or substituted with a (C1-C30)alkyl; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. Preferably, the substituents may be at least one selected from the group consisting of a (C1-C20)alkyl; an unsubstituted (5- to 25-membered)heteroaryl; an unsubstituted (C6-C25)aryl; an amino; a mono- or di-(C1-C20)alkylamino; an unsubstituted mono- or di-(C6-C25)arylamino; a (C1-C20)alkyl(C6-C25)arylamino; a (C6-C25)aryl(C1-C20)alkyl; and a (C1-C20)alkyl(C6-C25)aryl. More preferably, the substitutents may be may be at least one selected from the group consisting of a (C1-C10)alkyl, a (C6-C18)aryl, and a di(C6-C18)arylamino. For example, the substituents may be at least one selected from the group consisting of a methyl, a naphthyl, and a diphenylamino.

The compound represented by formula 1 may be at least one selected from the following compounds, but is not limited thereto.

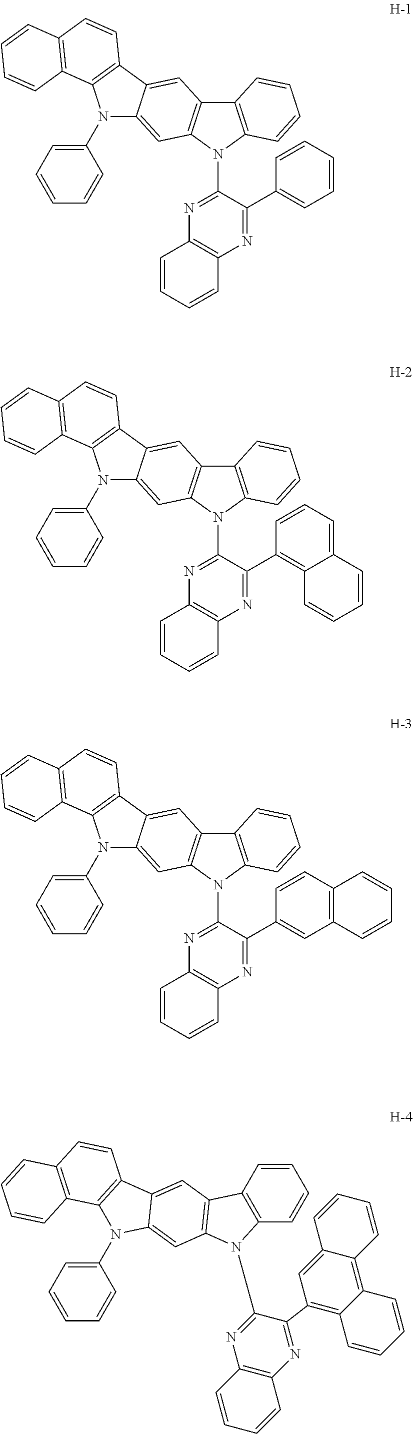 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

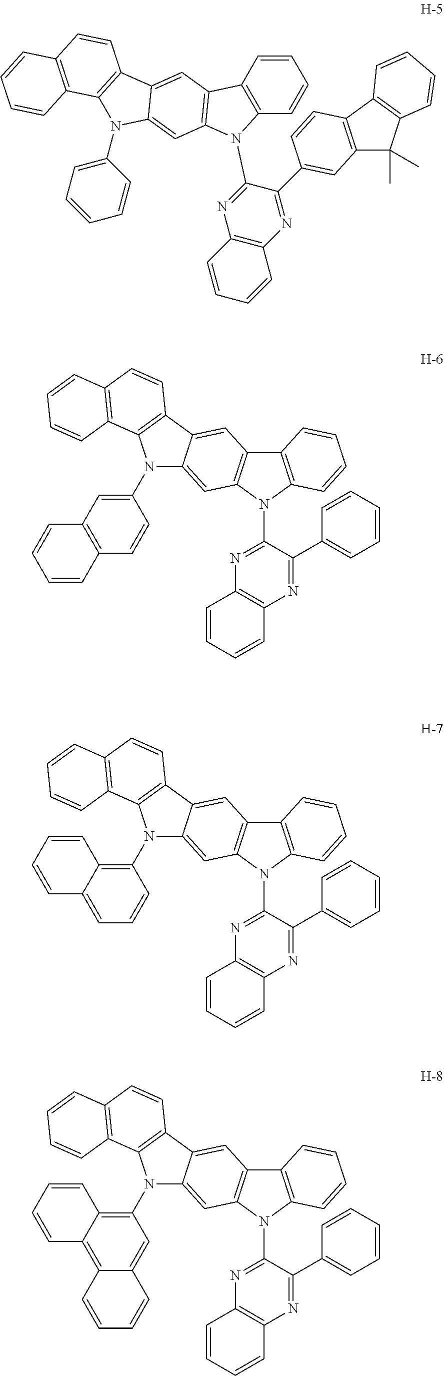 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

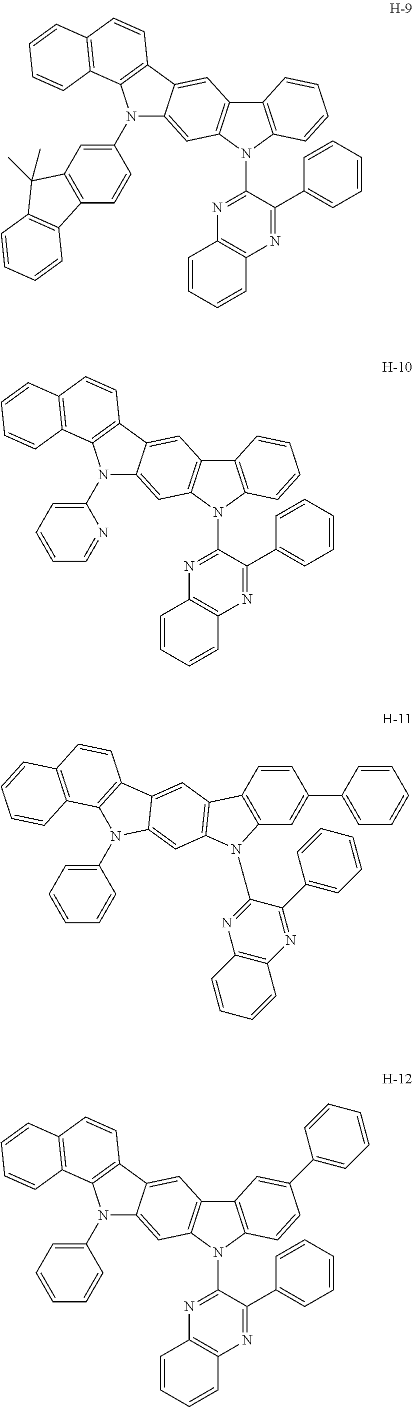 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccc5)c4cc2n3-c2nc3ccccc3nc2-c2ccccc2)cc1]

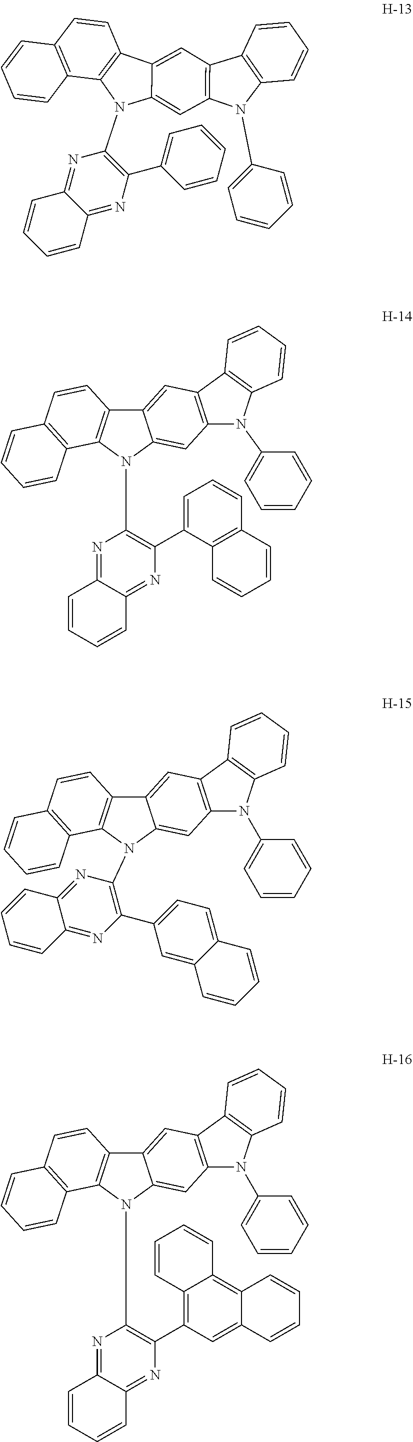 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

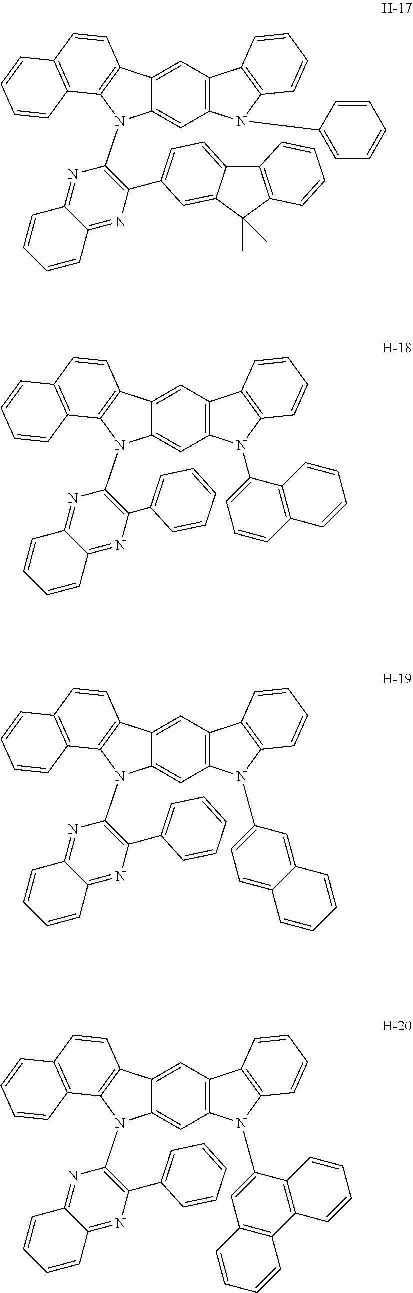 [SMILES: CC1(C)c2ccccc2-c2ccc(-c3nc4ccccc4nc3-n3c4cc5c(cc4c4ccc6ccccc6c43)c3ccccc3n5-c3ccccc3)cc21 ; c1ccc(-c2nc3ccccc3nc2-n2c3cc4c(cc3c3ccc5ccccc5c32)c2ccccc2n4-c2cccc3ccccc23)cc1 ; c1ccc(-c2nc3ccccc3nc2-n2c3cc4c(cc3c3ccc5ccccc5c32)c2ccccc2n4-c2ccc3ccccc3c2)cc1 ; c1ccc(-c2nc3ccccc3nc2-n2c3cc4c(cc3c3ccc5ccccc5c32)c2ccccc2n4-c2cc3ccccc3c3ccccc23)cc1]

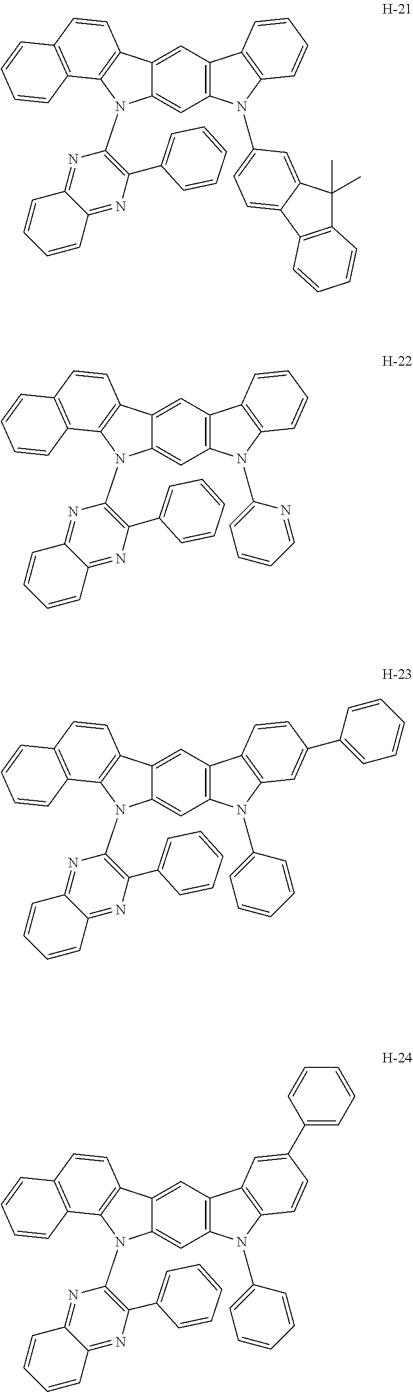 [SMILES: CC1(C)c2ccccc2-c2ccc(-n3c4ccccc4c4cc5c6ccc7ccccc7c6n(-c6nc7ccccc7nc6-c6ccccc6)c5cc43)cc21 ; c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1]

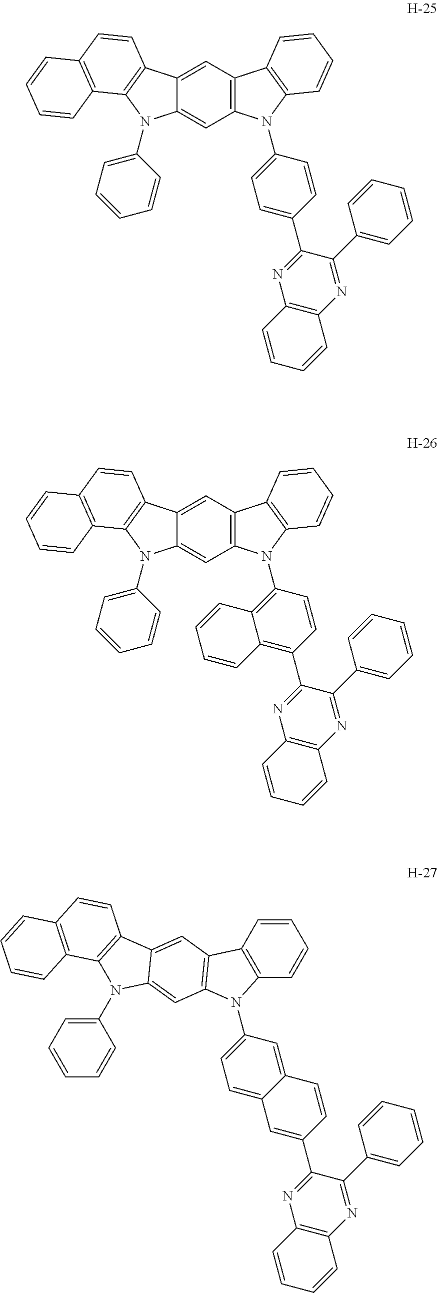 [SMILES: c1ccc(-c2nc3ccccc3nc2-c2ccc(-n3c4ccccc4c4cc5c6ccc7ccccc7c6n(-c6ccccc6)c5cc43)cc2)cc1 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1]

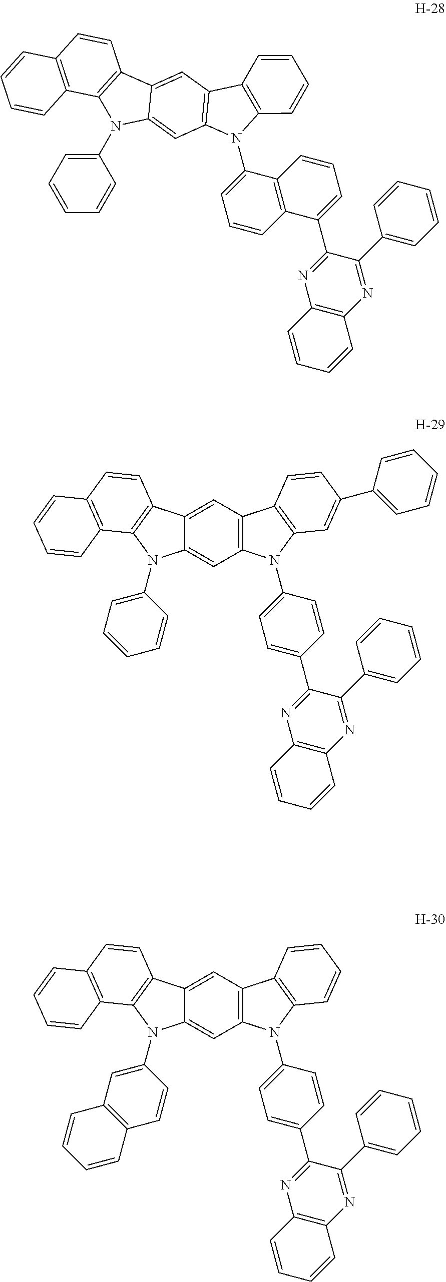 [SMILES: c1ccc(-c2nc3ccccc3nc2-c2cccc3c(-n4c5ccccc5c5cc6c7ccc8ccccc8c7n(-c7ccccc7)c6cc54)cccc23)cc1 ; c1ccc(-c2ccc3c4cc5c6ccc7ccccc7c6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6ccc7ccccc7c6n(-c6ccc7ccccc7c6)c5cc43)cc2)cc1]

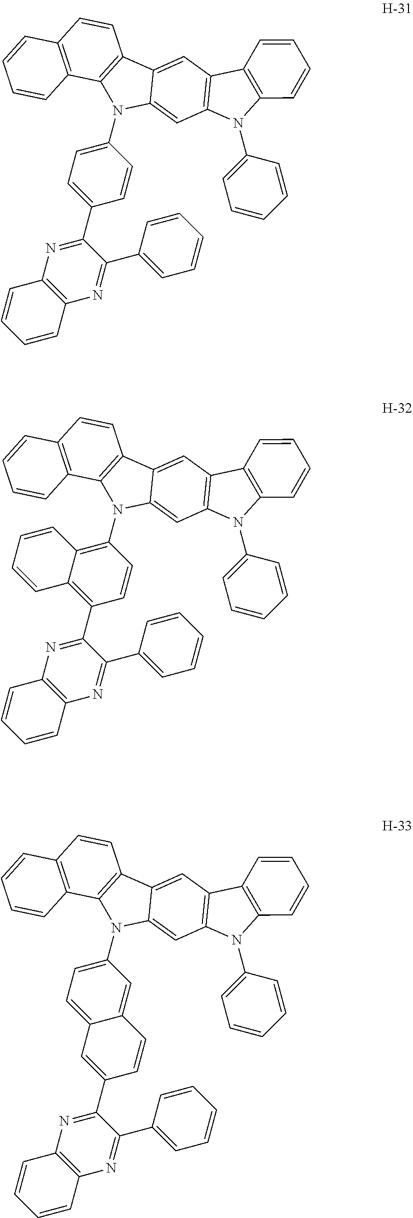 [SMILES: c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-c2ccc(-n3c4cc5c(cc4c4ccc6ccccc6c43)c3ccccc3n5-c3ccccc3)c3ccccc23)cc1 ; c1ccc(-c2nc3ccccc3nc2-c2ccc3cc(-n4c5cc6c(cc5c5ccc7ccccc7c54)c4ccccc4n6-c4ccccc4)ccc3c2)cc1]

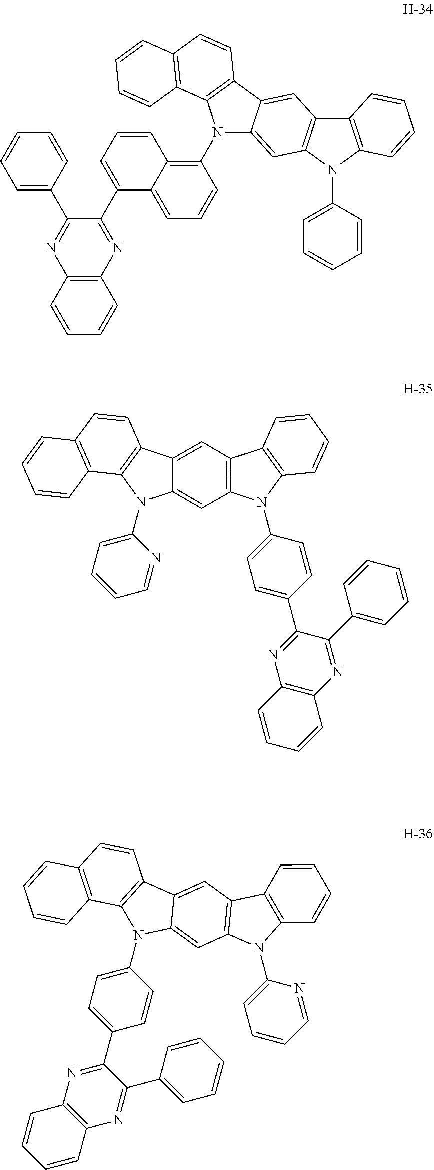 [SMILES: c1ccc(-c2nc3ccccc3nc2-c2cccc3c(-n4c5cc6c(cc5c5ccc7ccccc7c54)c4ccccc4n6-c4ccccc4)cccc23)cc1 ; c1ccc(-c2nc3ccccc3nc2-c2ccc(-n3c4ccccc4c4cc5c6ccc7ccccc7c6n(-c6ccccn6)c5cc43)cc2)cc1 ; c1ccc(-c2nc3ccccc3nc2-c2ccc(-n3c4cc5c(cc4c4ccc6ccccc6c43)c3ccccc3n5-c3ccccn3)cc2)cc1]

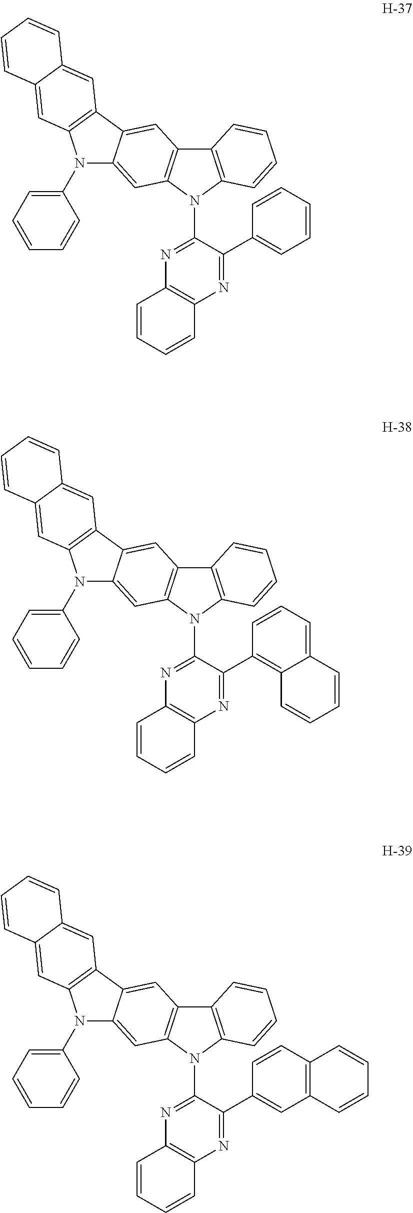 [SMILES: c1ccc(-c2nc3ccccc3nc2-n2c3ccccc3c3cc4c5cc6ccccc6cc5n(-c5ccccc5)c4cc32)cc1 ; c1ccc(-n2c3cc4ccccc4cc3c3cc4c5ccccc5n(-c5nc6ccccc6nc5-c5cccc6ccccc56)c4cc32)cc1 ; c1ccc(-n2c3cc4ccccc4cc3c3cc4c5ccccc5n(-c5nc6ccccc6nc5-c5ccc6ccccc6c5)c4cc32)cc1]

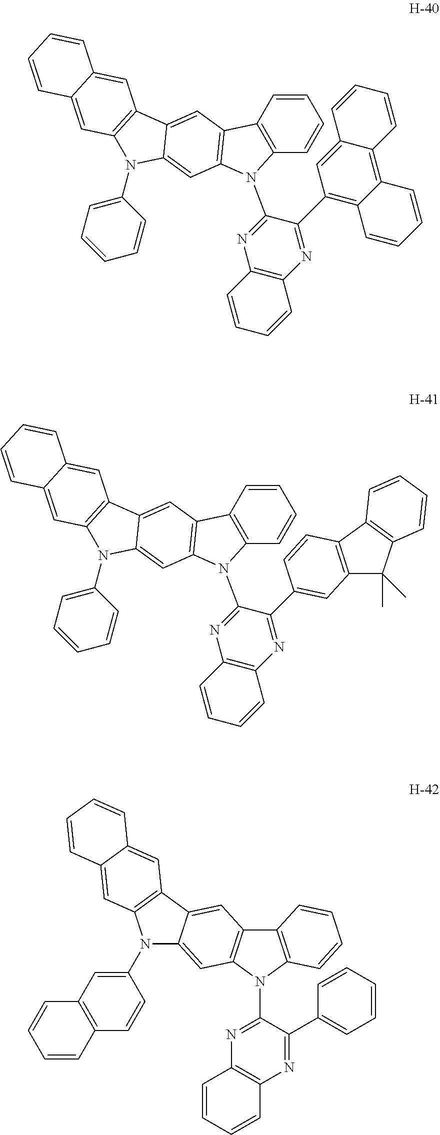 [SMILES: c1ccc(-n2c3cc4ccccc4cc3c3cc4c5ccccc5n(-c5nc6ccccc6nc5-c5cc6ccccc6c6ccccc56)c4cc32)cc1 ; CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1]

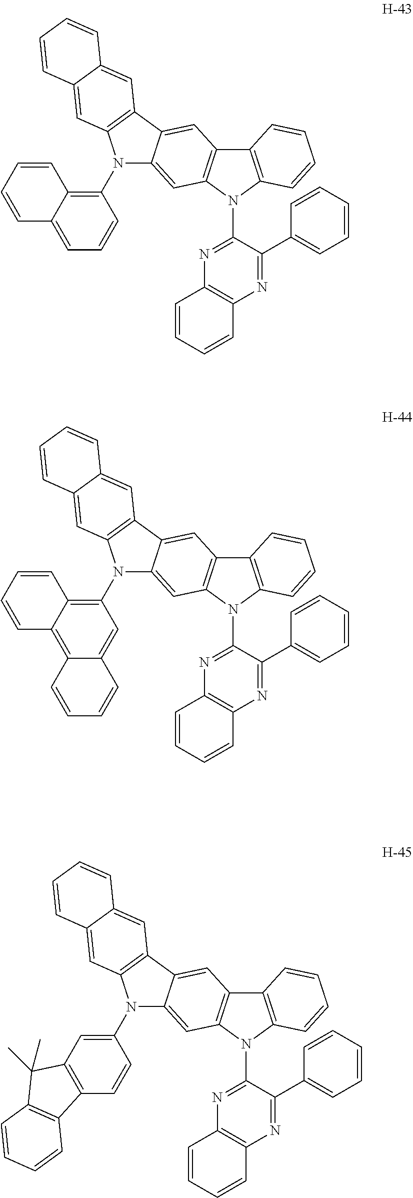 [SMILES: c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1 ; CC1(C)c2ccccc2-c2ccc(-n3c4cc5ccccc5cc4c4cc5c6ccccc6n(-c6nc7ccccc7nc6-c6ccccc6)c5cc43)cc21]

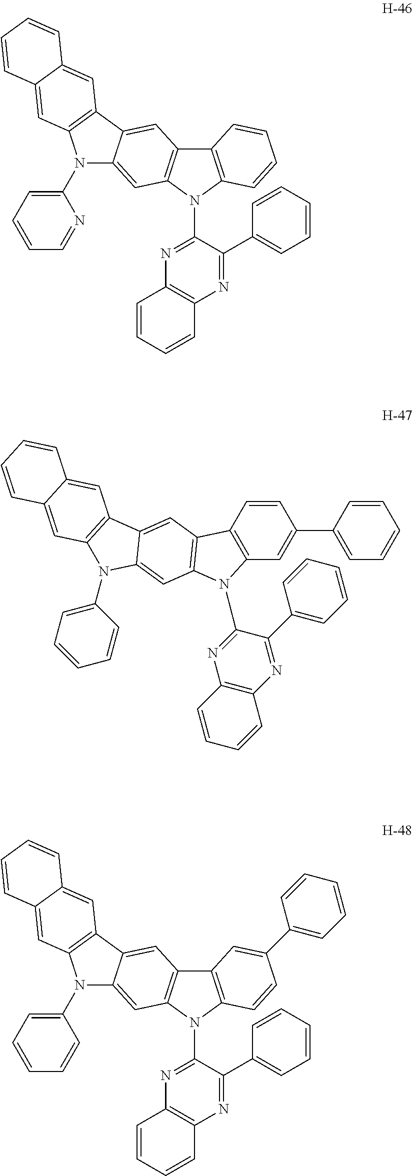 [SMILES: c1ccc(-c2nc3ccccc3nc2-n2c3ccccc3c3cc4c5cc6ccccc6cc5n(-c5ccccn5)c4cc32)cc1 ; c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1]

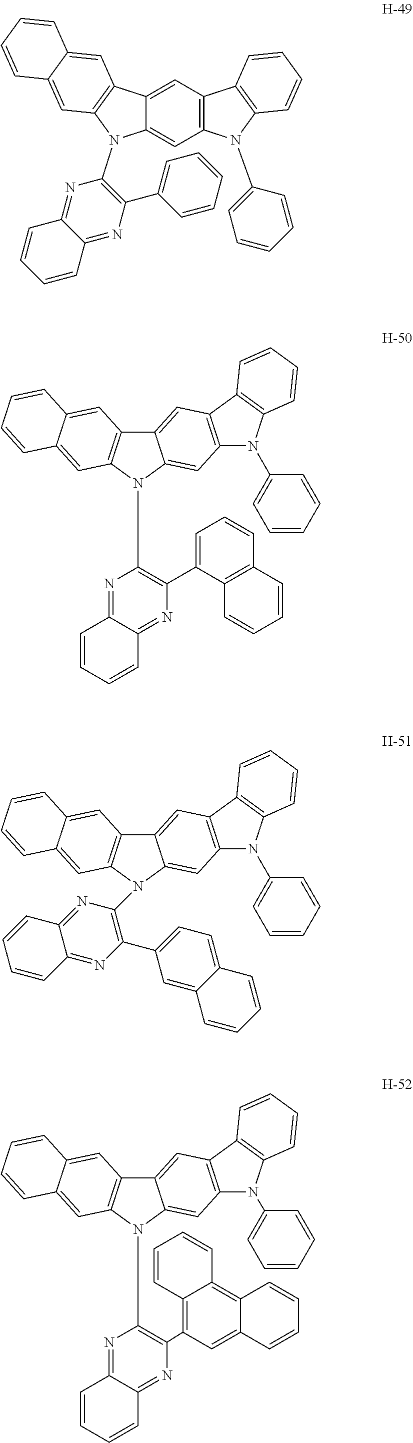 [SMILES: c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1 ; c1ccc(-n2c3ccccc3c3cc4c5cc6ccccc6cc5n(-c5nc6ccccc6nc5-c5ccc6ccccc6c5)c4cc32)cc1 ; c1ccc(-n2c3ccccc3c3cc4c5cc6ccccc6cc5n(-c5nc6ccccc6nc5-c5cc6ccccc6c6ccccc56)c4cc32)cc1]

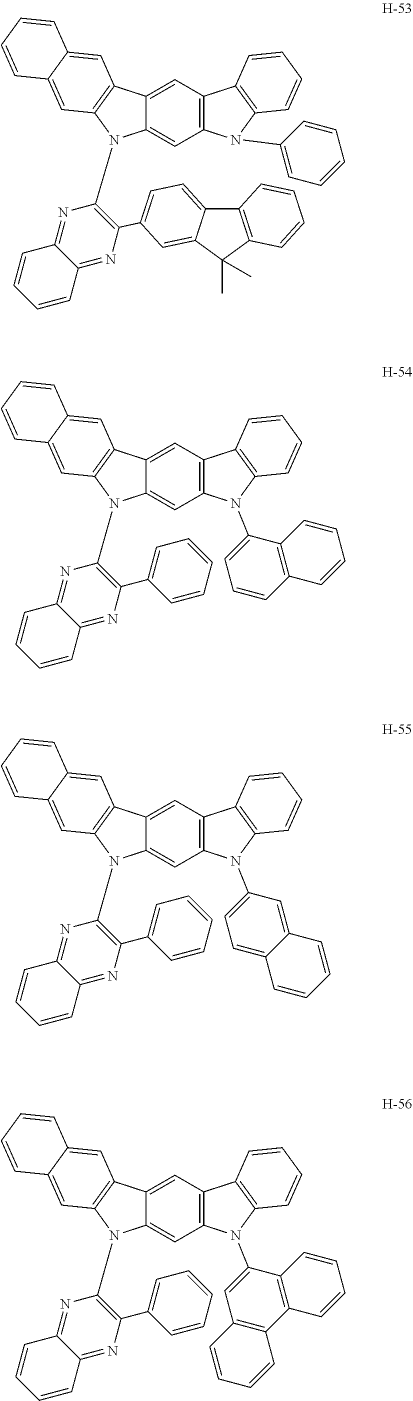 [SMILES: CC1(C)c2ccccc2-c2ccc(-c3nc4ccccc4nc3-n3c4cc5ccccc5cc4c4cc5c6ccccc6n(-c6ccccc6)c5cc43)cc21 ; c1ccc(-c2nc3ccccc3nc2-n2c3cc4ccccc4cc3c3cc4c5ccccc5n(-c5cccc6ccccc56)c4cc32)cc1 ; c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1]

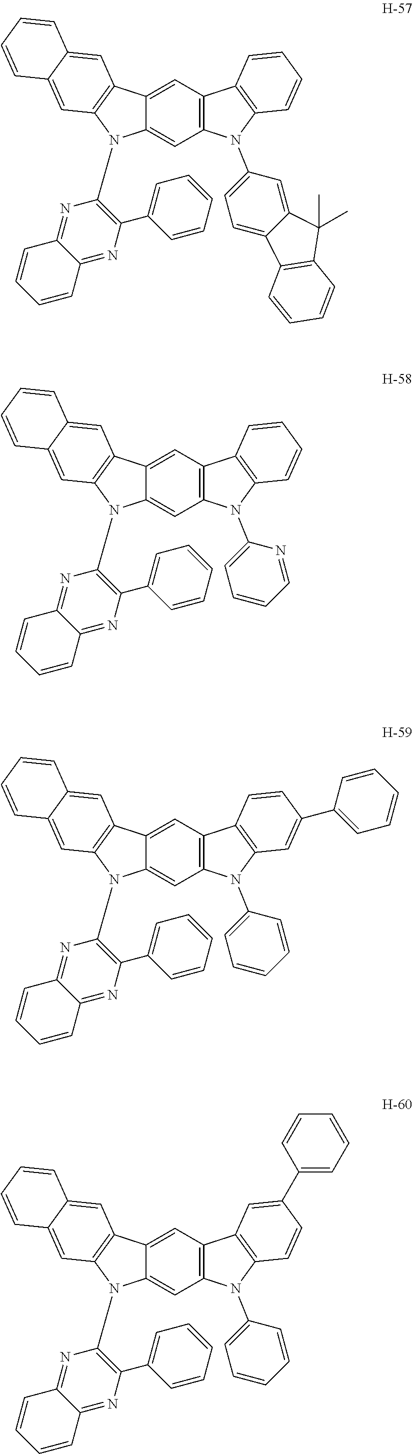 [SMILES: CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1 ; c1ccc(-c2ccc3c4cc5c6cc7ccccc7cc6n(-c6nc7ccccc7nc6-c6ccccc6)c5cc4n(-c4ccccc4)c3c2)cc1 ; c1ccc(-c2ccc3c(c2)c2cc4c5cc6ccccc6cc5n(-c5nc6ccccc6nc5-c5ccccc5)c4cc2n3-c2ccccc2)cc1]

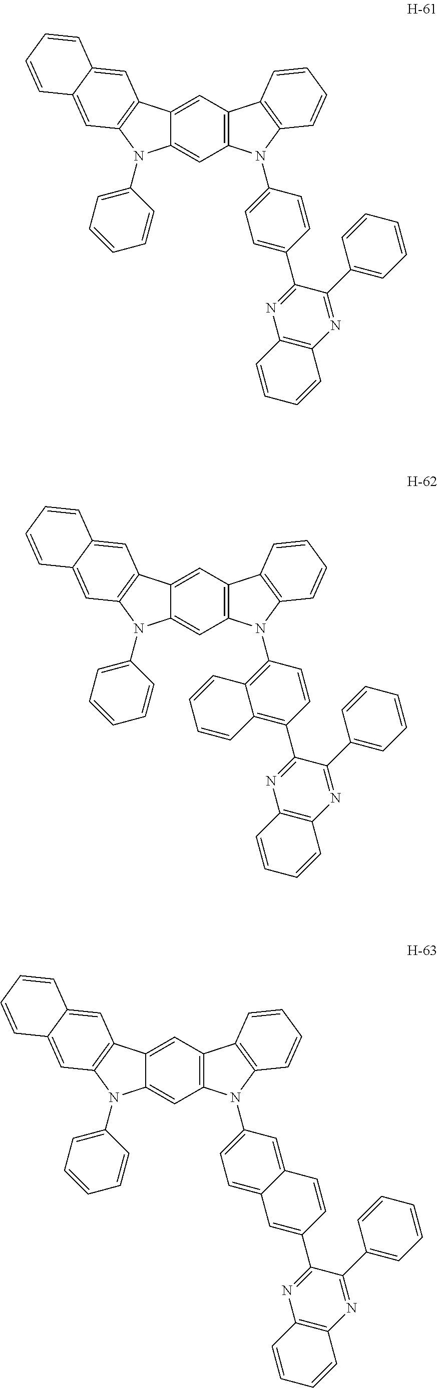 [SMILES: c1ccc(-c2nc3ccccc3nc2-c2ccc(-n3c4ccccc4c4cc5c6cc7ccccc7cc6n(-c6ccccc6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1]

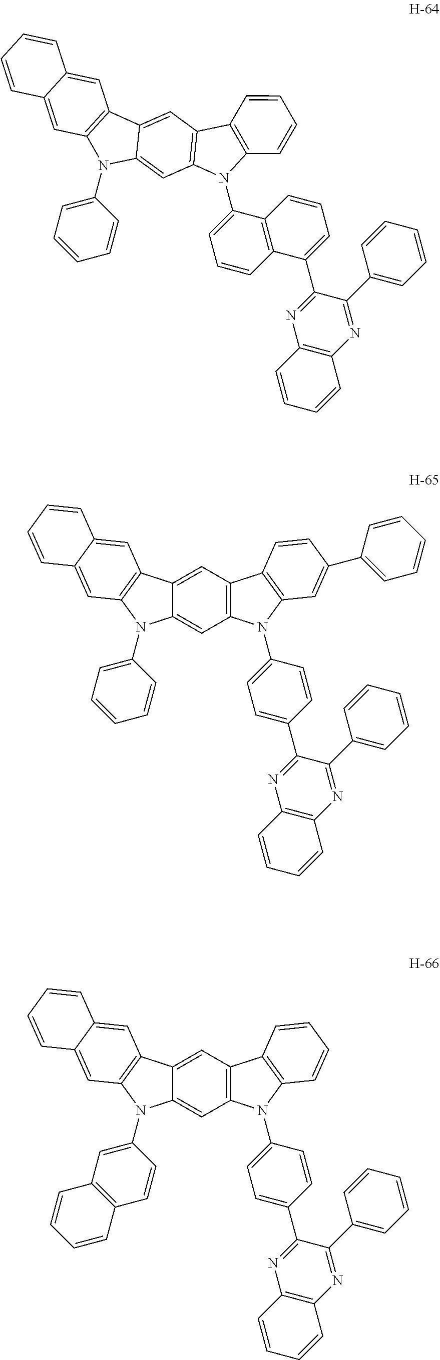 [SMILES: c1ccc(-c2nc3ccccc3nc2-c2cccc3c(-n4c5ccccc5c5cc6c7cc8ccccc8cc7n(-c7ccccc7)c6cc54)cccc23)cc1 ; c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1]

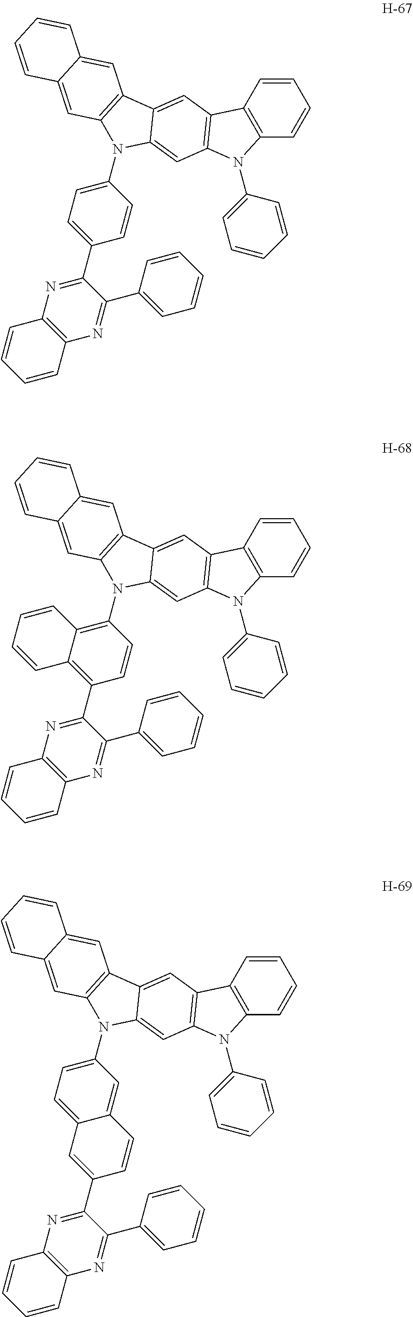 [SMILES: c1ccc(-c2nc3ccccc3nc2-c2ccc(-n3c4cc5ccccc5cc4c4cc5c6ccccc6n(-c6ccccc6)c5cc43)cc2)cc1 ; c1ccc(-c2nc3ccccc3nc2-c2ccc(-n3c4cc5ccccc5cc4c4cc5c6ccccc6n(-c6ccccc6)c5cc43)c3ccccc23)cc1 ; c1ccc(-c2nc3ccccc3nc2-c2ccc3cc(-n4c5cc6ccccc6cc5c5cc6c7ccccc7n(-c7ccccc7)c6cc54)ccc3c2)cc1]

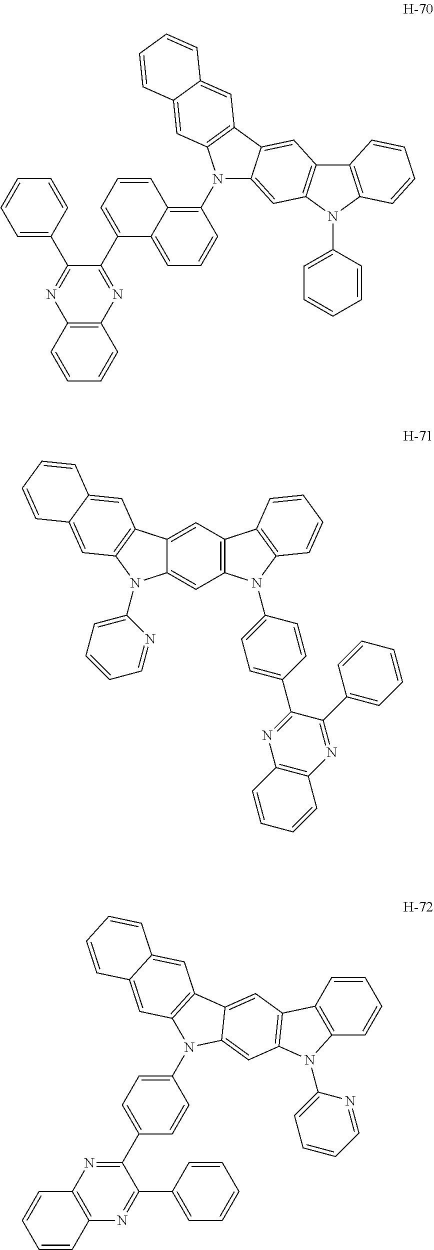 [SMILES: c1ccc(-c2nc3ccccc3nc2-c2cccc3c(-n4c5cc6ccccc6cc5c5cc6c7ccccc7n(-c7ccccc7)c6cc54)cccc23)cc1 ; c1ccc(-c2nc3ccccc3nc2-c2ccc(-n3c4ccccc4c4cc5c6cc7ccccc7cc6n(-c6ccccn6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1]

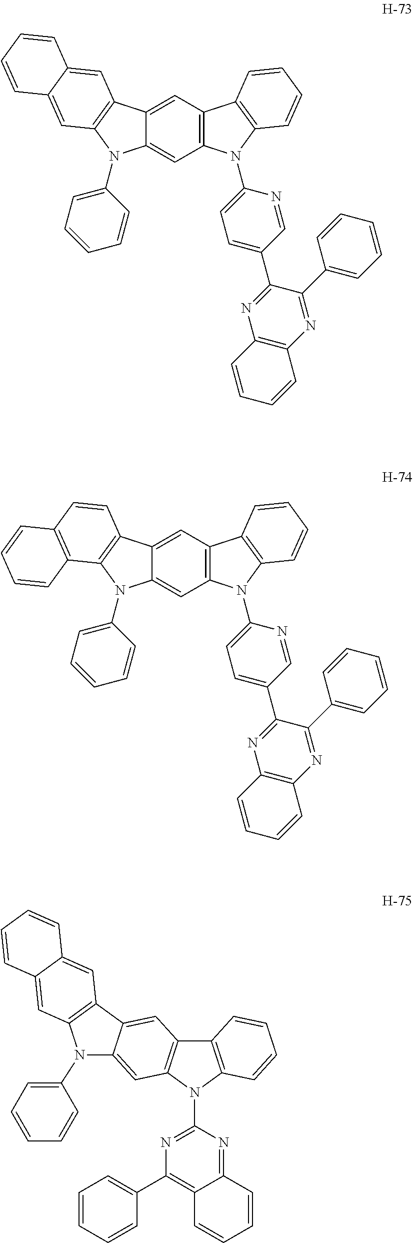 [SMILES: c1ccc(-c2nc3ccccc3nc2-c2ccc(-n3c4ccccc4c4cc5c6cc7ccccc7cc6n(-c6ccccc6)c5cc43)nc2)cc1 ; c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1]

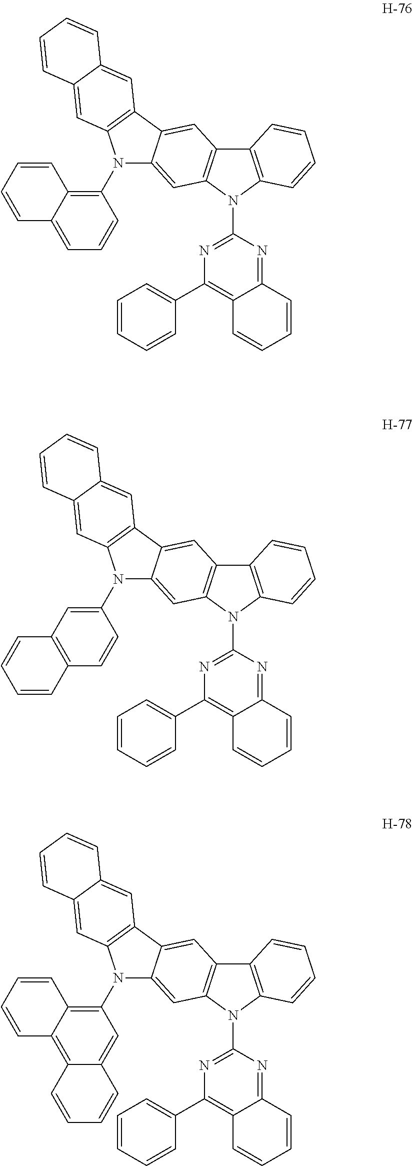 [SMILES: c1ccc(-c2nc(-n3c4ccccc4c4cc5c6cc7ccccc7cc6n(-c6cccc7ccccc67)c5cc43)nc3ccccc23)cc1 ; c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1]

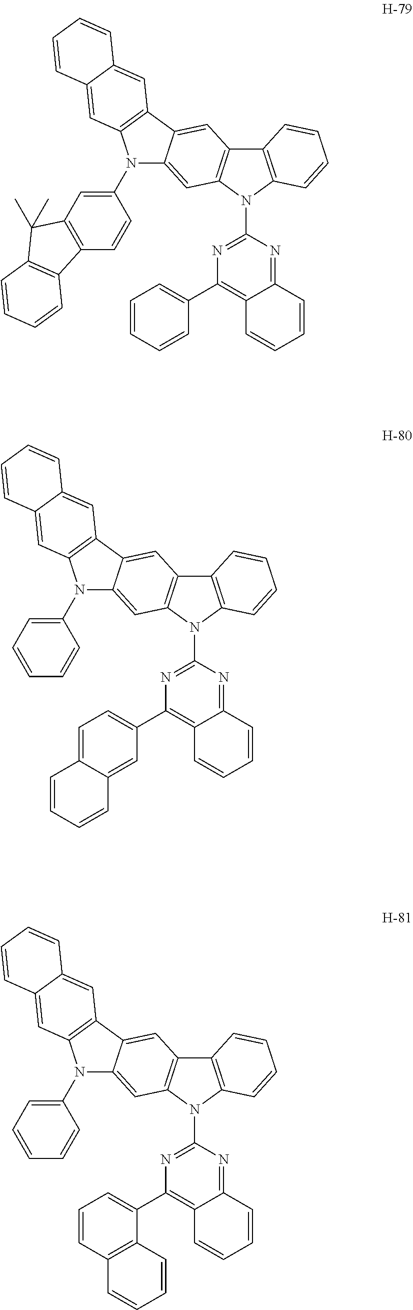 [SMILES: CC1(C)c2ccccc2-c2ccc(-n3c4cc5ccccc5cc4c4cc5c6ccccc6n(-c6nc(-c7ccccc7)c7ccccc7n6)c5cc43)cc21 ; c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1]

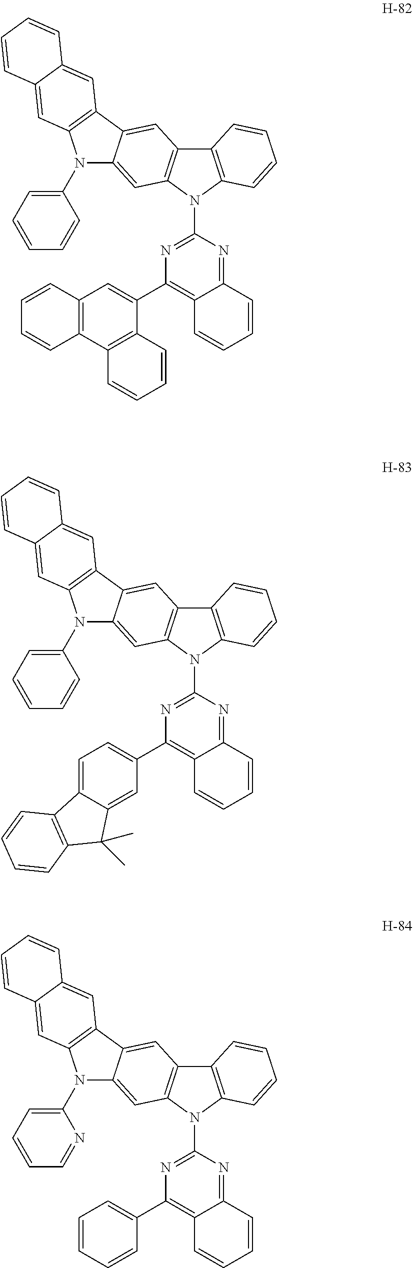 [SMILES: c1ccc(-n2c3cc4ccccc4cc3c3cc4c5ccccc5n(-c5nc(-c6cc7ccccc7c7ccccc67)c6ccccc6n5)c4cc32)cc1 ; CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1]

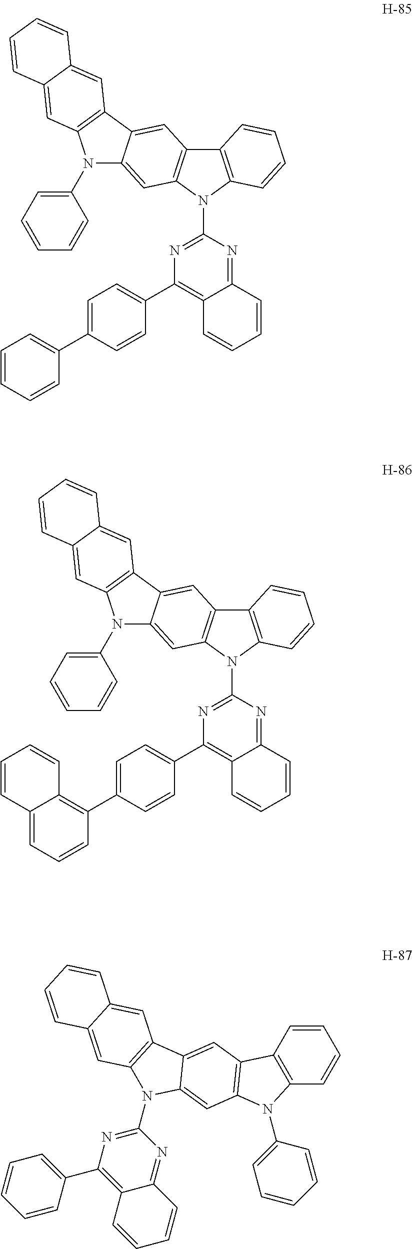 [SMILES: c1ccc(-c2ccc(-c3nc(-n4c5ccccc5c5cc6c7cc8ccccc8cc7n(-c7ccccc7)c6cc54)nc4ccccc34)cc2)cc1 ; c1ccc(-n2c3cc4ccccc4cc3c3cc4c5ccccc5n(-c5nc(-c6ccc(-c7cccc8ccccc78)cc6)c6ccccc6n5)c4cc32)cc1 ; c1ccc(-c2nc(-n3c4cc5ccccc5cc4c4cc5c6ccccc6n(-c6ccccc6)c5cc43)nc3ccccc23)cc1]

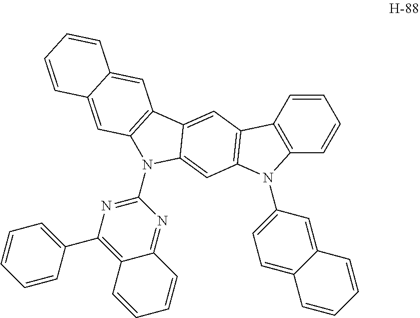 [SMILES: c1ccc(-c2nc(-n3c4cc5ccccc5cc4c4cc5c6ccccc6n(-c6ccc7ccccc7c6)c5cc43)nc3ccccc23)cc1]

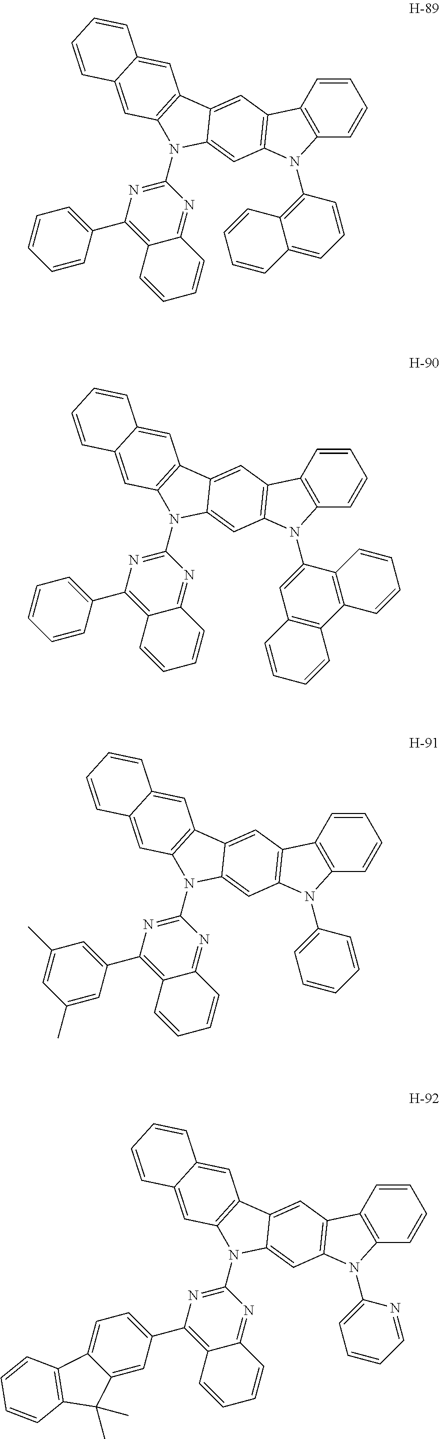 [SMILES: c1ccc(-c2nc(-n3c4cc5ccccc5cc4c4cc5c6ccccc6n(-c6cccc7ccccc67)c5cc43)nc3ccccc23)cc1 ; c1ccc(-c2nc(-n3c4cc5ccccc5cc4c4cc5c6ccccc6n(-c6cc7ccccc7c7ccccc67)c5cc43)nc3ccccc23)cc1 ; Cc1cc(C)cc(-c2nc(-n3c4cc5ccccc5cc4c4cc5c6ccccc6n(-c6ccccc6)c5cc43)nc3ccccc23)c1 ; CC1(C)c2ccccc2-c2ccc(-c3nc(-n4c5cc6ccccc6cc5c5cc6c7ccccc7n(-c7ccccn7)c6cc54)nc4ccccc34)cc21]

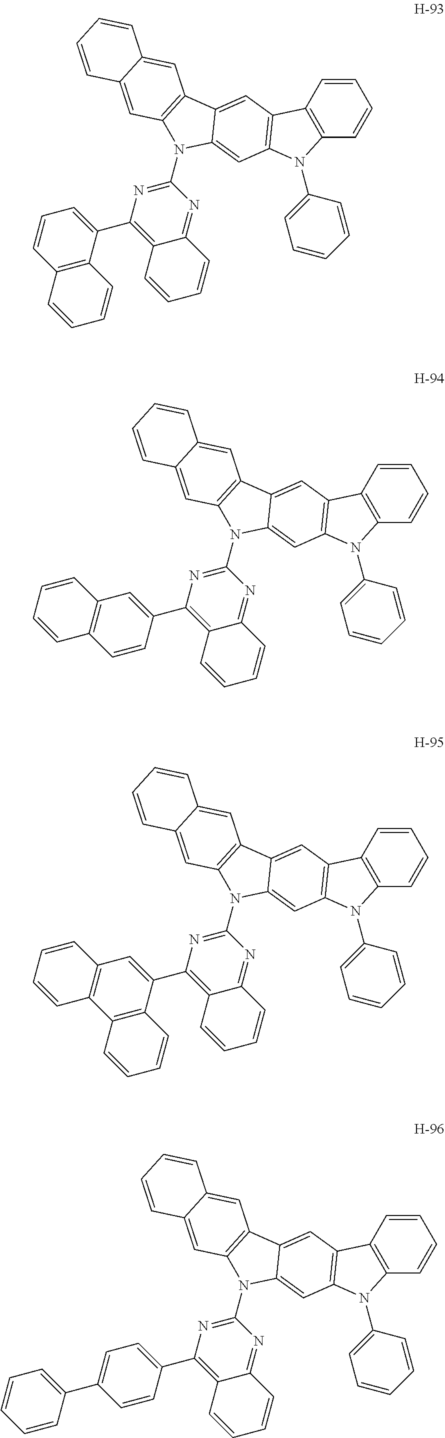 [SMILES: c1ccc(-n2c3ccccc3c3cc4c5cc6ccccc6cc5n(-c5nc(-c6cccc7ccccc67)c6ccccc6n5)c4cc32)cc1 ; c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1 ; c1ccc(-c2ccc(-c3nc(-n4c5cc6ccccc6cc5c5cc6c7ccccc7n(-c7ccccc7)c6cc54)nc4ccccc34)cc2)cc1]

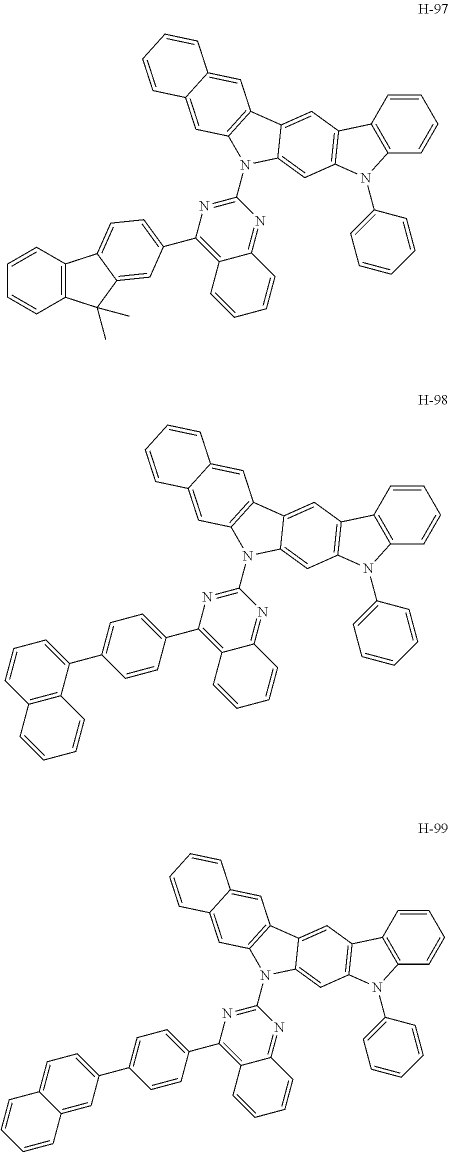 [SMILES: CC1(C)c2ccccc2-c2ccc(-c3nc(-n4c5cc6ccccc6cc5c5cc6c7ccccc7n(-c7ccccc7)c6cc54)nc4ccccc34)cc21 ; c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1]

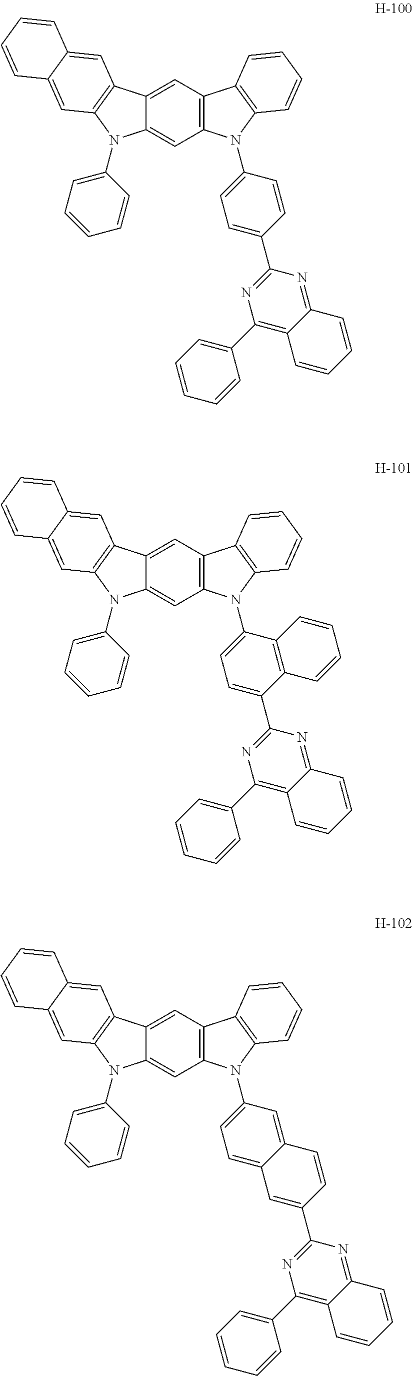 [SMILES: c1ccc(-c2nc(-c3ccc(-n4c5ccccc5c5cc6c7cc8ccccc8cc7n(-c7ccccc7)c6cc54)cc3)nc3ccccc23)cc1 ; c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1]

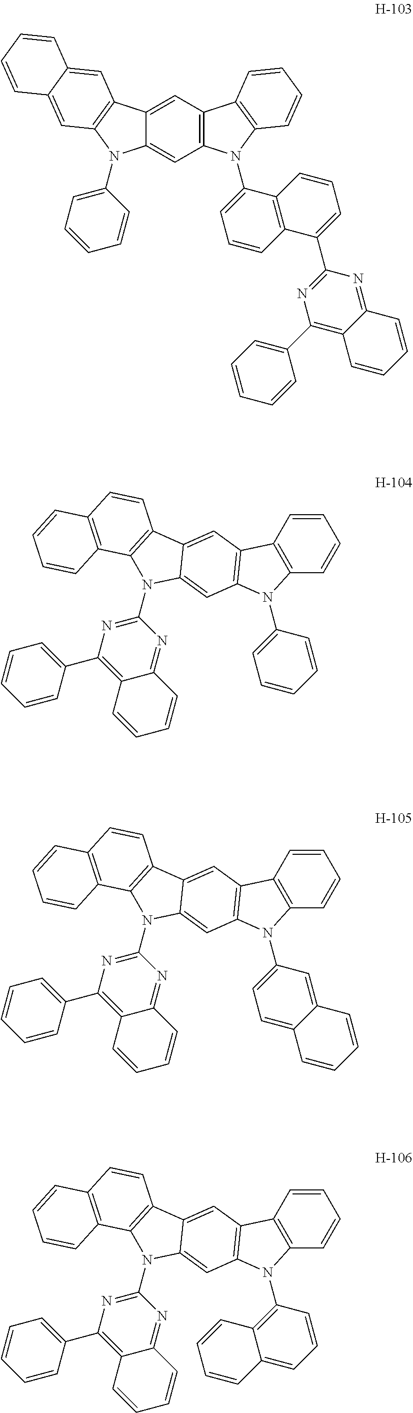 [SMILES: c1ccc(-c2nc(-c3cccc4c(-n5c6ccccc6c6cc7c8cc9ccccc9cc8n(-c8ccccc8)c7cc65)cccc34)nc3ccccc23)cc1 ; c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1]

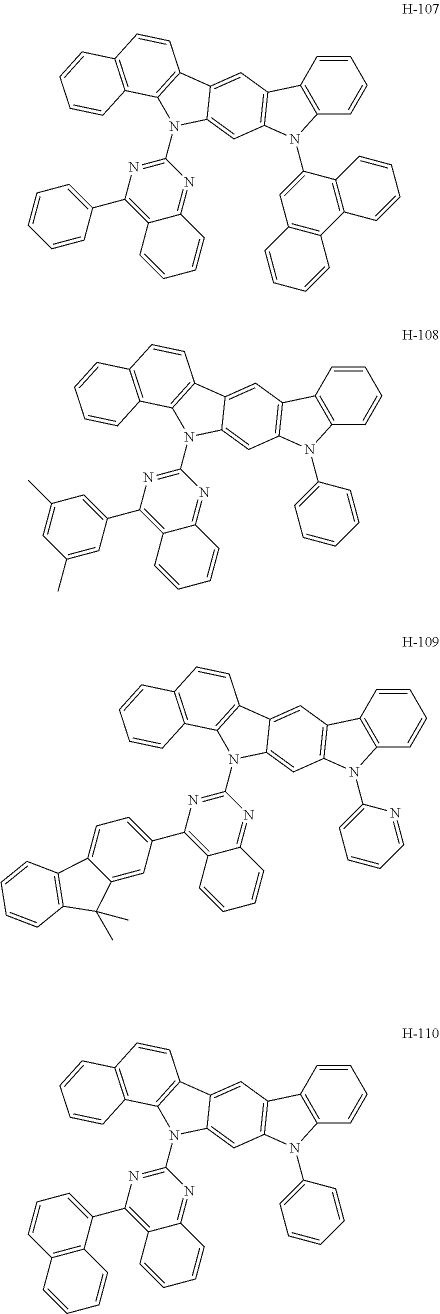 [SMILES: c1ccc(-c2nc(-n3c4cc5c(cc4c4ccc6ccccc6c43)c3ccccc3n5-c3cc4ccccc4c4ccccc34)nc3ccccc23)cc1 ; Cc1cc(C)cc(-c2nc(-n3c4cc5c(cc4c4ccc6ccccc6c43)c3ccccc3n5-c3ccccc3)nc3ccccc23)c1 ; CC1(C)c2ccccc2-c2ccc(-c3nc(-n4c5cc6c(cc5c5ccc7ccccc7c54)c4ccccc4n6-c4ccccn4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1]

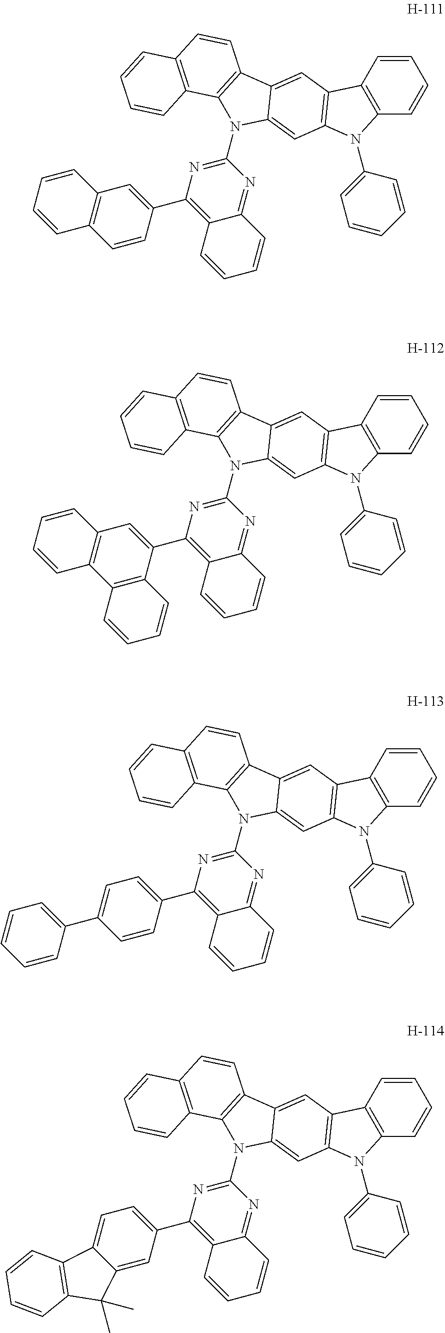 [SMILES: c1ccc(-n2c3ccccc3c3cc4c5ccc6ccccc6c5n(-c5nc(-c6ccc7ccccc7c6)c6ccccc6n5)c4cc32)cc1 ; c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1 ; CC1(C)c2ccccc2-c2ccc(-c3nc(-n4c5cc6c(cc5c5ccc7ccccc7c54)c4ccccc4n6-c4ccccc4)nc4ccccc34)cc21]

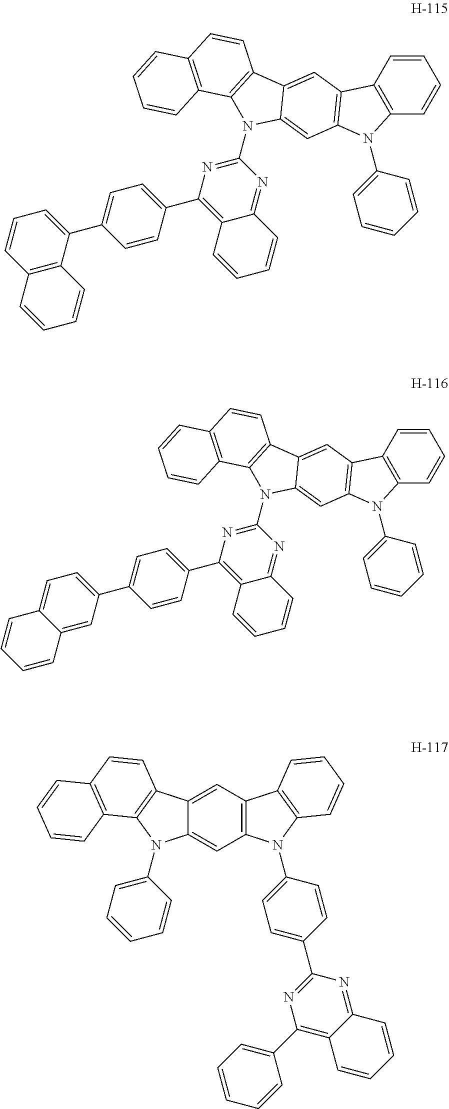 [SMILES: c1ccc(-n2c3ccccc3c3cc4c5ccc6ccccc6c5n(-c5nc(-c6ccc(-c7cccc8ccccc78)cc6)c6ccccc6n5)c4cc32)cc1 ; c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1]

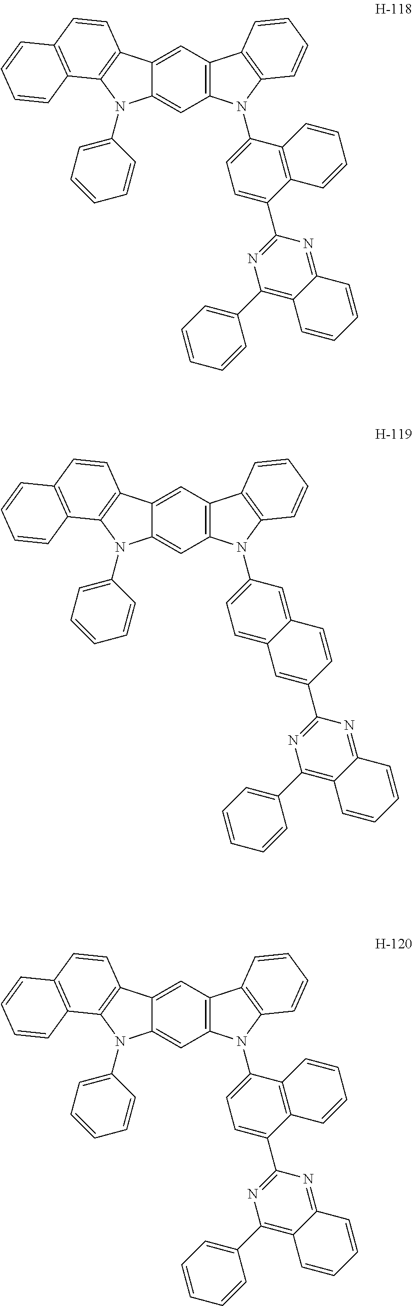 [SMILES: c1ccc(-c2nc(-c3ccc(-n4c5ccccc5c5cc6c7ccc8ccccc8c7n(-c7ccccc7)c6cc54)c4ccccc34)nc3ccccc23)cc1 ; c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3ccc(-n4c5ccccc5c5cc6c7ccc8ccccc8c7n(-c7ccccc7)c6cc54)c4ccccc34)nc3ccccc23)cc1]

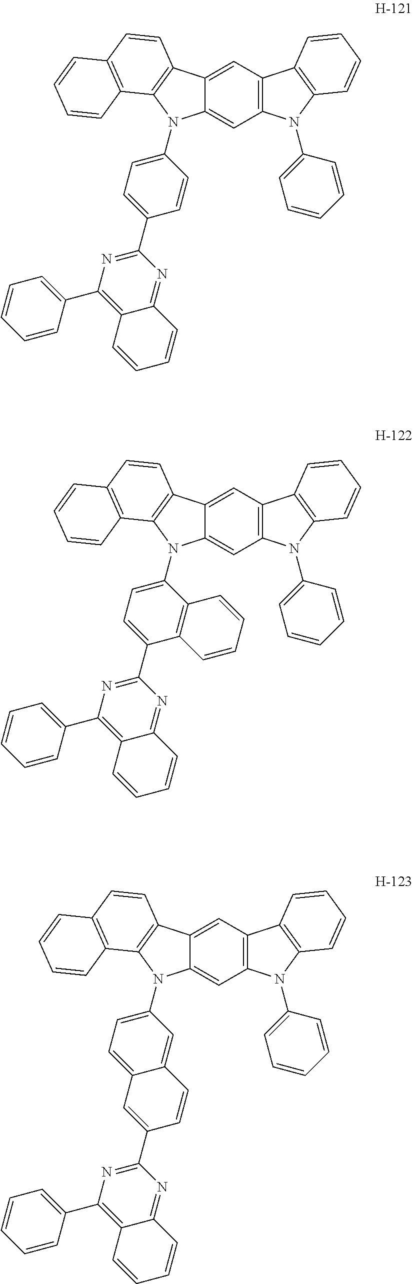 [SMILES: c1ccc(-c2nc(-c3ccc(-n4c5cc6c(cc5c5ccc7ccccc7c54)c4ccccc4n6-c4ccccc4)cc3)nc3ccccc23)cc1 ; c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1]

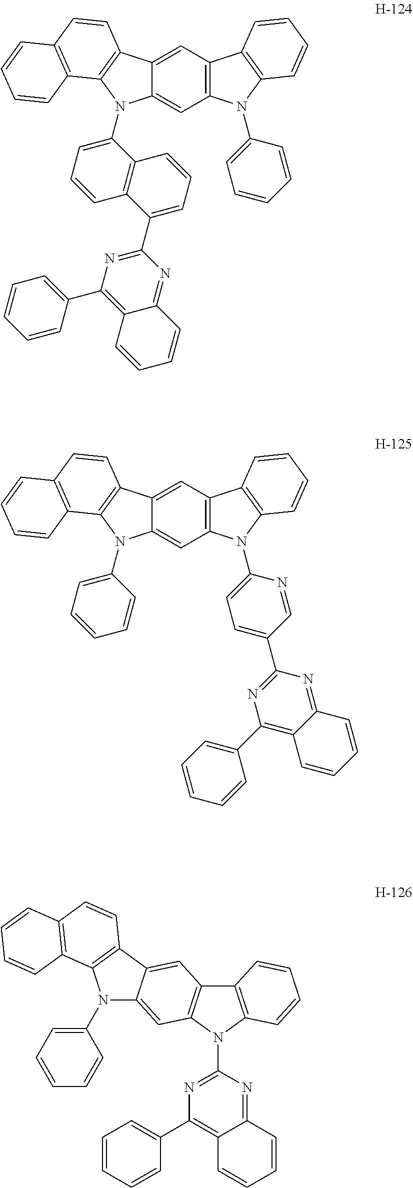 [SMILES: c1ccc(-c2nc(-c3cccc4c(-n5c6cc7c(cc6c6ccc8ccccc8c65)c5ccccc5n7-c5ccccc5)cccc34)nc3ccccc23)cc1 ; c1ccc(-c2nc(-c3ccc(-n4c5ccccc5c5cc6c7ccc8ccccc8c7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1]

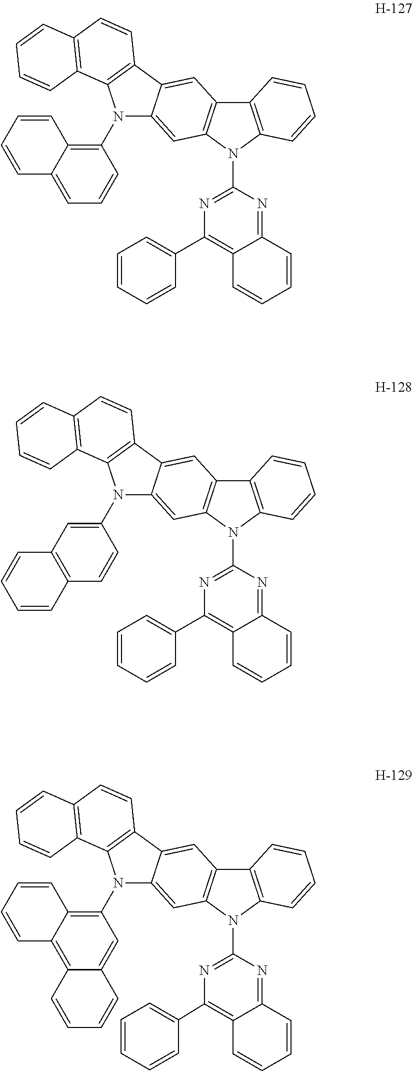 [SMILES: c1ccc(-c2nc(-n3c4ccccc4c4cc5c6ccc7ccccc7c6n(-c6cccc7ccccc67)c5cc43)nc3ccccc23)cc1 ; c1ccc(-c2nc(-n3c4ccccc4c4cc5c6ccc7ccccc7c6n(-c6ccc7ccccc7c6)c5cc43)nc3ccccc23)cc1 ; c1ccc(-c2nc(-n3c4ccccc4c4cc5c6ccc7ccccc7c6n(-c6cc7ccccc7c7ccccc67)c5cc43)nc3ccccc23)cc1]

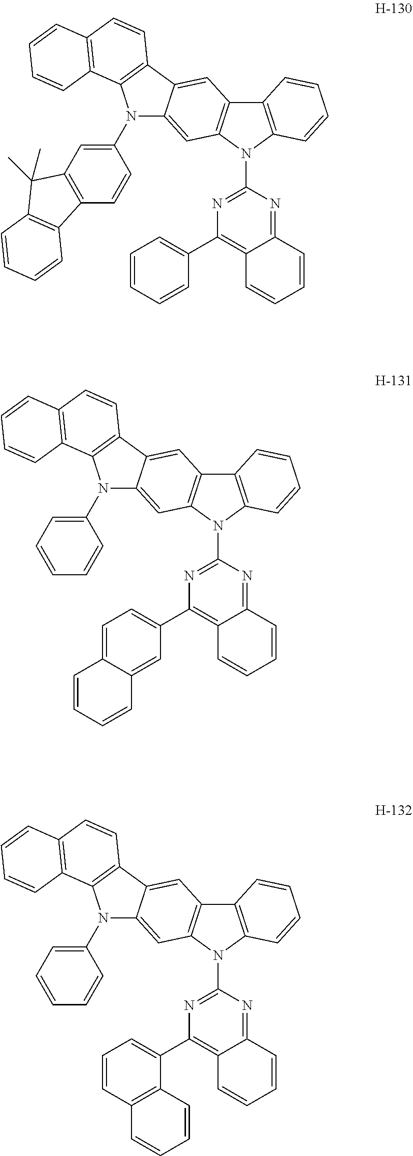 [SMILES: CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1 ; c1ccc(-n2c3cc4c(cc3c3ccc5ccccc5c32)c2ccccc2n4-c2nc(-c3cccc4ccccc34)c3ccccc3n2)cc1]

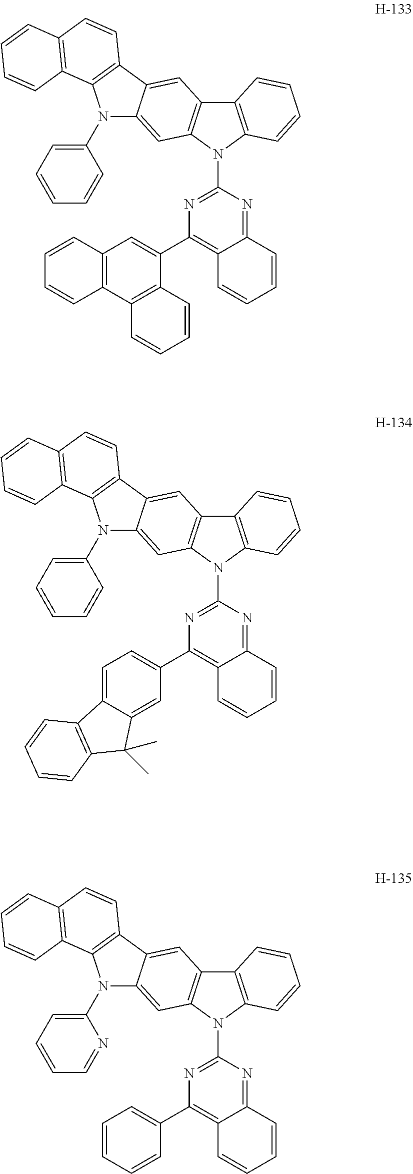 [SMILES: c1ccc(-n2c3cc4c(cc3c3ccc5ccccc5c32)c2ccccc2n4-c2nc(-c3cc4ccccc4c4ccccc34)c3ccccc3n2)cc1 ; CC1(C)c2ccccc2-c2ccc(-c3nc(-n4c5ccccc5c5cc6c7ccc8ccccc8c7n(-c7ccccc7)c6cc54)nc4ccccc34)cc21 ; c1ccc(-c2nc(-n3c4ccccc4c4cc5c6ccc7ccccc7c6n(-c6ccccn6)c5cc43)nc3ccccc23)cc1]

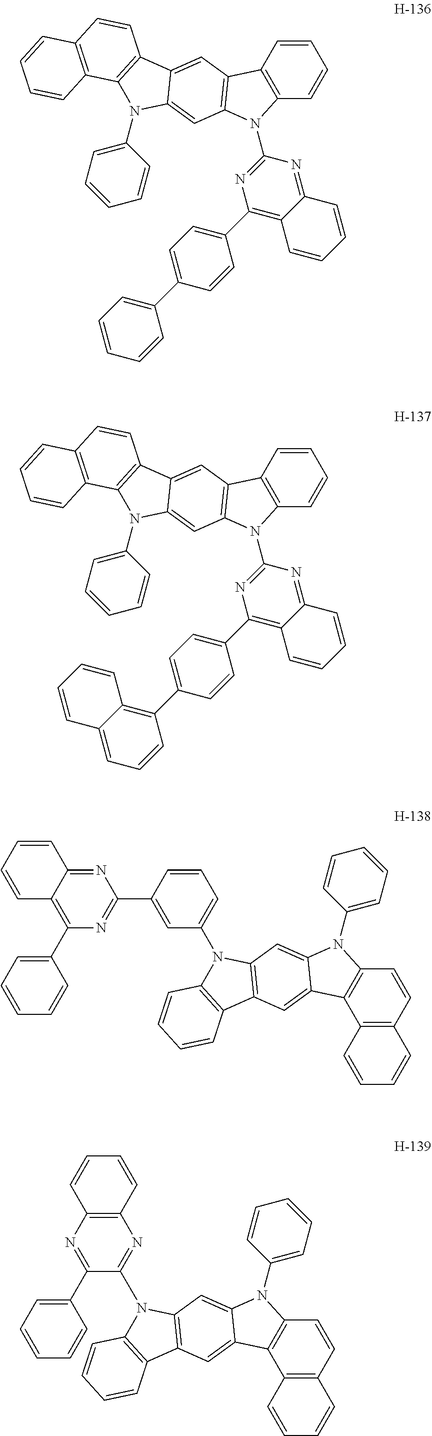 [SMILES: c1ccc(-c2ccc(-c3nc(-n4c5ccccc5c5cc6c7ccc8ccccc8c7n(-c7ccccc7)c6cc54)nc4ccccc34)cc2)cc1 ; c1ccc(-n2c3cc4c(cc3c3ccc5ccccc5c32)c2ccccc2n4-c2nc(-c3ccc(-c4cccc5ccccc45)cc3)c3ccccc3n2)cc1 ; c1ccc(-c2nc(-c3cccc(-n4c5ccccc5c5cc6c7c8ccccc8ccc7n(-c7ccccc7)c6cc54)c3)nc3ccccc23)cc1 ; c1ccc(-c2nc3ccccc3nc2-n2c3ccccc3c3cc4c5c6ccccc6ccc5n(-c5ccccc5)c4cc32)cc1]

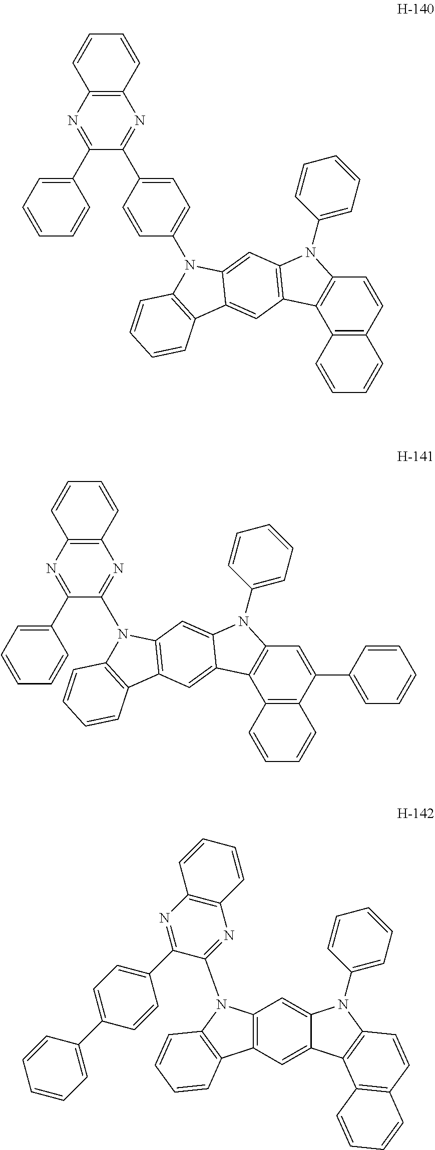 [SMILES: c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-c2ccc(-c3nc4ccccc4nc3-n3c4ccccc4c4cc5c6c7ccccc7ccc6n(-c6ccccc6)c5cc43)cc2)cc1]

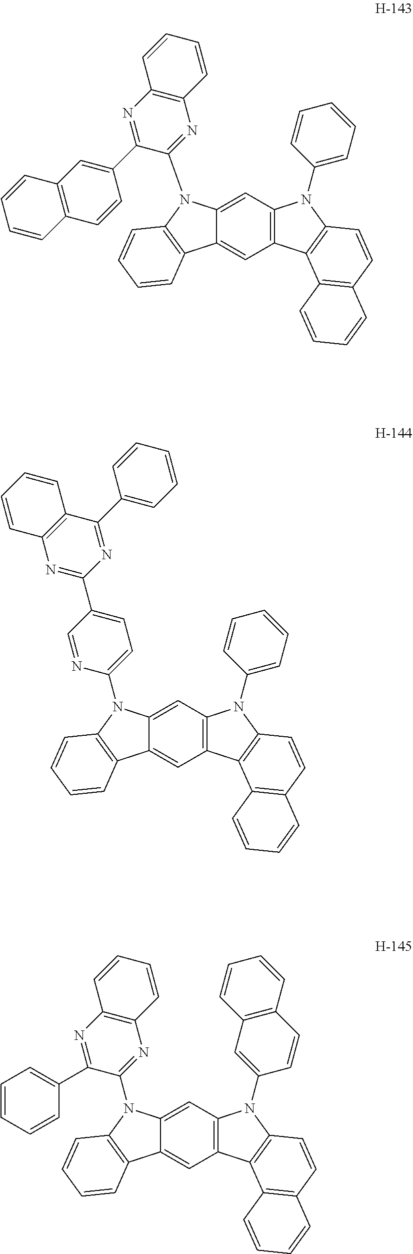 [SMILES: c1ccc(-n2c3cc4c(cc3c3c5ccccc5ccc32)c2ccccc2n4-c2nc3ccccc3nc2-c2ccc3ccccc3c2)cc1 ; c1ccc(-c2nc(-c3ccc(-n4c5ccccc5c5cc6c7c8ccccc8ccc7n(-c7ccccc7)c6cc54)nc3)nc3ccccc23)cc1 ; c1ccc(-c2nc3ccccc3nc2-n2c3ccccc3c3cc4c5c6ccccc6ccc5n(-c5ccc6ccccc6c5)c4cc32)cc1]

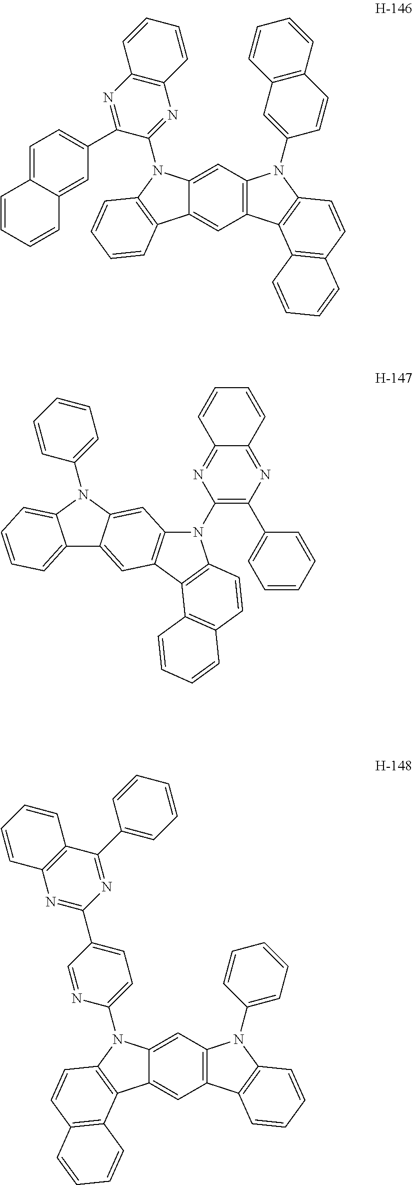 [SMILES: c1ccc2cc(-c3nc4ccccc4nc3-n3c4ccccc4c4cc5c6c7ccccc7ccc6n(-c6ccc7ccccc7c6)c5cc43)ccc2c1 ; c1ccc(-c2nc3ccccc3nc2-n2c3cc4c(cc3c3c5ccccc5ccc32)c2ccccc2n4-c2ccccc2)cc1 ; c1ccc(-c2nc(-c3ccc(-n4c5cc6c(cc5c5c7ccccc7ccc54)c4ccccc4n6-c4ccccc4)nc3)nc3ccccc23)cc1]

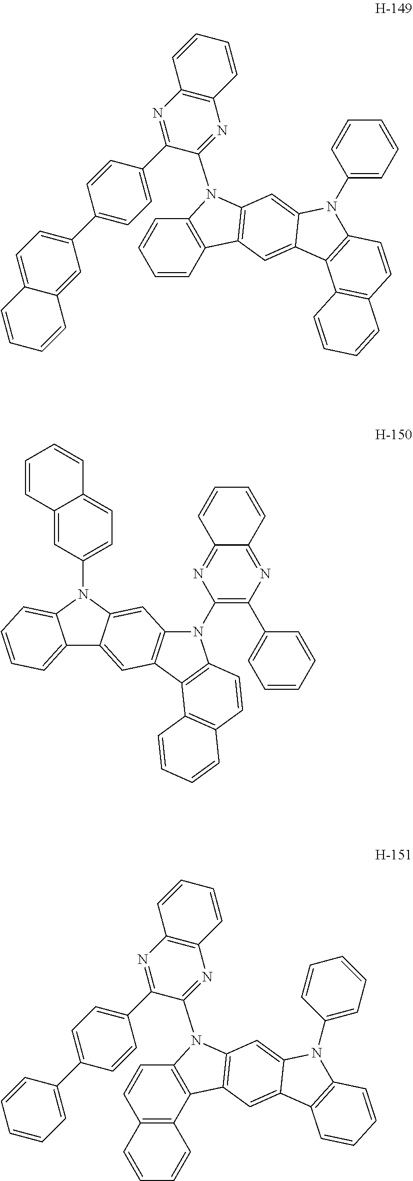 [SMILES: c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2nc3ccccc3nc2-n2c3cc4c(cc3c3c5ccccc5ccc32)c2ccccc2n4-c2ccc3ccccc3c2)cc1 ; c1ccc(-c2ccc(-c3nc4ccccc4nc3-n3c4cc5c(cc4c4c6ccccc6ccc43)c3ccccc3n5-c3ccccc3)cc2)cc1]

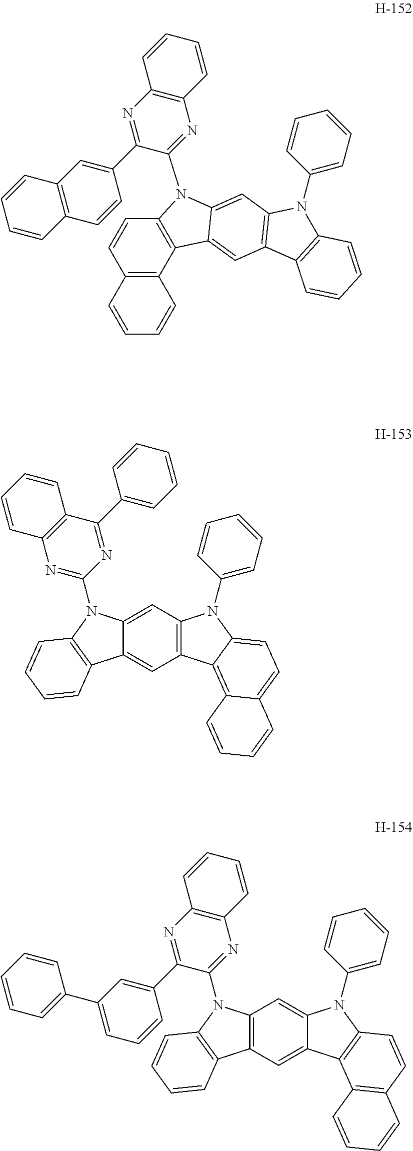 [SMILES: c1ccc(-n2c3ccccc3c3cc4c5c6ccccc6ccc5n(-c5nc6ccccc6nc5-c5ccc6ccccc6c5)c4cc32)cc1 ; c1ccc(-c2nc(-n3c4ccccc4c4cc5c6c7ccccc7ccc6n(-c6ccccc6)c5cc43)nc3ccccc23)cc1 ; c1ccc(-c2cccc(-c3nc4ccccc4nc3-n3c4ccccc4c4cc5c6c7ccccc7ccc6n(-c6ccccc6)c5cc43)c2)cc1]

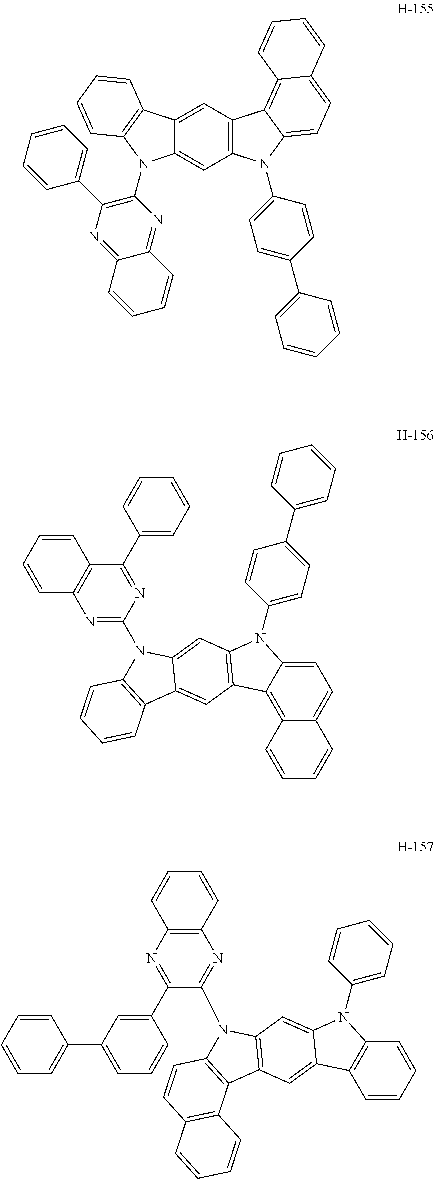 [SMILES: c1ccc(-c2ccc(-n3c4cc5c(cc4c4c6ccccc6ccc43)c3ccccc3n5-c3nc4ccccc4nc3-c3ccccc3)cc2)cc1 ; c1ccc(-c2ccc(-n3c4cc5c(cc4c4c6ccccc6ccc43)c3ccccc3n5-c3nc(-c4ccccc4)c4ccccc4n3)cc2)cc1 ; c1ccc(-c2cccc(-c3nc4ccccc4nc3-n3c4cc5c(cc4c4c6ccccc6ccc43)c3ccccc3n5-c3ccccc3)c2)cc1]

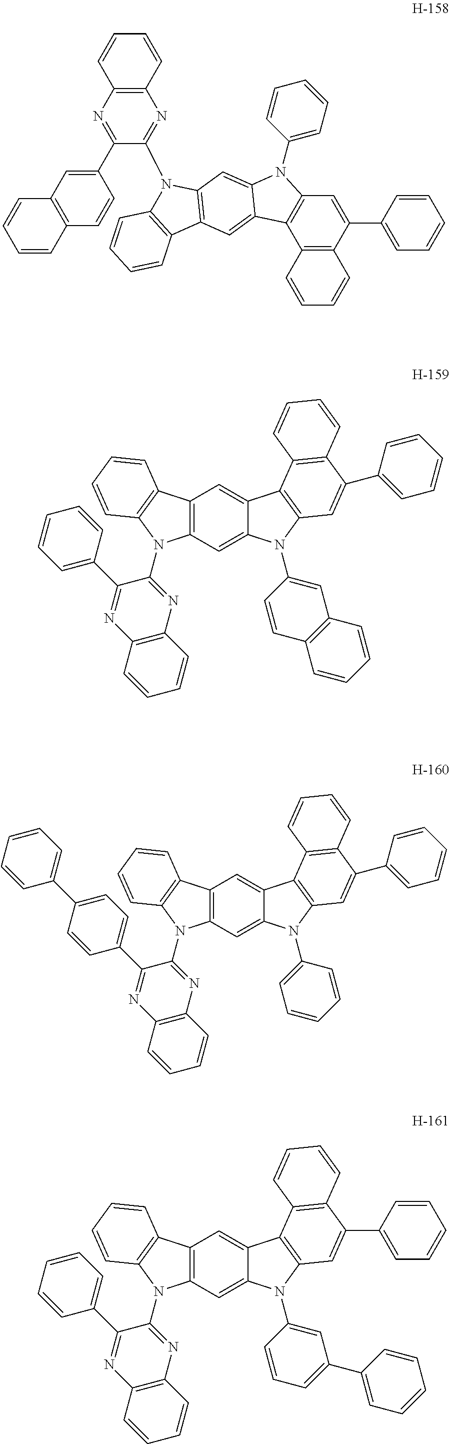 [SMILES: c1ccc(-c2cc3c(c4ccccc24)c2cc4c5ccccc5n(-c5nc6ccccc6nc5-c5ccc6ccccc6c5)c4cc2n3-c2ccccc2)cc1 ; c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1 ; c1ccc(-c2cccc(-n3c4cc5c(cc4c4c6ccccc6c(-c6ccccc6)cc43)c3ccccc3n5-c3nc4ccccc4nc3-c3ccccc3)c2)cc1]

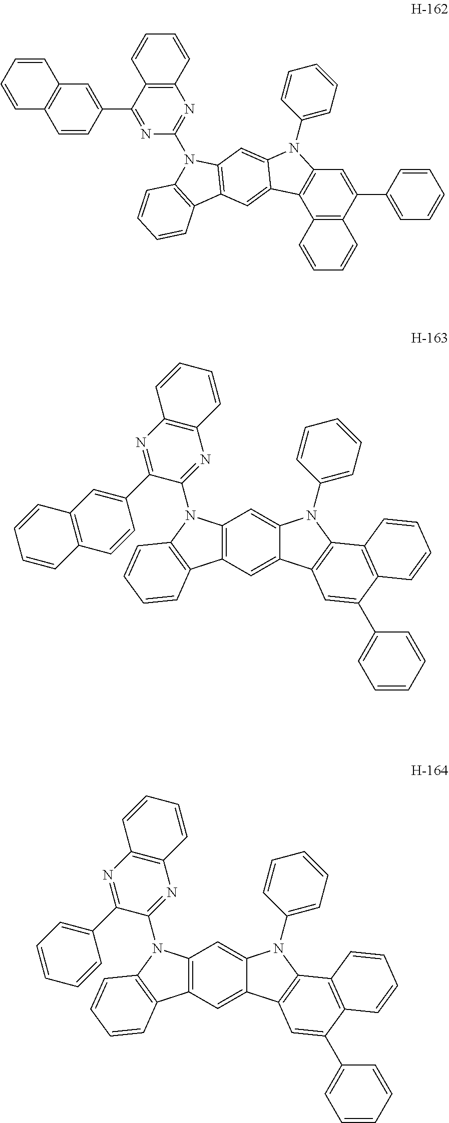 [SMILES: c1ccc(-c2cc3c(c4ccccc24)c2cc4c5ccccc5n(-c5nc(-c6ccc7ccccc7c6)c6ccccc6n5)c4cc2n3-c2ccccc2)cc1 ; c1ccc(-c2cc3c4cc5c6ccccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1]

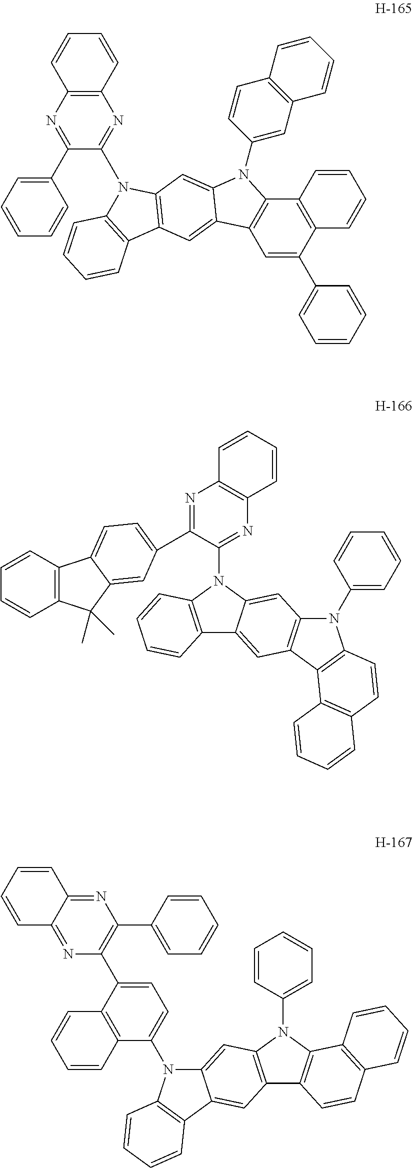 [SMILES: c1ccc(-c2nc3ccccc3nc2-n2c3ccccc3c3cc4c5cc(-c6ccccc6)c6ccccc6c5n(-c5ccc6ccccc6c5)c4cc32)cc1 ; CC1(C)c2ccccc2-c2ccc(-c3nc4ccccc4nc3-n3c4ccccc4c4cc5c6c7ccccc7ccc6n(-c6ccccc6)c5cc43)cc21 ; c1ccc(-c2nc3ccccc3nc2-c2ccc(-n3c4ccccc4c4cc5c6ccc7ccccc7c6n(-c6ccccc6)c5cc43)c3ccccc23)cc1]

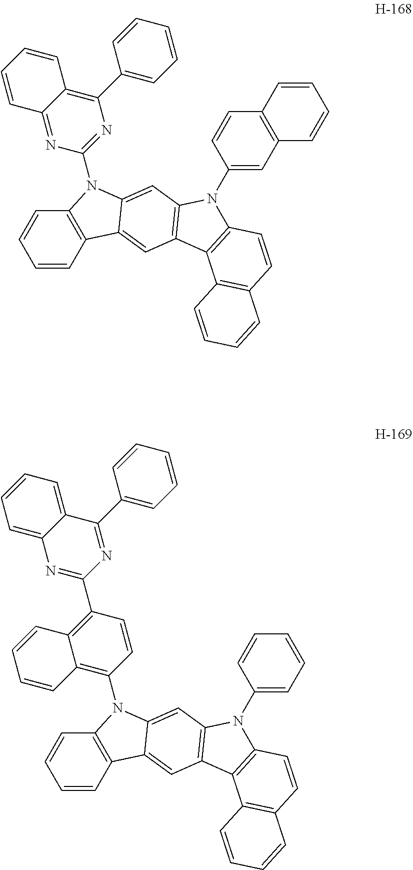 [SMILES: c1ccc(-c2nc(-n3c4ccccc4c4cc5c6c7ccccc7ccc6n(-c6ccc7ccccc7c6)c5cc43)nc3ccccc23)cc1 ; c1ccc(-c2nc(-c3ccc(-n4c5ccccc5c5cc6c7c8ccccc8ccc7n(-c7ccccc7)c6cc54)c4ccccc34)nc3ccccc23)cc1]

The compound represented by formula 11 may be at least one selected from the following compounds, but is not limited thereto.

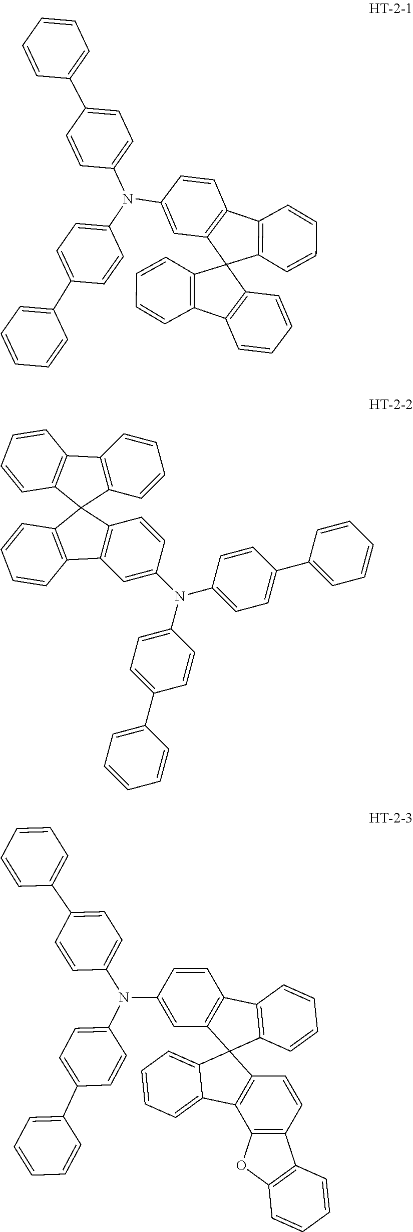 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; c1ccc(-c2ccc(N(c3ccc(-c4ccccc4)cc3)c3ccc4c(c3)C3(c5ccccc5-4)c4ccccc4-c4c3ccc3c4oc4ccccc43)cc2)cc1]

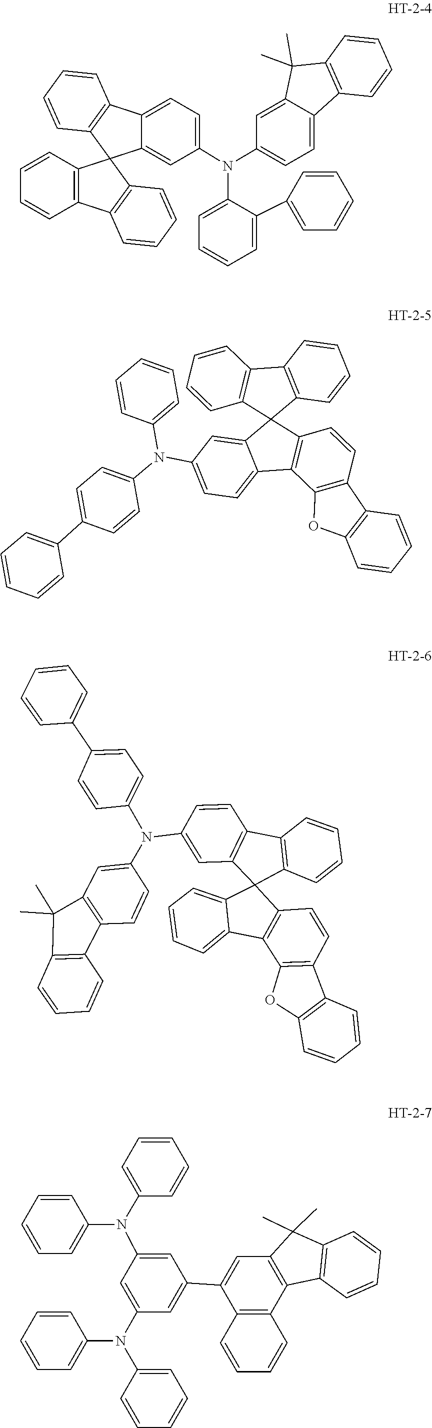 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccccc3)c3ccc4c(c3)C3(c5ccccc5-c5ccccc53)c3ccc5c(oc6ccccc65)c3-4)cc2)cc1 ; CC1(C)c2ccccc2-c2ccc(N(c3ccc(-c4ccccc4)cc3)c3ccc4c(c3)C3(c5ccccc5-4)c4ccccc4-c4c3ccc3c4oc4ccccc43)cc21 ; CC1(C)c2ccccc2-c2c1cc(-c1cc(N(c3ccccc3)c3ccccc3)cc(N(c3ccccc3)c3ccccc3)c1)c1ccccc21]

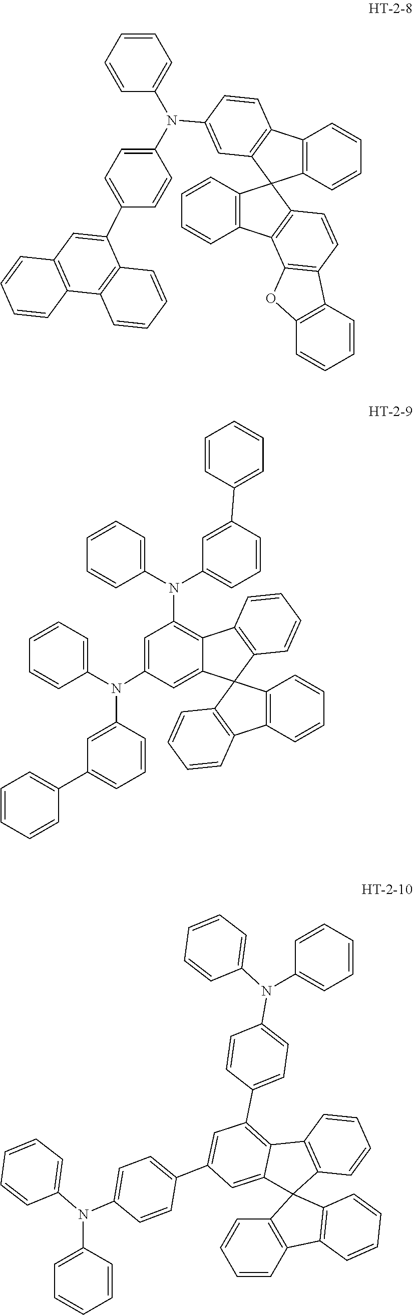 [SMILES: c1ccc(N(c2ccc(-c3cc4ccccc4c4ccccc34)cc2)c2ccc3c(c2)C2(c4ccccc4-3)c3ccccc3-c3c2ccc2c3oc3ccccc32)cc1 ; c1ccc(-c2cccc(N(c3ccccc3)c3cc(N(c4ccccc4)c4cccc(-c5ccccc5)c4)c4c(c3)C3(c5ccccc5-c5ccccc53)c3ccccc3-4)c2)cc1 ; c1ccc(N(c2ccccc2)c2ccc(-c3cc(-c4ccc(N(c5ccccc5)c5ccccc5)cc4)c4c(c3)C3(c5ccccc5-c5ccccc53)c3ccccc3-4)cc2)cc1]

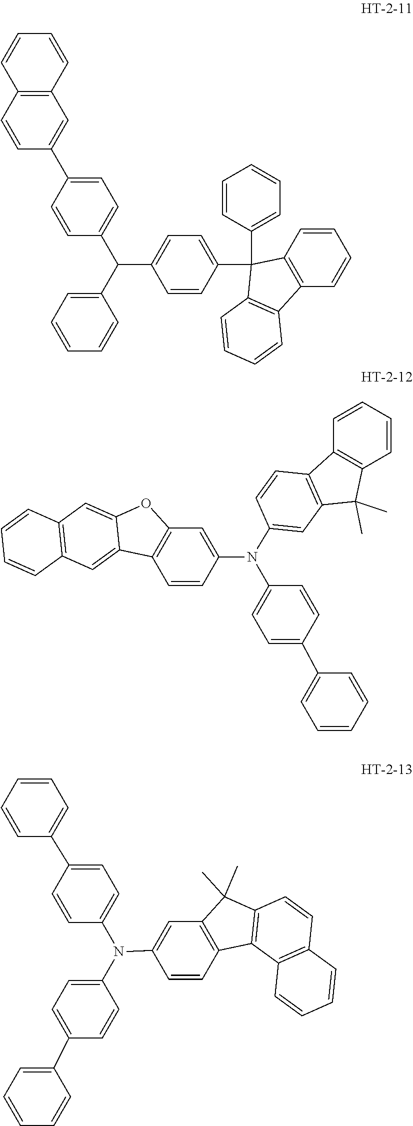

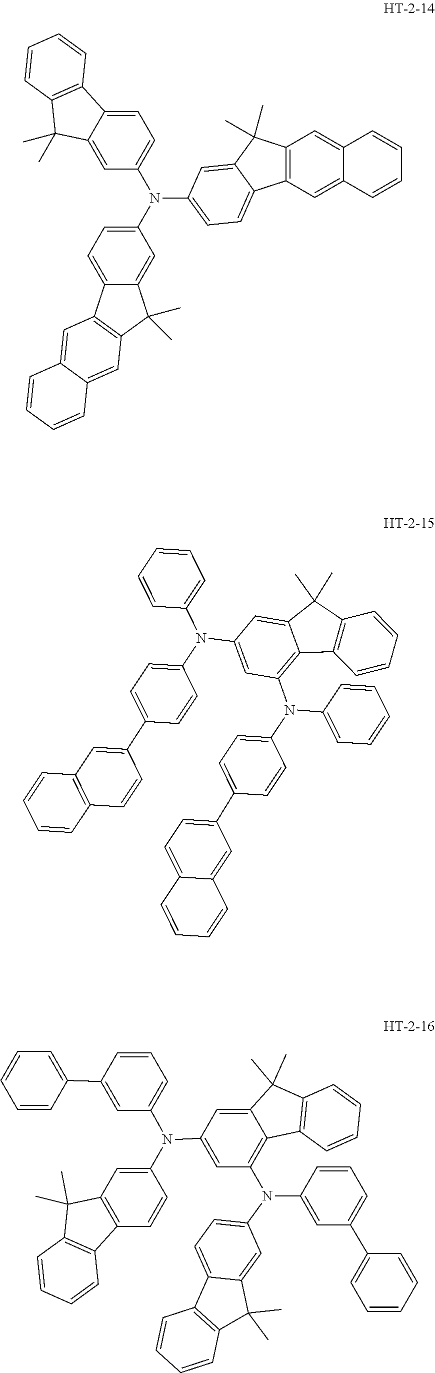 [SMILES: CC1(C)c2ccccc2-c2ccc(N(c3ccc4c(c3)C(C)(C)c3cc5ccccc5cc3-4)c3ccc4c(c3)C(C)(C)c3cc5ccccc5cc3-4)cc21 ; CC1(C)c2ccccc2-c2c(N(c3ccccc3)c3ccc(-c4ccc5ccccc5c4)cc3)cc(N(c3ccccc3)c3ccc(-c4ccc5ccccc5c4)cc3)cc21 ; CC1(C)c2ccccc2-c2ccc(N(c3cccc(-c4ccccc4)c3)c3cc(N(c4cccc(-c5ccccc5)c4)c4ccc5c(c4)C(C)(C)c4ccccc4-5)c4c(c3)C(C)(C)c3ccccc3-4)cc21]

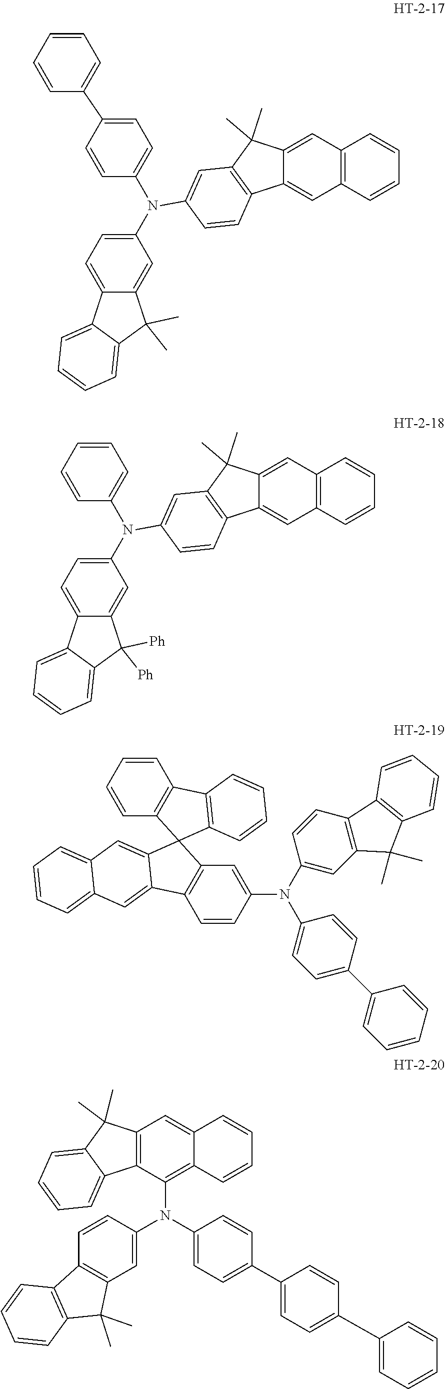 [SMILES: CC1(C)c2ccccc2-c2ccc(N(c3ccc(-c4ccccc4)cc3)c3ccc4c(c3)C(C)(C)c3cc5ccccc5cc3-4)cc21 ; CC1(C)c2cc(N(c3ccccc3)c3ccc4c(c3)C(c3ccccc3)(c3ccccc3)c3ccccc3-4)ccc2-c2cc3ccccc3cc21 ; CC1(C)c2ccccc2-c2ccc(N(c3ccc(-c4ccccc4)cc3)c3ccc4c(c3)C3(c5ccccc5-c5ccccc53)c3cc5ccccc5cc3-4)cc21 ; CC1(C)c2ccccc2-c2ccc(N(c3ccc(-c4ccc(-c5ccccc5)cc4)cc3)c3c4c(cc5ccccc35)C(C)(C)c3ccccc3-4)cc21]

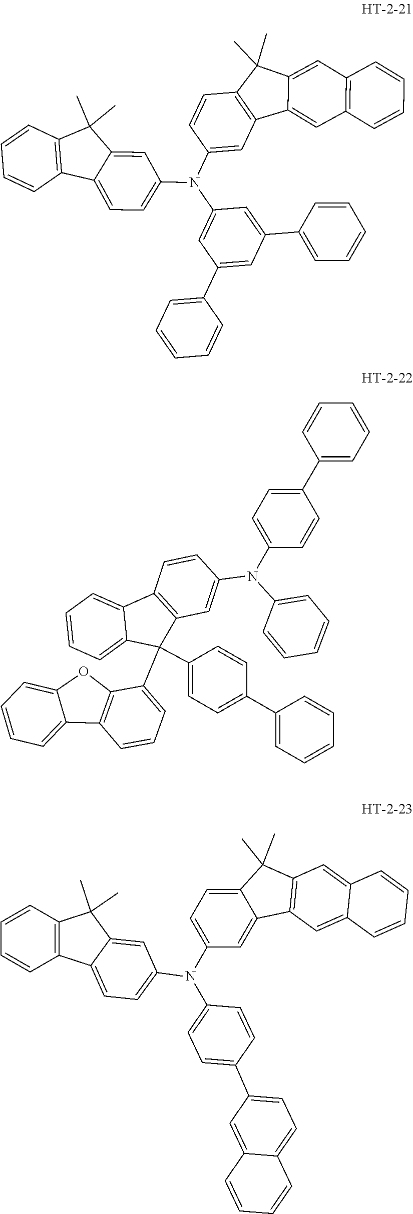 [SMILES: CC1(C)c2ccccc2-c2ccc(N(c3cc(-c4ccccc4)cc(-c4ccccc4)c3)c3ccc4c(c3)-c3cc5ccccc5cc3C4(C)C)cc21 ; c1ccc(-c2ccc(N(c3ccccc3)c3ccc4c(c3)C(c3ccc(-c5ccccc5)cc3)(c3cccc5c3oc3ccccc35)c3ccccc3-4)cc2)cc1 ; CC1(C)c2ccccc2-c2ccc(N(c3ccc(-c4ccc5ccccc5c4)cc3)c3ccc4c(c3)-c3cc5ccccc5cc3C4(C)C)cc21]

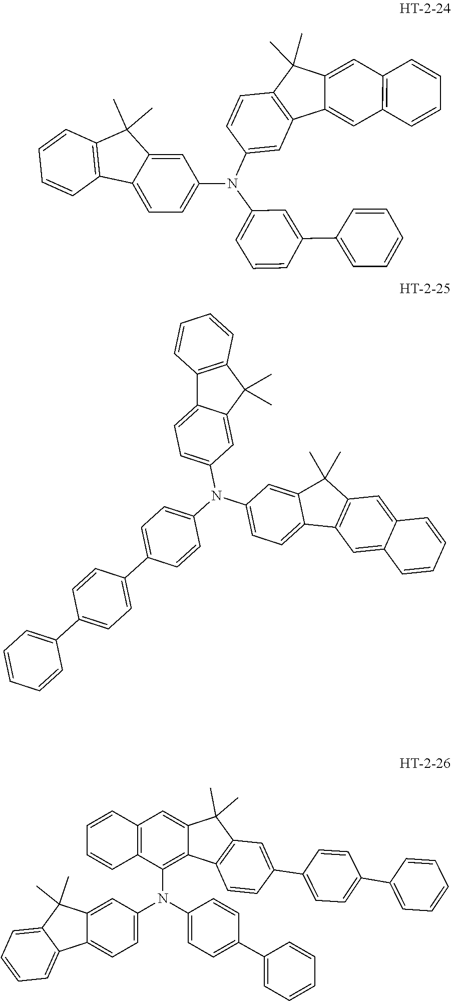 [SMILES: CC1(C)c2ccccc2-c2ccc(N(c3cccc(-c4ccccc4)c3)c3ccc4c(c3)-c3cc5ccccc5cc3C4(C)C)cc21 ; CC1(C)c2ccccc2-c2ccc(N(c3ccc(-c4ccc(-c5ccccc5)cc4)cc3)c3ccc4c(c3)C(C)(C)c3cc5ccccc5cc3-4)cc21 ; CC1(C)c2ccccc2-c2ccc(N(c3ccc(-c4ccccc4)cc3)c3c4c(cc5ccccc35)C(C)(C)c3cc(-c5ccc(-c6ccccc6)cc5)ccc3-4)cc21]

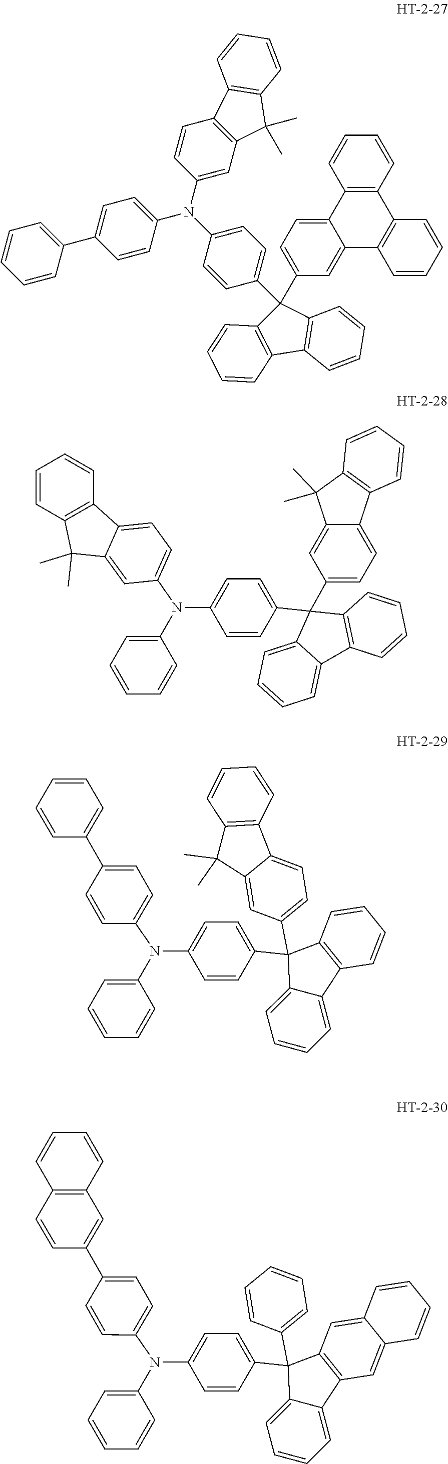 [SMILES: CC1(C)c2ccccc2-c2ccc(N(c3ccc(-c4ccccc4)cc3)c3ccc(C4(c5ccc6c7ccccc7c7ccccc7c6c5)c5ccccc5-c5ccccc54)cc3)cc21 ; CC1(C)c2ccccc2-c2ccc(N(c3ccccc3)c3ccc(C4(c5ccc6c(c5)C(C)(C)c5ccccc5-6)c5ccccc5-c5ccccc54)cc3)cc21 ; CC1(C)c2ccccc2-c2ccc(C3(c4ccc(N(c5ccccc5)c5ccc(-c6ccccc6)cc5)cc4)c4ccccc4-c4ccccc43)cc21 ; c1ccc(N(c2ccc(-c3ccc4ccccc4c3)cc2)c2ccc(C3(c4ccccc4)c4ccccc4-c4cc5ccccc5cc43)cc2)cc1]

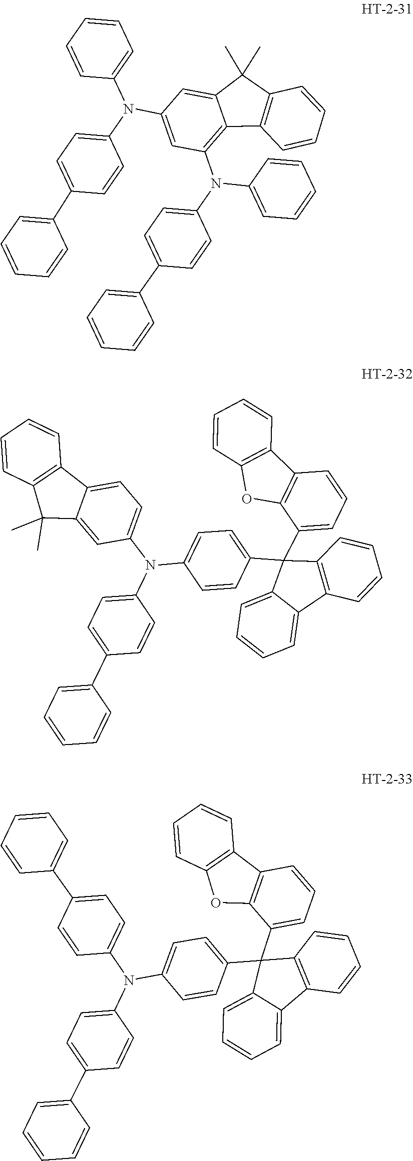 [SMILES: CC1(C)c2ccccc2-c2c(N(c3ccccc3)c3ccc(-c4ccccc4)cc3)cc(N(c3ccccc3)c3ccc(-c4ccccc4)cc3)cc21 ; CC1(C)c2ccccc2-c2ccc(N(c3ccc(-c4ccccc4)cc3)c3ccc(C4(c5cccc6c5oc5ccccc56)c5ccccc5-c5ccccc54)cc3)cc21 ; c1ccc(-c2ccc(N(c3ccc(-c4ccccc4)cc3)c3ccc(C4(c5cccc6c5oc5ccccc56)c5ccccc5-c5ccccc54)cc3)cc2)cc1]

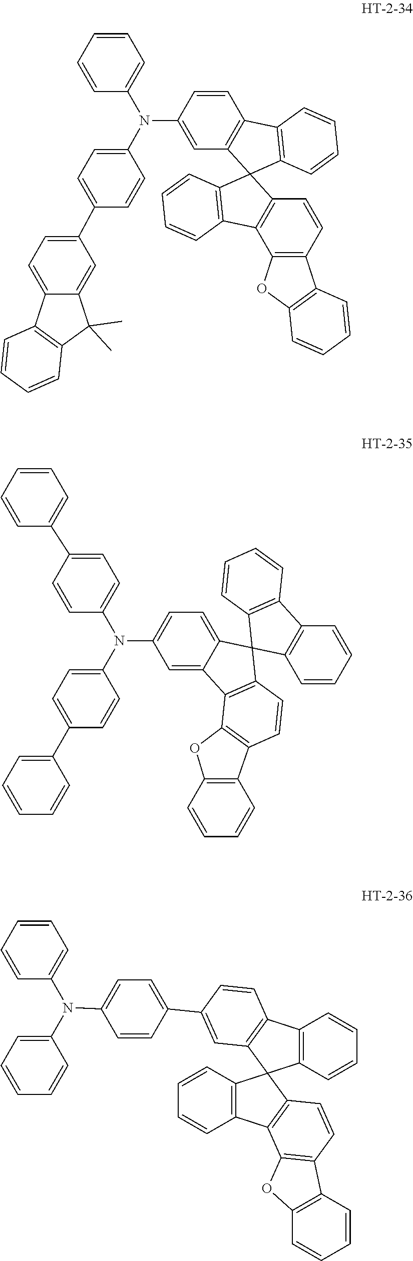

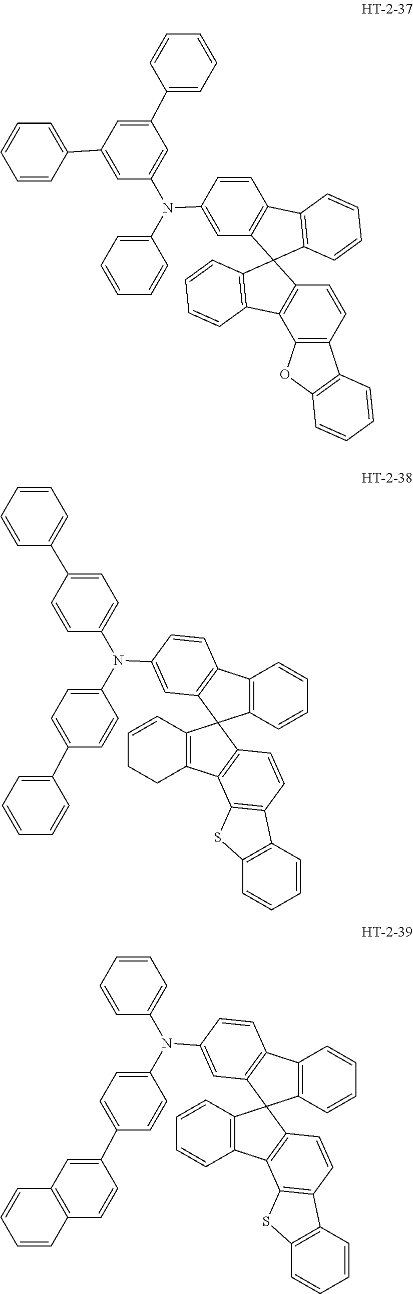 [SMILES: c1ccc(-c2cc(-c3ccccc3)cc(N(c3ccccc3)c3ccc4c(c3)C3(c5ccccc5-4)c4ccccc4-c4c3ccc3c4oc4ccccc43)c2)cc1 ; C1=CC2=C(CC1)c1c(ccc3c1sc1ccccc13)C21c2ccccc2-c2ccc(N(c3ccc(-c4ccccc4)cc3)c3ccc(-c4ccccc4)cc3)cc21 ; c1ccc(N(c2ccc(-c3ccc4ccccc4c3)cc2)c2ccc3c(c2)C2(c4ccccc4-3)c3ccccc3-c3c2ccc2c3sc3ccccc32)cc1]

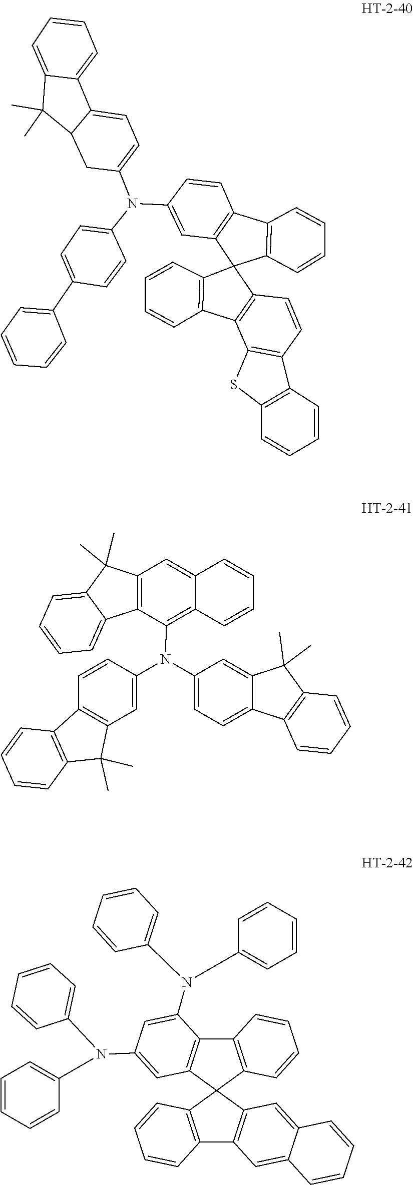 [SMILES: CC1(C)c2ccccc2C2=CC=C(N(c3ccc(-c4ccccc4)cc3)c3ccc4c(c3)C3(c5ccccc5-4)c4ccccc4-c4c3ccc3c4sc4ccccc43)CC21 ; CC1(C)c2ccccc2-c2ccc(N(c3ccc4c(c3)C(C)(C)c3ccccc3-4)c3c4c(cc5ccccc35)C(C)(C)c3ccccc3-4)cc21 ; c1ccc(N(c2ccccc2)c2cc(N(c3ccccc3)c3ccccc3)c3c(c2)C2(c4ccccc4-c4cc5ccccc5cc42)c2ccccc2-3)cc1]

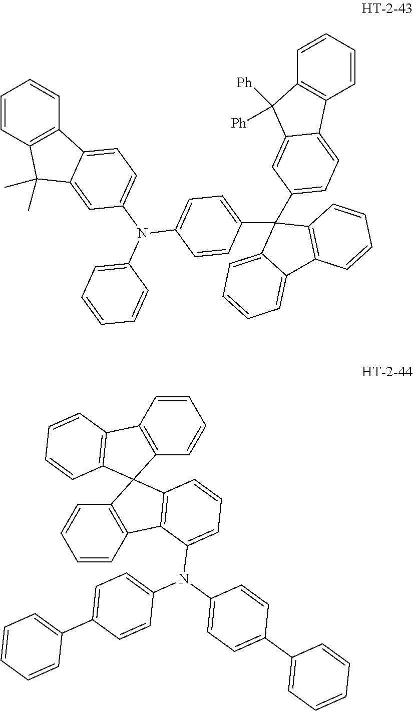 [SMILES: CC1(C)c2ccccc2-c2ccc(N(c3ccccc3)c3ccc(C4(c5ccc6c(c5)C(c5ccccc5)(c5ccccc5)c5ccccc5-6)c5ccccc5-c5ccccc54)cc3)cc21 ; c1ccc(-c2ccc(N(c3ccc(-c4ccccc4)cc3)c3cccc4c3-c3ccccc3C43c4ccccc4-c4ccccc43)cc2)cc1]

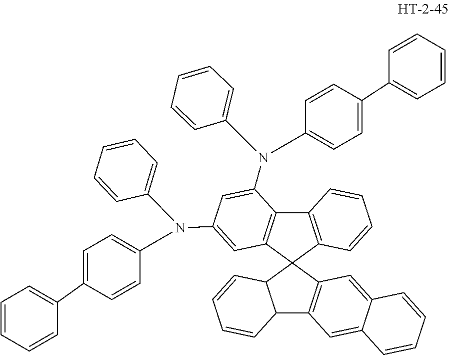 [SMILES: C1=CC2c3cc4ccccc4cc3C3(c4ccccc4-c4c(N(c5ccccc5)c5ccc(-c6ccccc6)cc5)cc(N(c5ccccc5)c5ccc(-c6ccccc6)cc5)cc43)C2C=C1]

The compound represented by formula 1 according to the present disclosure may be produced by a synthetic method known to one skilled in the art, and for example, may be synthesized with reference to the following reaction schemes 1 to 9, but is not limited thereto.

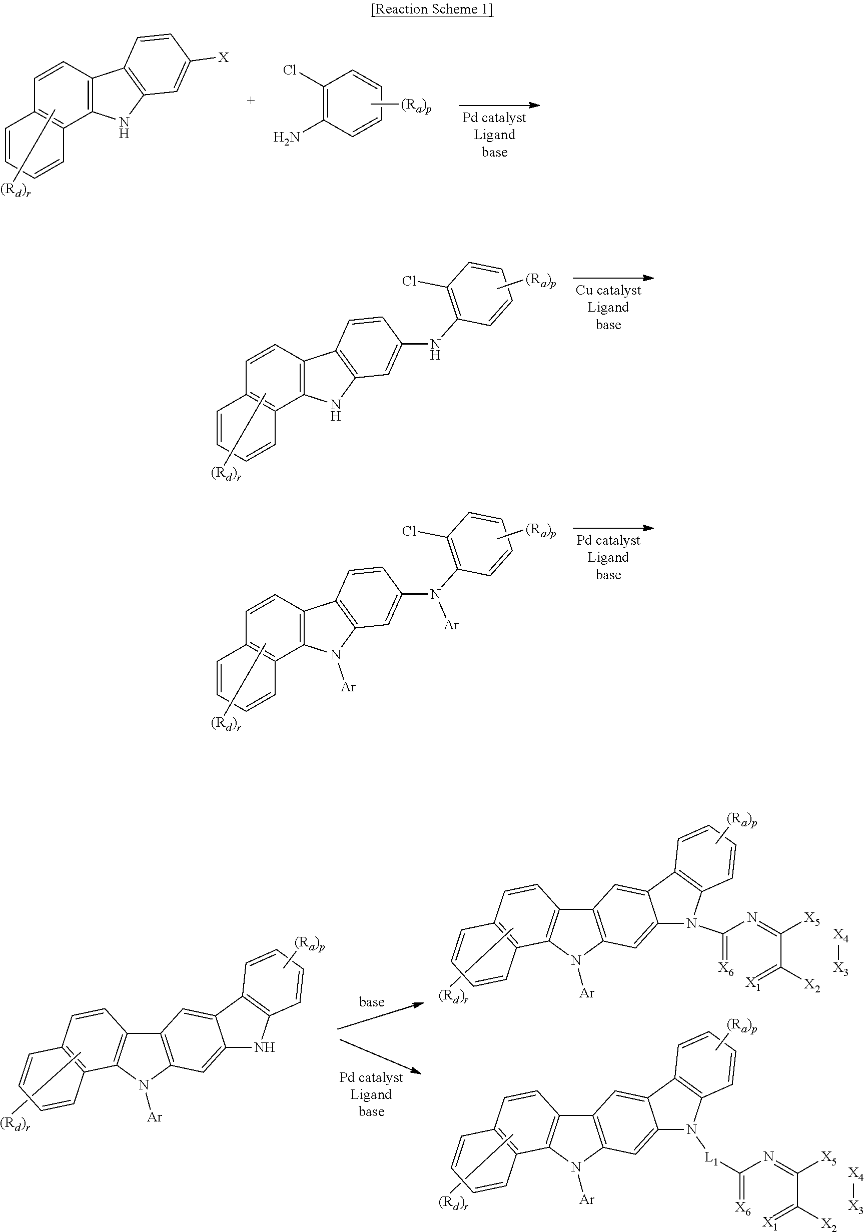

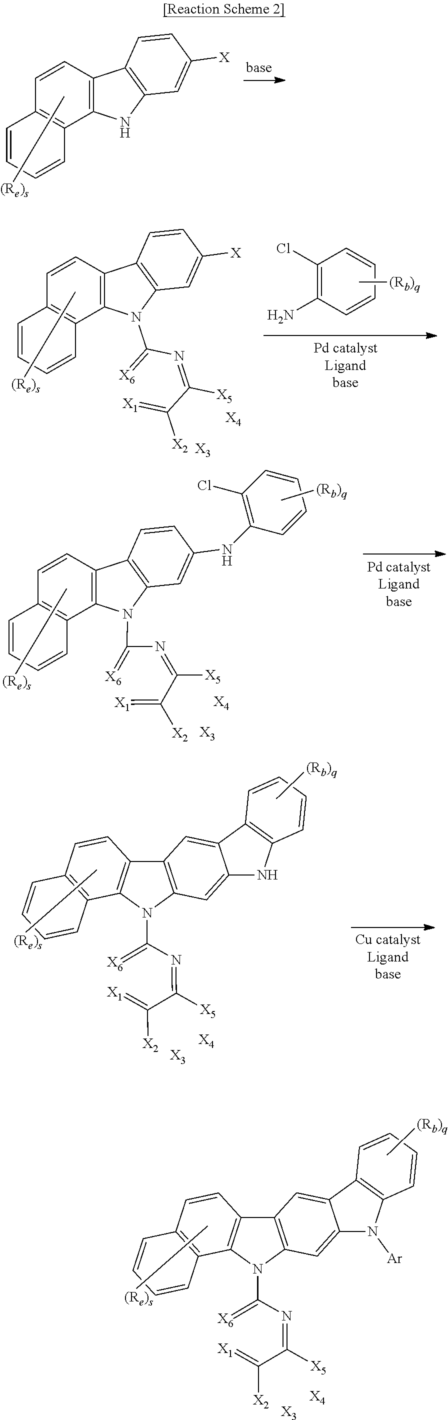

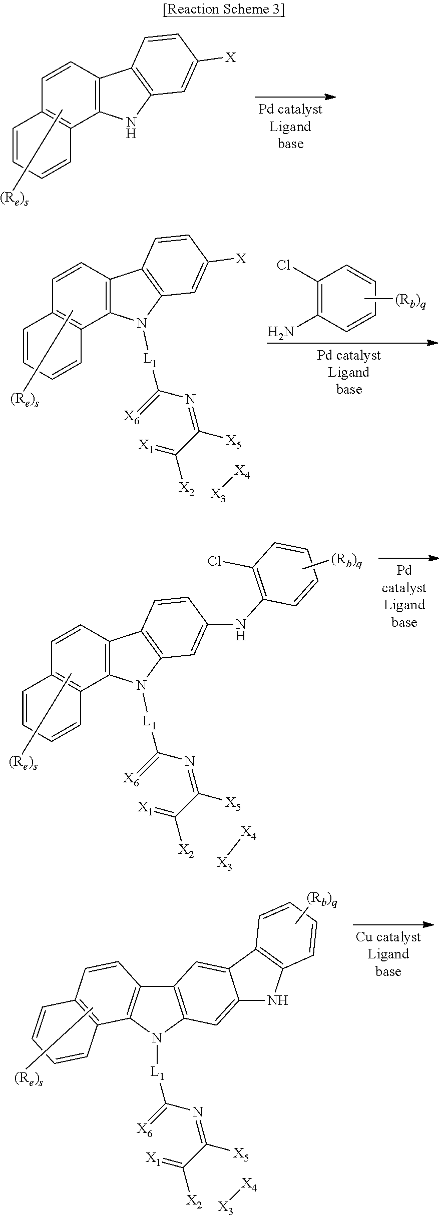

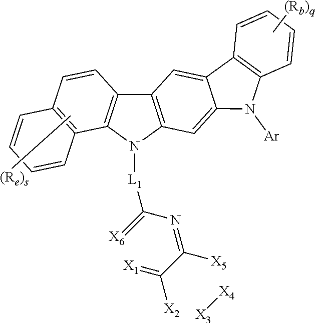

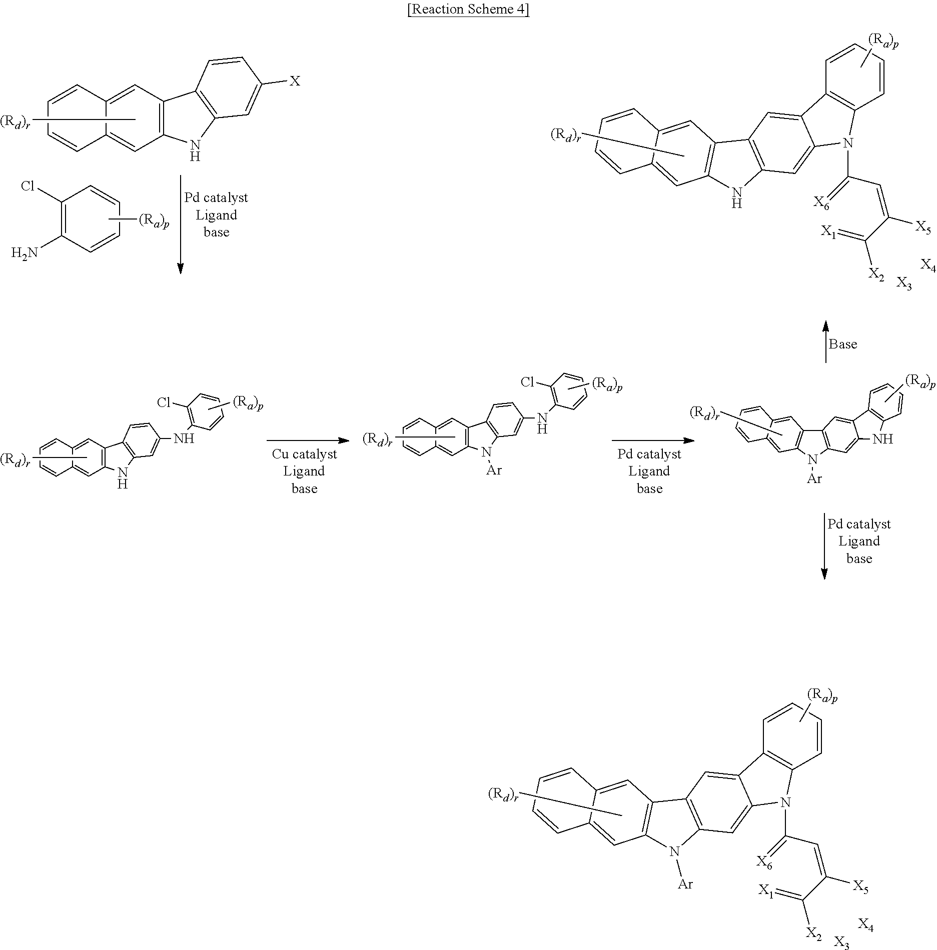

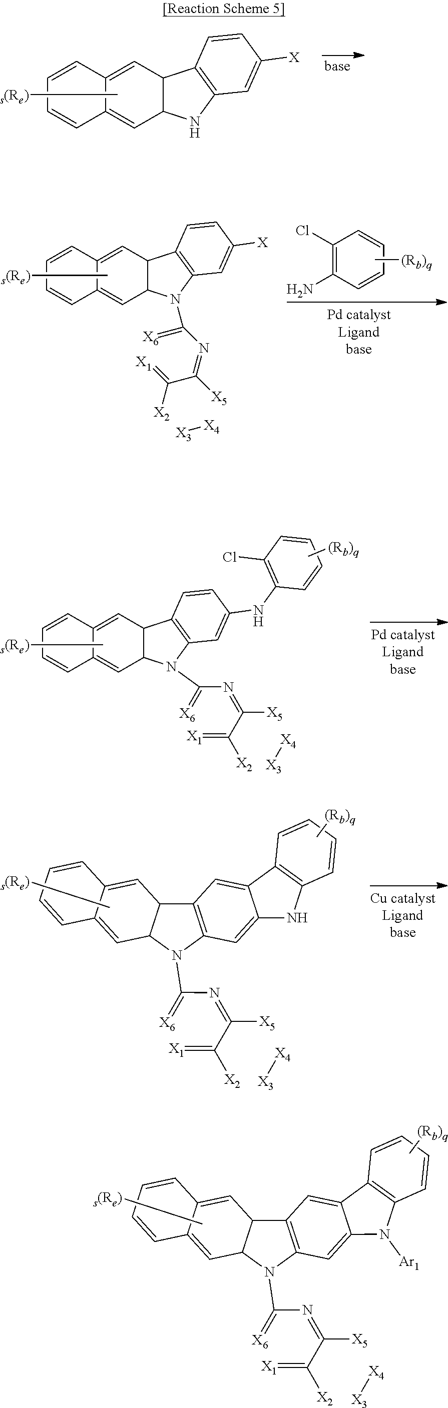

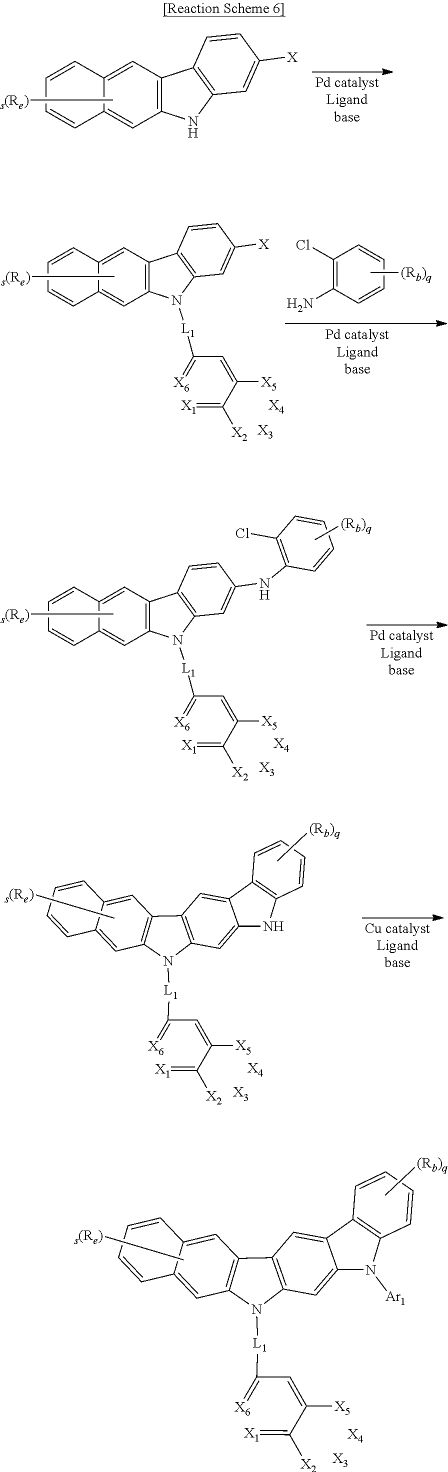

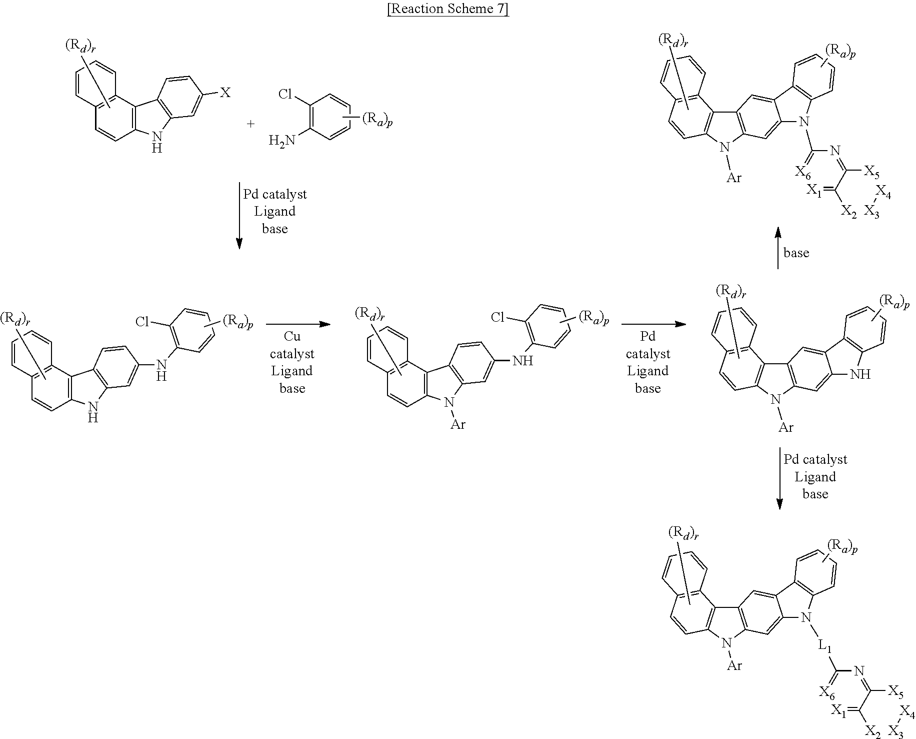

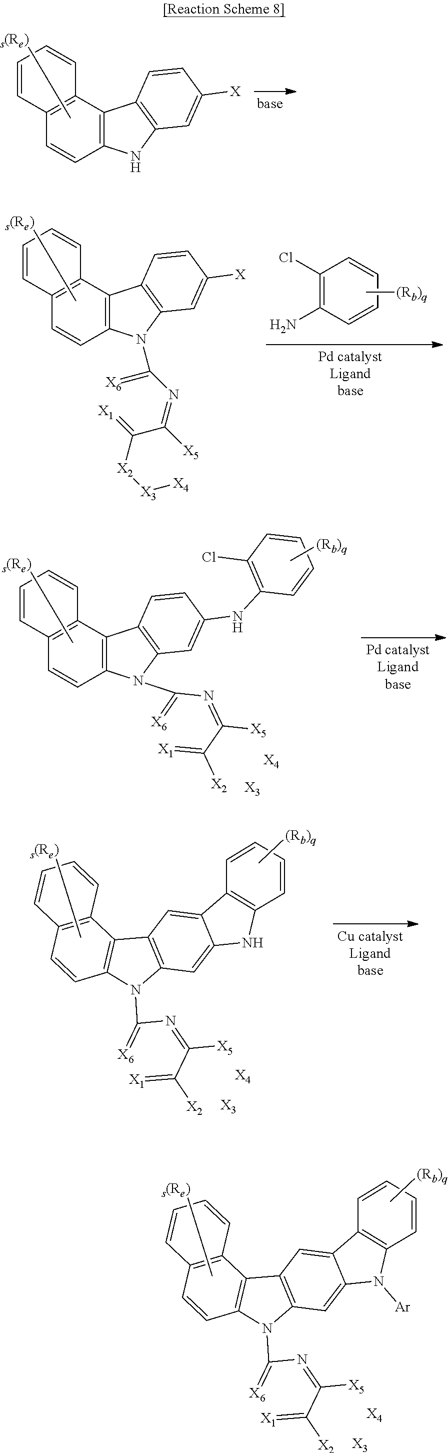

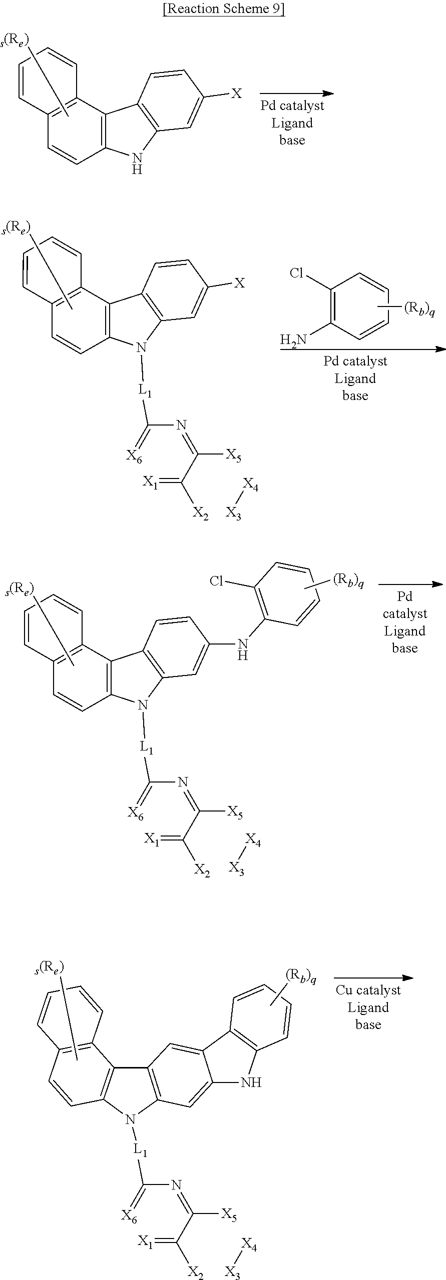

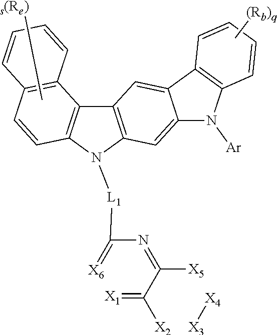

In reaction schemes 1 to 9, L₁, Ar, Rₐ, R_{b}, R_{d}, Rₑ, X₁ to X₆, p, q, r, and s are as defined in formulas 1 to 7, and X is a halogen.

The compound represented by formula 11 according to the present disclosure may be produced by a synthetic method known to one skilled in the art, and for example, may be synthesized by using or modifying the synthetic methods disclosed in Korean Patent Application Laid-Open Nos. 2014-0104895 A, 2015-0012488 A, and 2015-0066202 A, and Korean Patent No. 1476231 B.

The dopant comprised in the organic electroluminescent device according to the present disclosure may include at least one phosphorescent or fluorescent dopant, and preferably, at least one phosphorescent dopant. The phosphorescent dopant materials comprised in the organic electroluminescent device according to the present disclosure are not particularly limited, but may be selected from metallated complex compounds of iridium (Ir), osmium (Os), copper (Cu), and platinum (Pt), may be preferably selected from ortho-metallated complex compounds of iridium (Ir), osmium (Os), copper (Cu), and platinum (Pt), and may be more preferably an ortho-metallated iridium complex compound.

The dopant comprised in the organic electroluminescent device of the present disclosure may comprise the compound represented by the following formula 101, but is not limited thereto.

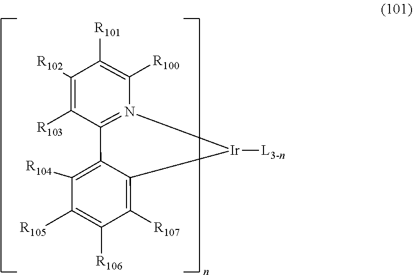

In formula 101, L is selected from the following structures:

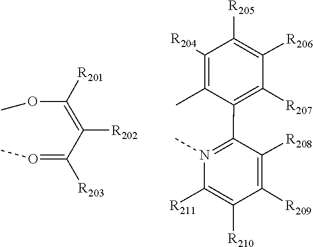

R₁₀₀ to R₁₀₃, each independently, represent hydrogen, deuterium, a halogen, a (C1-C30)alkyl unsubstituted or substituted with a halogen, a substituted or unsubstituted (C3-C30)cycloalkyl, a substituted or unsubstituted (C6-C30)aryl, a cyano, a substituted or unsubstituted (3- to 30-membered)heteroaryl, or a substituted or unsubstituted (C1-C30)alkoxy; or R₁₀₀ to R₁₀₃ may be linked to adjacent R₁₀₀ to R₁₀₃ to form a substituted or unsubstituted fused ring with a pyridine, e.g., a substituted or unsubstituted quinoline, a substituted or unsubstituted isoquinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline; R₁₀₄ to R₁₀₇, each independently, represent hydrogen, deuterium, a halogen, a (C1-C30)alkyl unsubstituted or substituted with a halogen, a substituted or unsubstituted (C3-C30)cycloalkyl, a substituted or unsubstituted (C6-C30)aryl, a substituted or unsubstituted (3- to 30-membered)heteroaryl, a cyano, or a substituted or unsubstituted (C1-C30)alkoxy; or R₁₀₄ to R₁₀₇ may be linked to adjacent R₁₀₄ to R₁₀₇ to form a substituted or unsubstituted fused ring with a benzene, e.g., a substituted or unsubstituted naphthyl, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine; R₂₀₁ to R₂₁₁, each independently, represent hydrogen, deuterium, a halogen, a (C1-C30)alkyl unsubstituted or substituted with a halogen, a substituted or unsubstituted (C3-C30)cycloalkyl, or a substituted or unsubstituted (C6-C30)aryl; or R₂₀₁ to R₂₁₁ may be linked to adjacent R₂₀₁ to R₂₁₁ to form a substituted or unsubstituted fused ring; and n represents an integer of 1 to 3.

Specifically, the dopant compound includes the following compounds, but is not limited thereto.

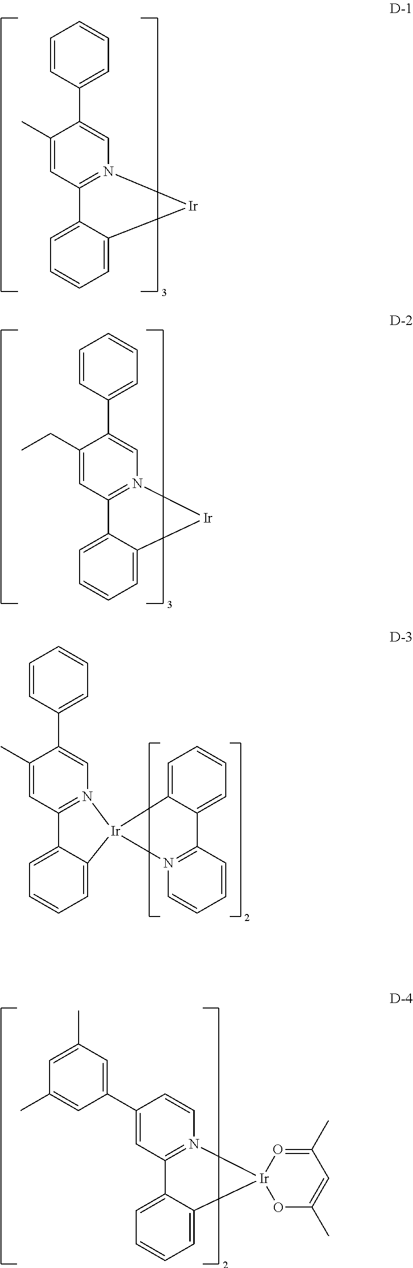

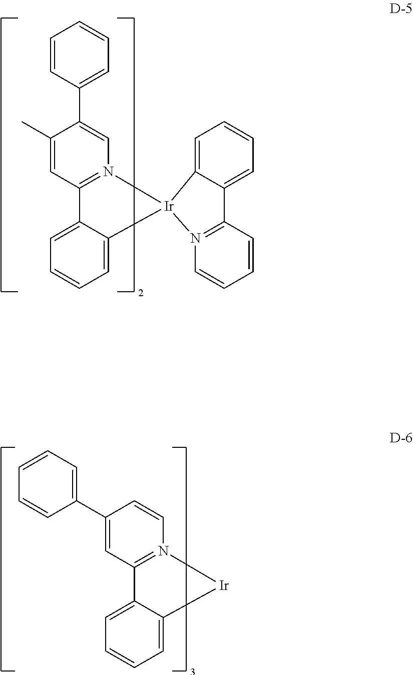

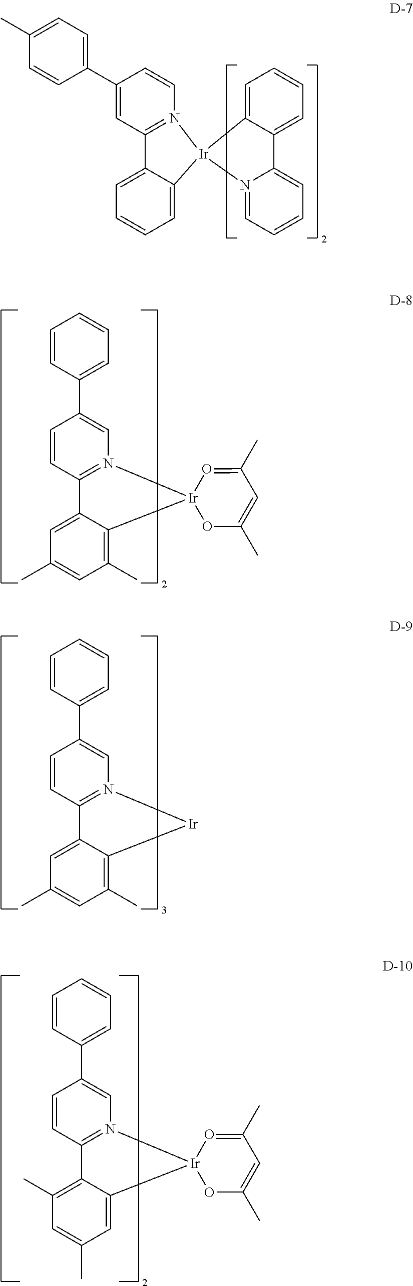

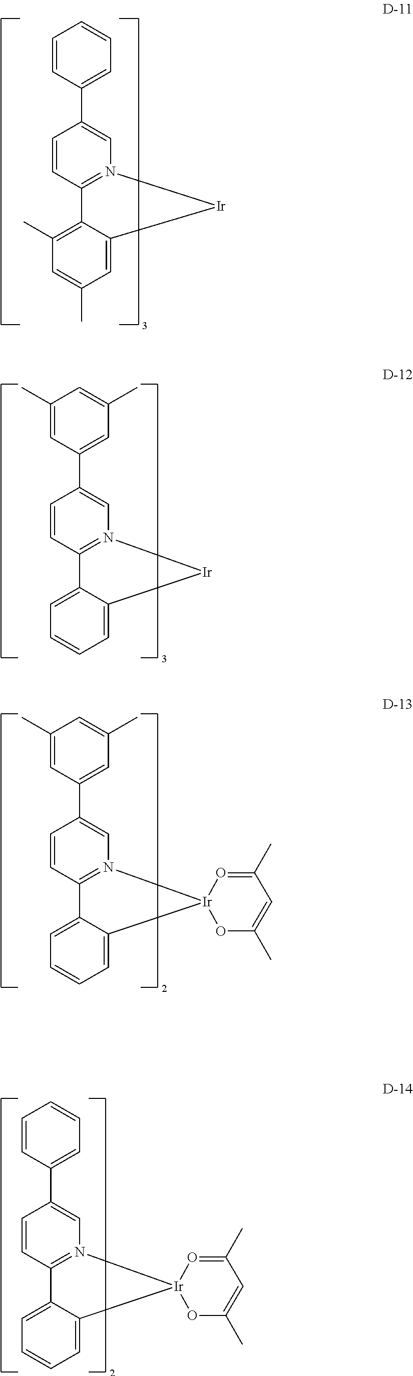

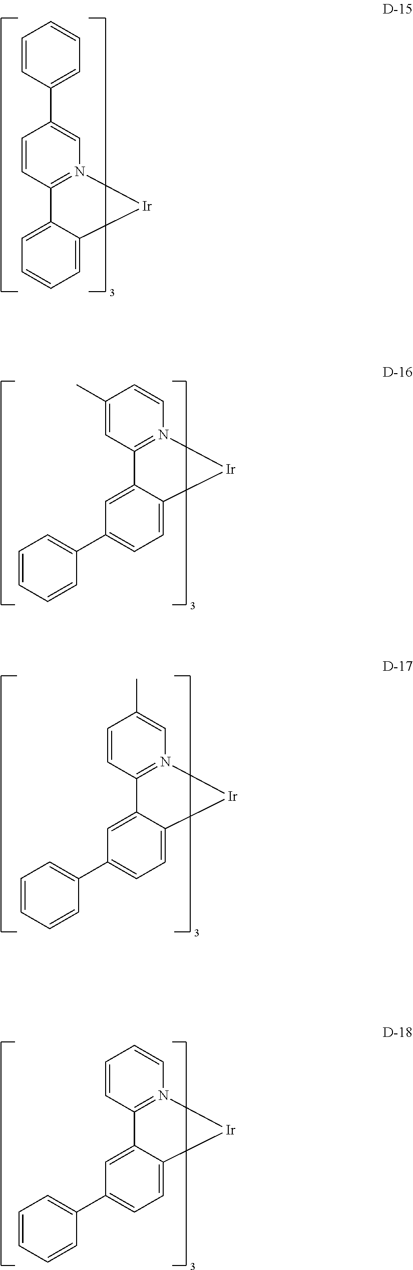

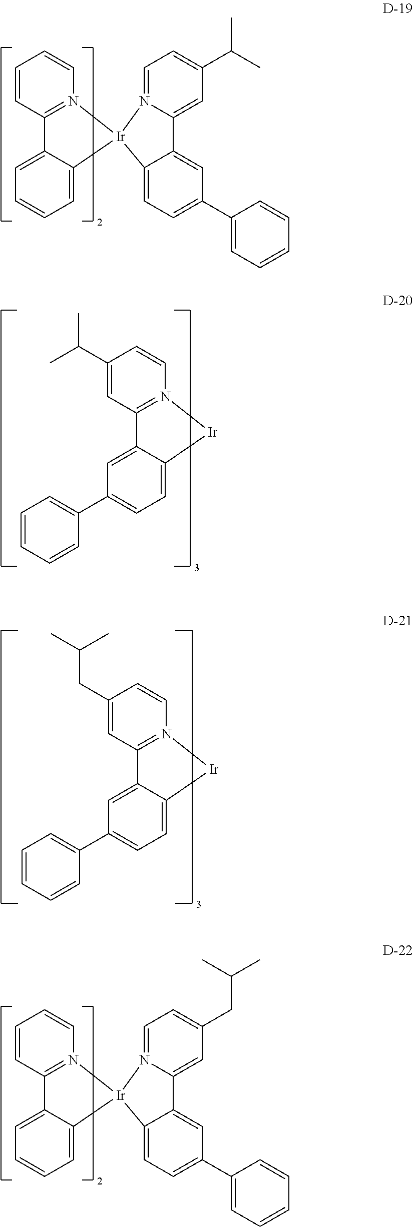

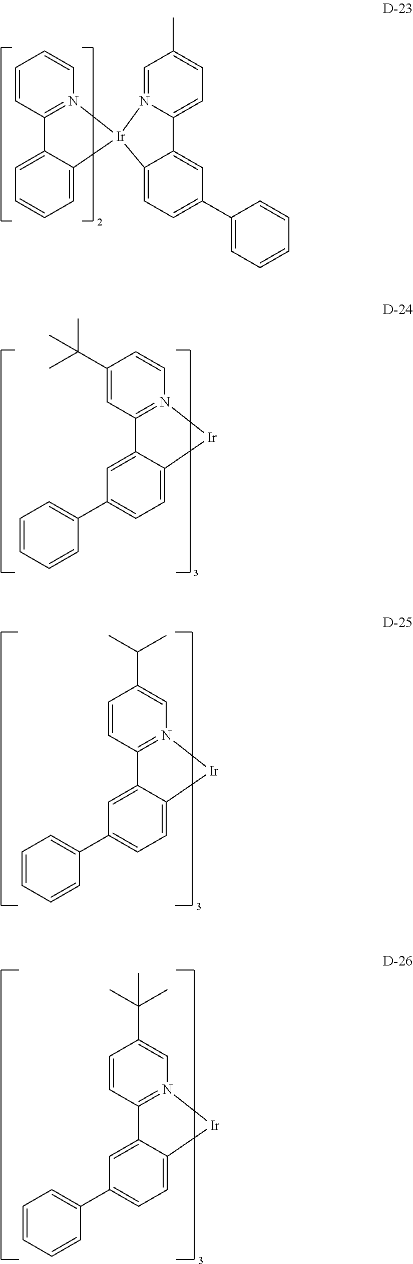

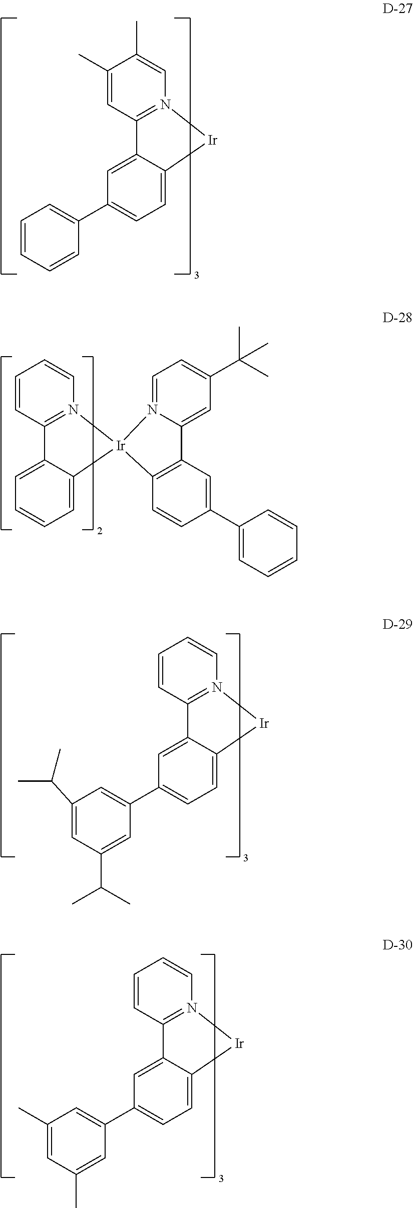

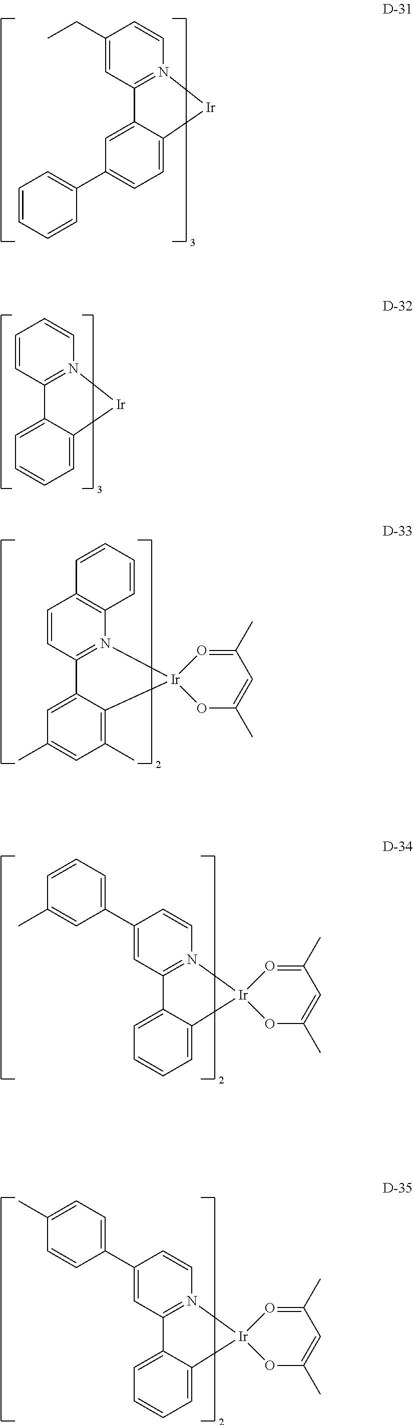

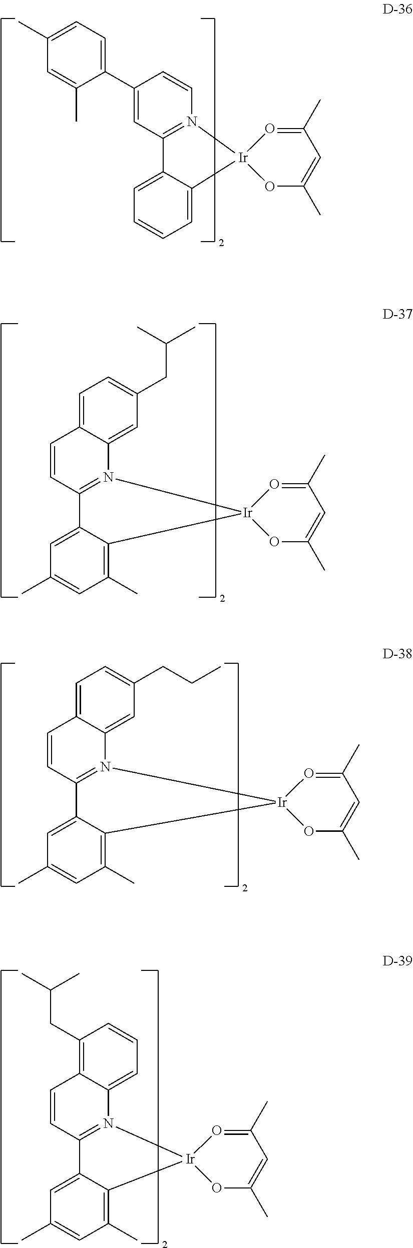

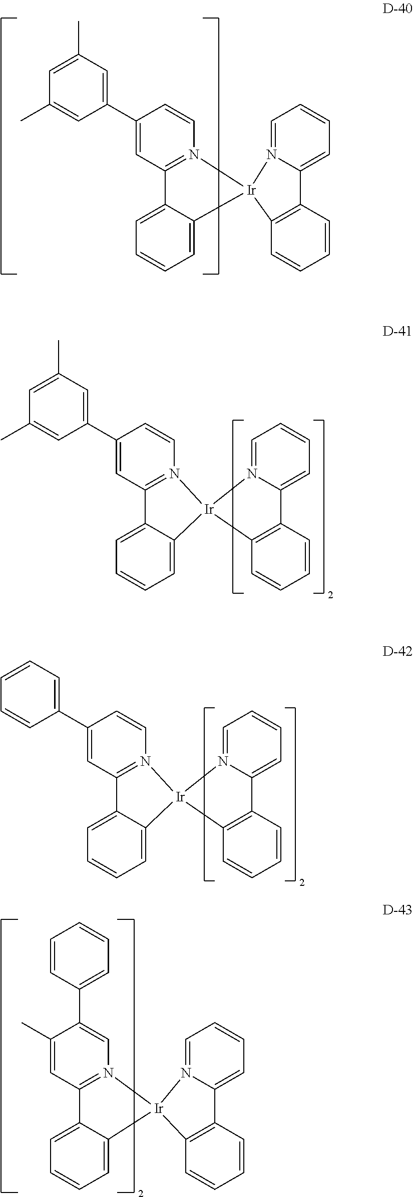

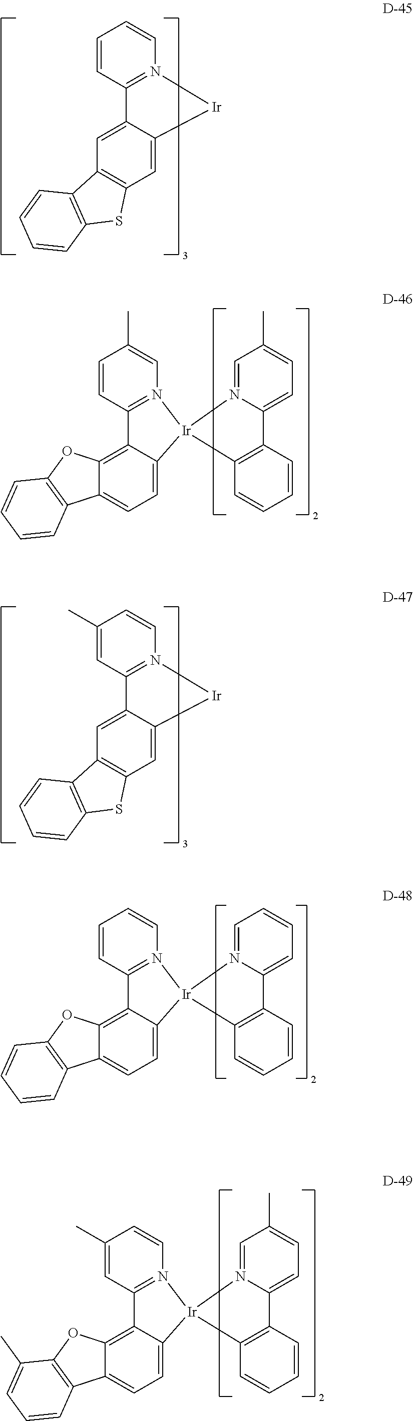

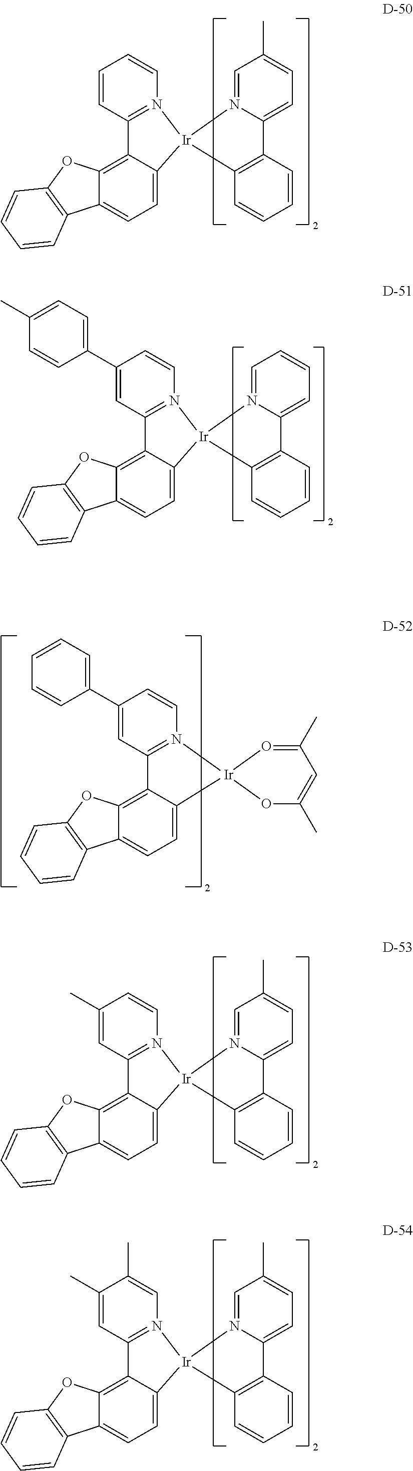

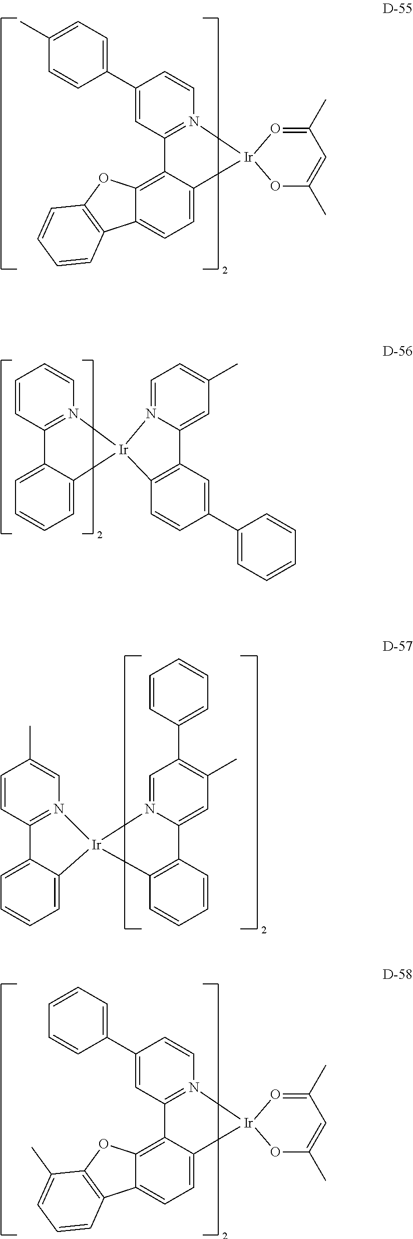

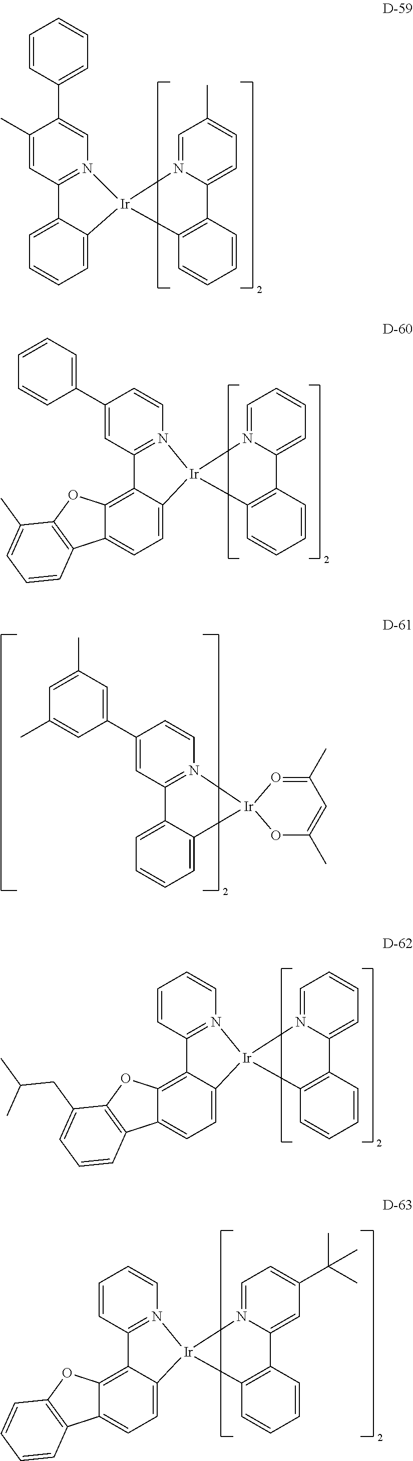

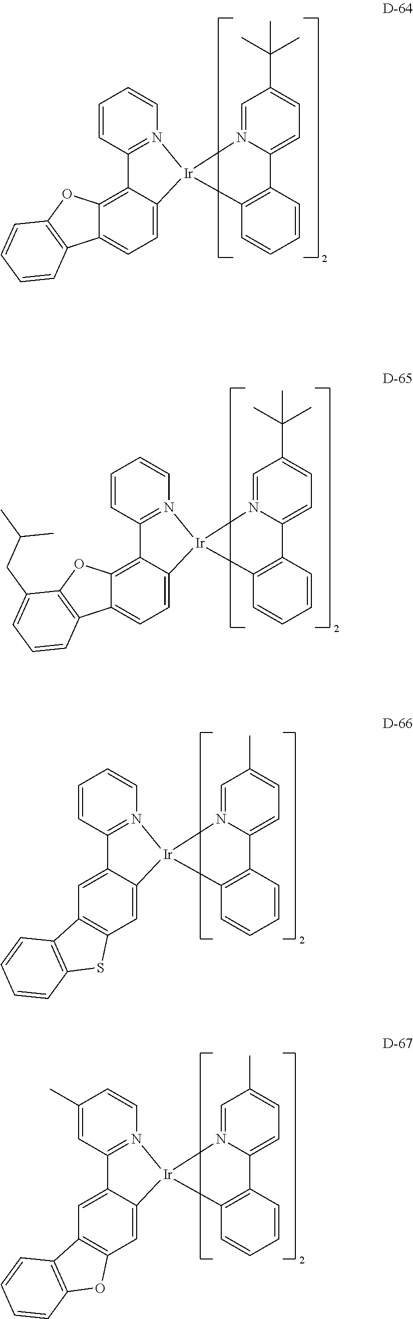

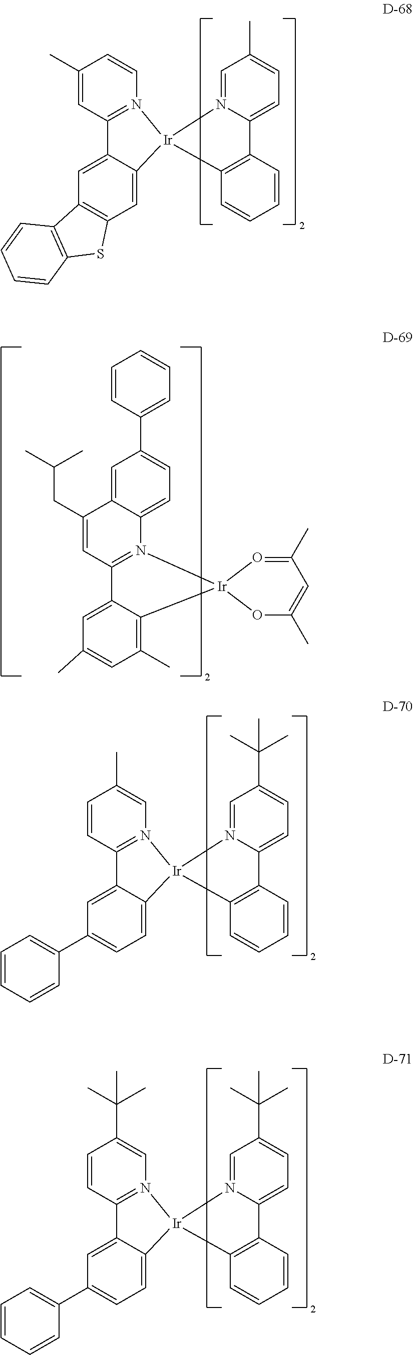

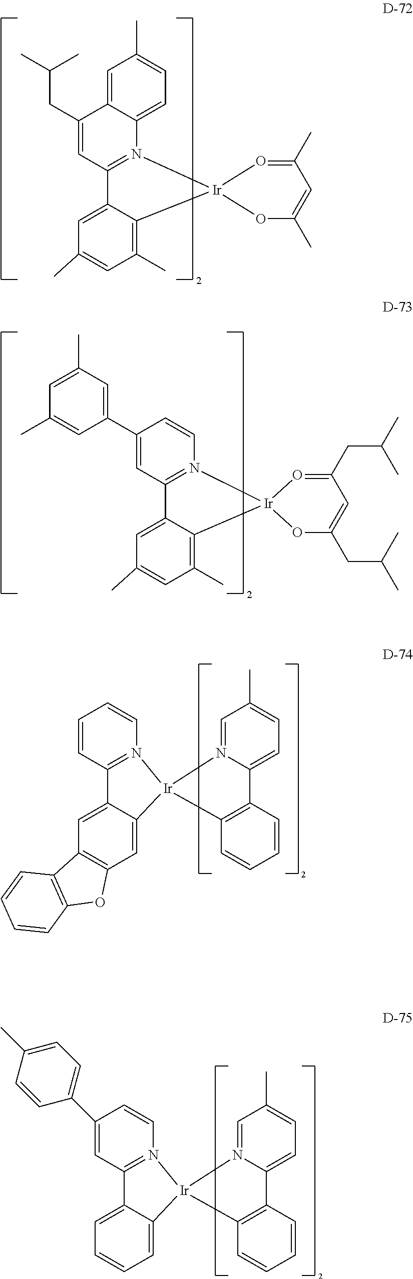

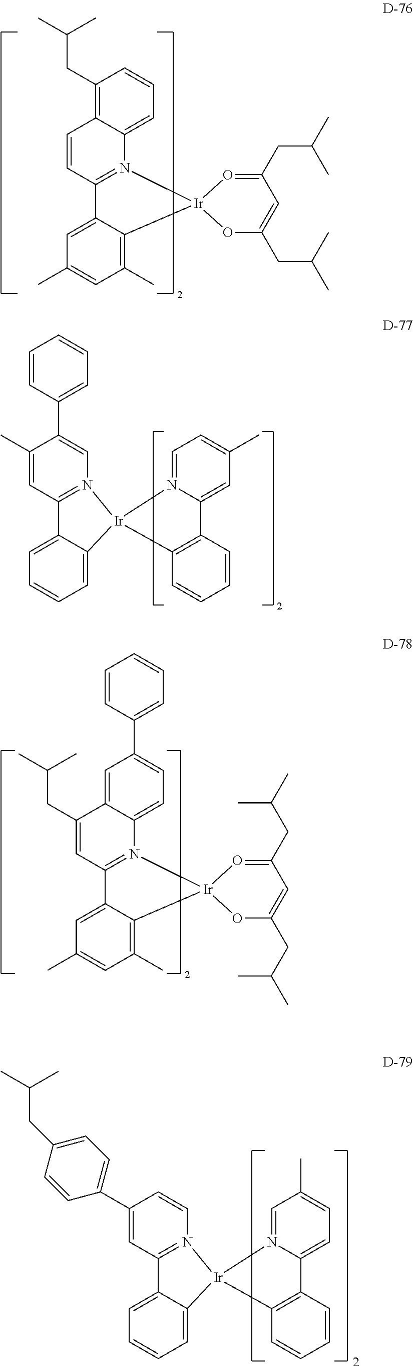

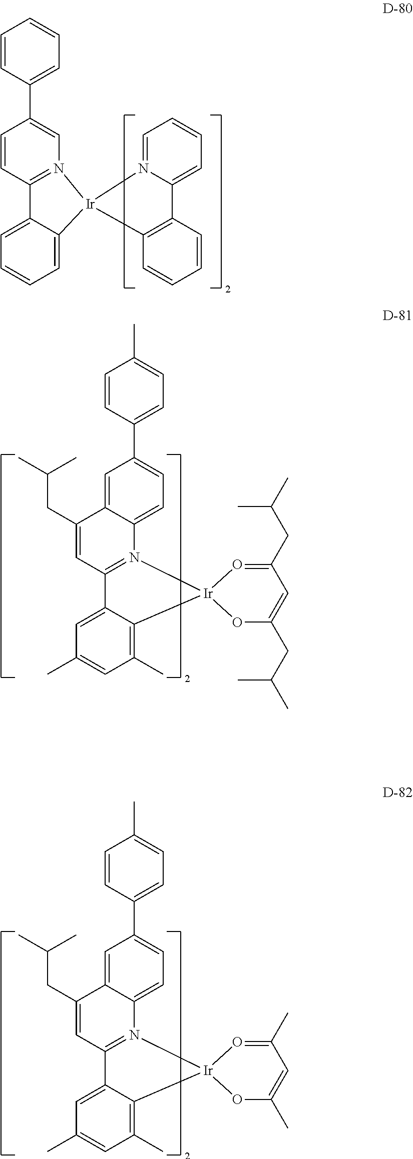

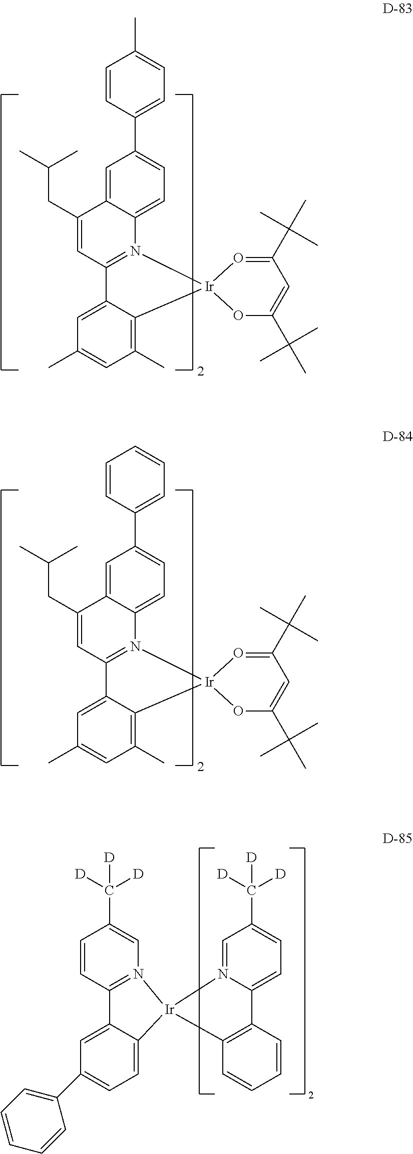

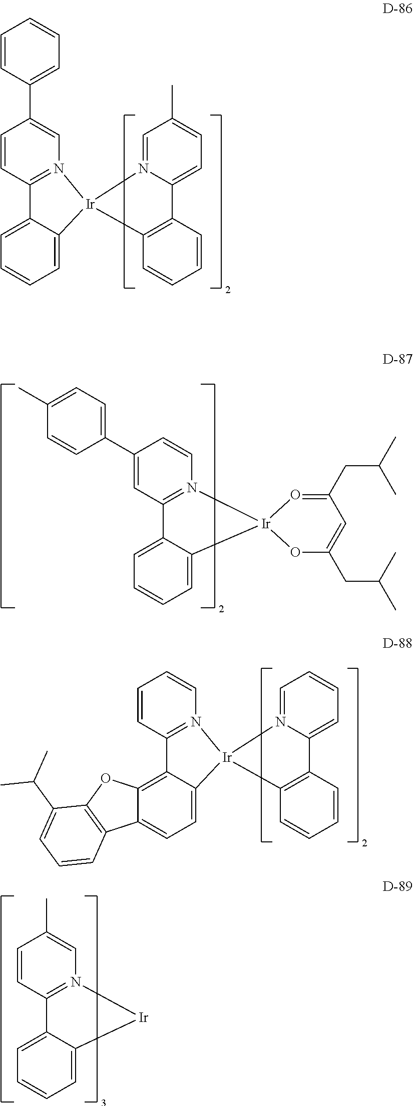

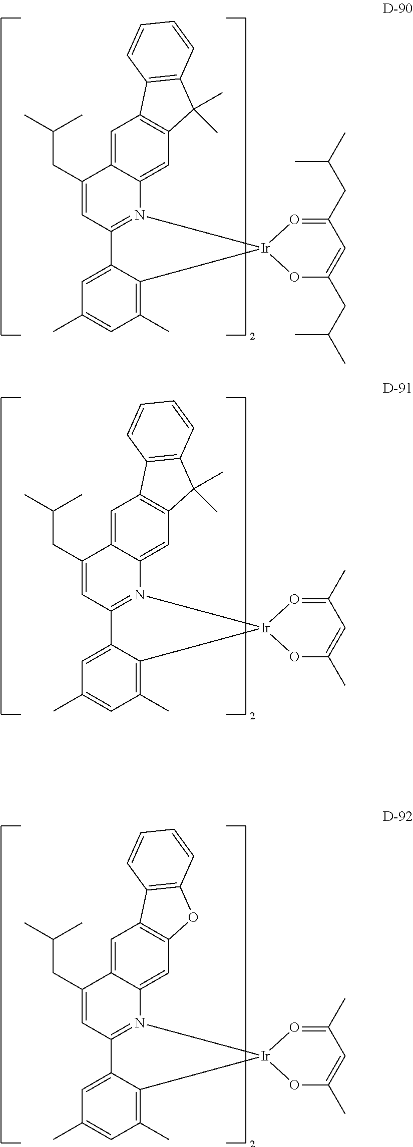

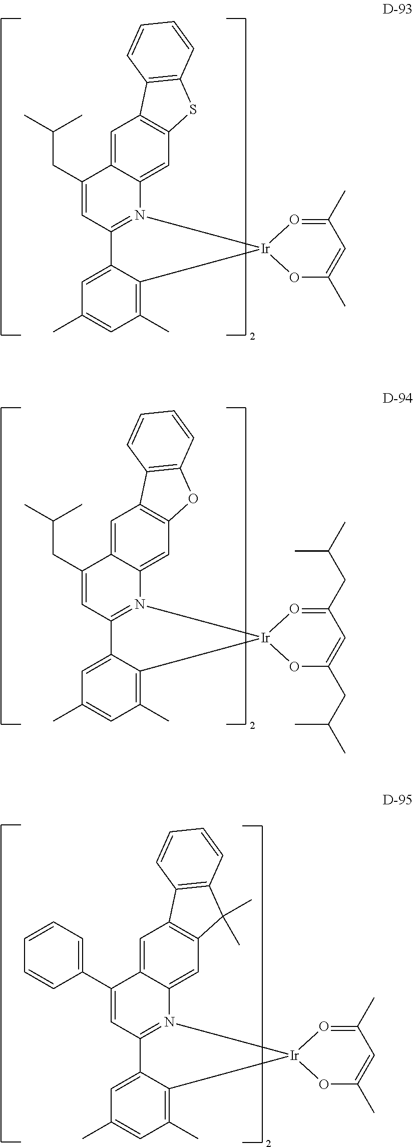

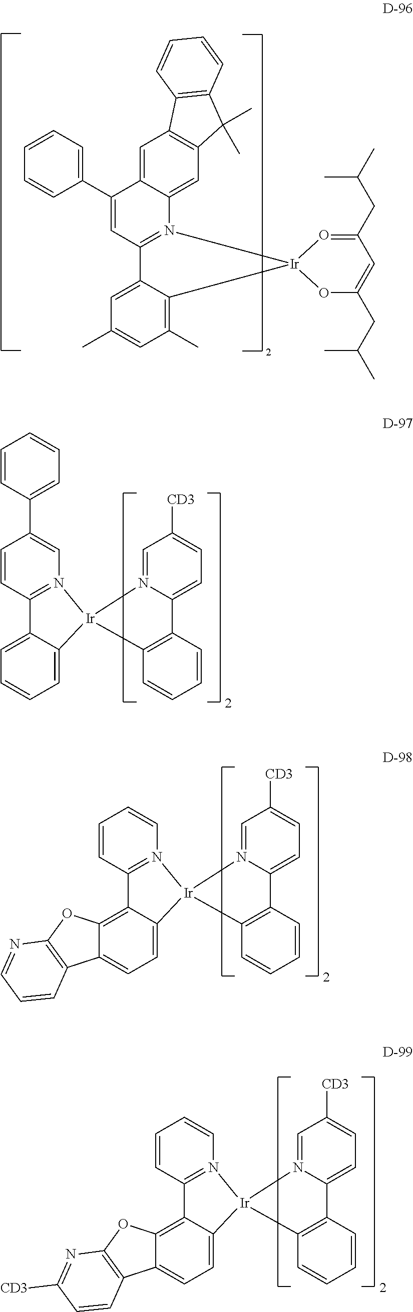

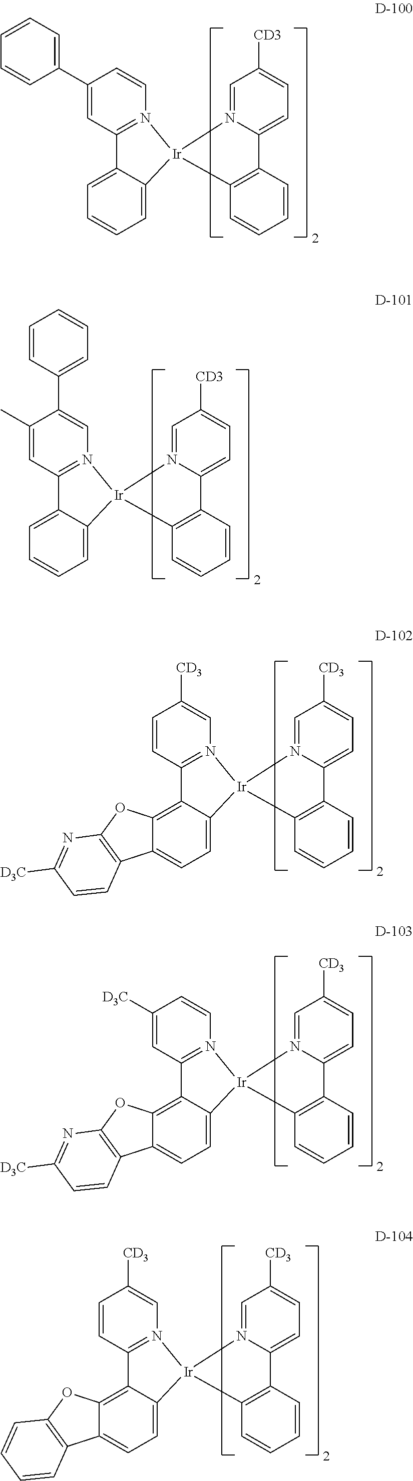

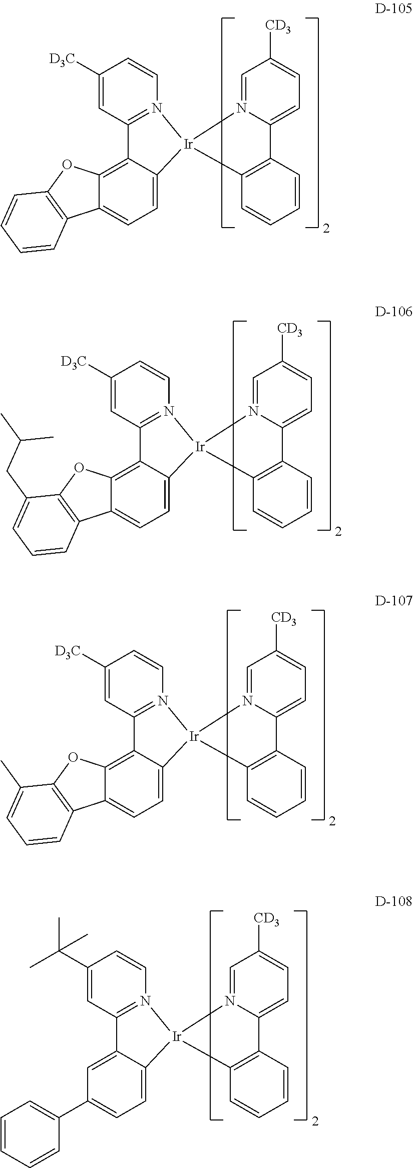

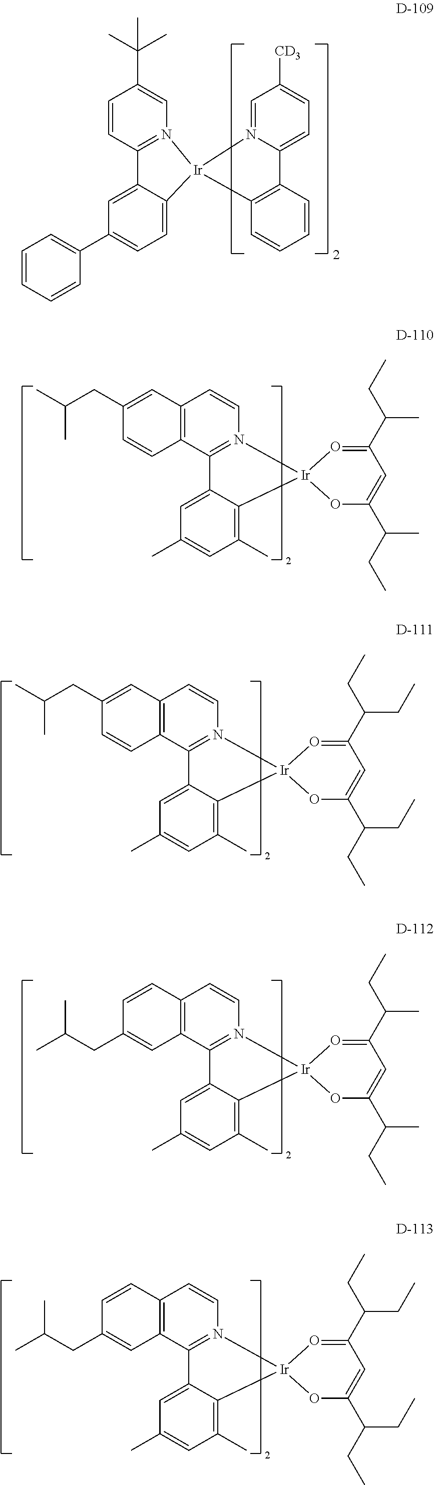

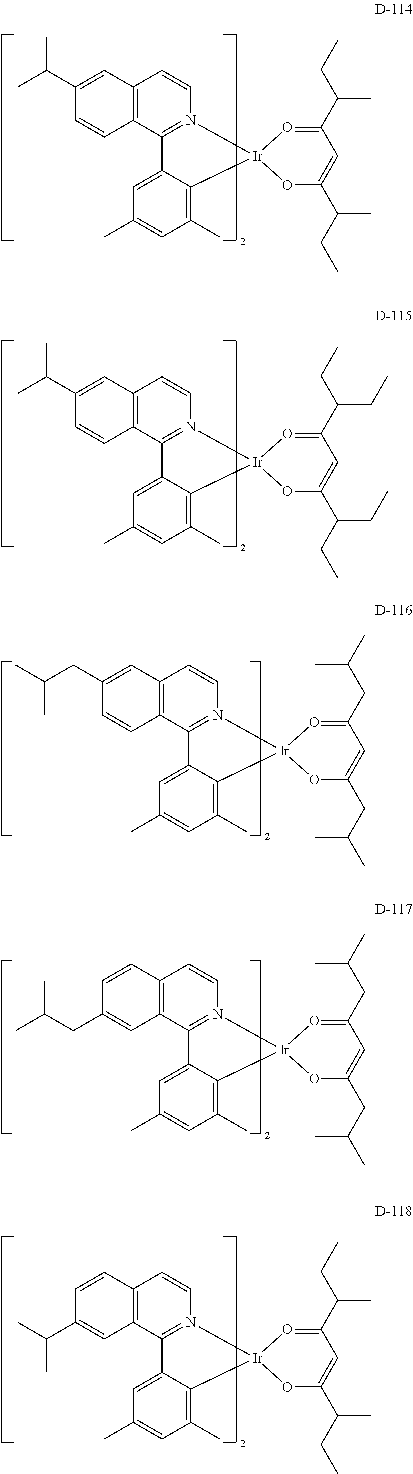

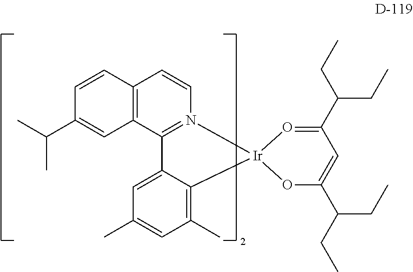

The organic electroluminescent device according to the present disclosure comprises a hole transport zone between a first electrode and a light-emitting layer, wherein the hole transport zone comprises an arylamine derivative containing a fluorene or a fused fluorene, and a HOMO energy level of the arylamine derivative satisfies the following equation 11. According to one embodiment of the present disclosure, the organic electroluminescent device may comprise a first hole transport layer between a first electrode and a light-emitting layer, and a second transport layer between the first hole transport layer and the light-emitting layer, wherein the second transport layer comprises an arylamine derivative containing a fluorene or a fused fluorene, and a HOMO energy level of the arylamine derivative satisfies the following equation 11. The second hole transport layer may be a single layer or a plurality of layers, and may play a role as a hole transport layer, a light-emitting auxiliary layer, a hole auxiliary layer and/or an electron blocking layer.

−5.0 eV≤HOMO≤−4.65 eV (11)

According to one embodiment of the present disclosure, the HOMO energy level of the arylamine derivative may satisfy the following formula 12:

−5.0 eV≤HOMO≤−4.70 eV (12).

If the hole transport zone comprises the compound having a HOMO energy level of less than −5.0, for example, at most −5.1, it is less than the HOMO energy level of the compound represented by formula 1 comprised in the light-emitting layer. As a result, the hole injection is blocked and the driving voltage increases. That is, although the luminous efficiency of a device increases, there is no advantage in terms of power efficiency (lm/W), rather, the power efficiency may decrease, since the driving power increases as much as the luminance efficiency increases. On the other hand, if the hole transport zone comprises the compound having a HOMO energy level more than −4.65, the energy barrier between the layer comprising said compound, for example, a second hole transport layer, and a light-emitting layer highly increases, and thus, rather, the hole injection is blocked. As a result, the luminous efficiency may decrease. According to one embodiment of the present disclosure, the difference between the upper limit value and the lower limit value in the HOMO energy level of the compound comprised in the hole transport zone may be approximately 0.3 eV or less.

By using the organic electroluminescent device of the present disclosure, a display device, for example, for smartphones, tablets, notebooks, PCs, TVs, or vehicles, or a lighting device, for example, an indoor or outdoor lighting device, can be produced.

The organic electroluminescent device of the present disclosure is intended to explain one embodiment of the present disclosure, and is not meant in any way to restrict the scope of the disclosure. The organic electroluminescent device may be embodied in another way.

The HOMO energy levels were measured by using density functional theory (DFT) in Gaussian 03 program of Gaussian Inc. Specifically, the HOMO and LUMO energy levels in the Device Examples and Comparative Examples were extracted from the structure having the lowest energy by optimizing the structures of isomers in all possible forms at the level of B3LYP/6-31g*, and then comparing the calculated energies of the isomers.

Hereinafter, it will be confirmed whether the efficiency of an organic light-emitting diode (OLED) device can be improved by comprising the compound represented by formula 1 in a light-emitting layer and comprising the arylamine derivative containing a fluorene or a fused fluorene having a specific HOMO energy level in a hole transport zone. The OLED device according to the present disclosure will be explained in detail, but is not limited by the following examples.

### Device Examples 1 to 6: Producing an OLED Device According to the Present Disclosure

An OLED device according to the present disclosure was produced as follows: A transparent electrode indium tin oxide (ITO) thin film (10 Ω/sq) on a glass substrate for an OLED device (GEOMATEC CO., LTD., Japan) was subjected to an ultrasonic washing with acetone and isopropanol, sequentially, and then was stored in isopropanol. The ITO substrate was then mounted on a substrate holder of a vacuum vapor deposition apparatus. Compound HI-1 was introduced into a cell of the vacuum vapor deposition apparatus, and then the pressure in the chamber of the apparatus was controlled to 10⁻⁶ torr. Thereafter, an electric current was applied to the cell to evaporate the above-introduced material, thereby forming a first hole injection layer having a thickness of 90 nm on the ITO substrate. Next, compound HI-2 was introduced into another cell of the vacuum vapor deposition apparatus and was evaporated by applying an electric current to the cell, thereby forming a second hole injection layer having a thickness of 5 nm on the first hole injection layer. Compound HT-1 was then introduced into a cell of the vacuum vapor deposition apparatus and was evaporated by applying an electric current to the cell, thereby forming a first hole transport layer having a thickness of 10 nm on the second hole injection layer. The compound shown in Table 1 below was then introduced into another cell of the vacuum vapor deposition apparatus and was evaporated by applying an electric current to the cell, thereby forming a second hole transport layer having a thickness of 60 nm on the first hole transport layer. After forming the hole injection layer and the hole transport layer, a light-emitting layer was formed thereon as follows: Compound H-139 was introduced into one cell of the vacuum vapor deposition apparatus as a host, and compound D-39 was introduced into another cell as a dopant. The two materials were evaporated at a different rate and the dopant was deposited in a doping amount of 2 wt % based on the total amount of the host and the dopant to form a light-emitting layer having a thickness of 40 nm on the second hole transport layer. Next, compound ET-1 and compound EI-1 were introduced into another two cells of the vacuum vapor deposition apparatus and evaporated at a rate of 1:1 to form an electron transport layer having a thickness of 35 nm on the light-emitting layer. After depositing compound EI-1 as an electron injection layer having a thickness of 2 nm on the electron transport layer, an AI cathode having a thickness of 80 nm was deposited on the electron injection layer by another vacuum vapor deposition apparatus. Thus, an OLED device was produced.

### Comparative Example 1: Producing an OLED Device not According to the Present Disclosure

An OLED device was produced in the same manner as in Device Example 1, except that the compound shown in Table 1 below was used in the second hole transport layer.

### Comparative Example 2: Producing an OLED Device not According to the Present Disclosure

An OLED device was produced in the same manner as in Device Example 3, except that compound C-1 was used as the host of the light-emitting layer.

The compounds used in Device Examples 1 to 6 and Comparative Examples 1 and 2 are as follows.

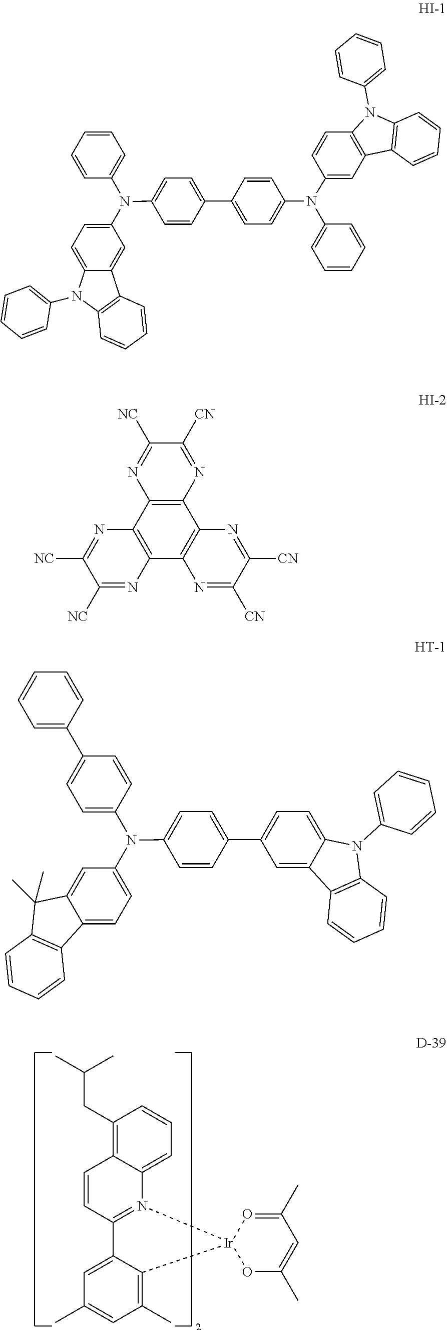

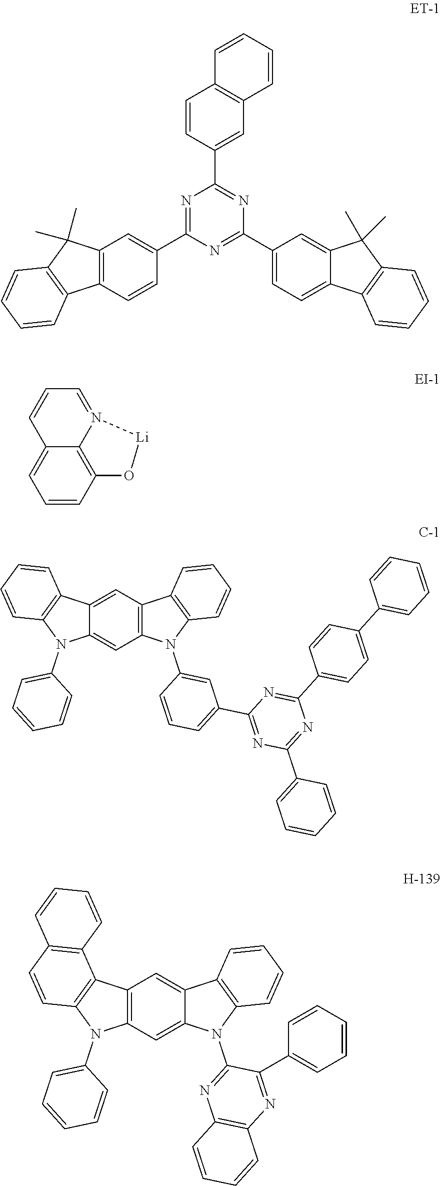

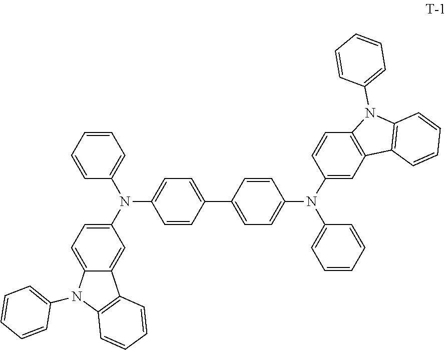 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The driving voltage, luminous efficiency, and CIE color coordinates at a luminance of 1,000 nits, and the lifespan (measured as the percentage to which the luminance is decreased from 100% after 16.7 hours at a luminance of 5,000 nits and a constant current) produced in the OLED devices of Device Examples 1 to 6 and Comparative Examples 1 and 2 are provided in Table 1 below.

TABLE 1

| | Second Hole | | | | | | |
|---|---|---|---|---|---|---|---|
| | Transport | | Voltage | Efficiency | CIE | | |
| | Layer | Host | (V) | (cd/A) | x | y | Lifespan |
| Device Example 1 | HT-2-1 | H-139 | 3.5 | 26.0 | 0.666 | 0.334 | 99.1 |
| Device Example 2 | HT-2-17 | | 3.1 | 26.4 | 0.667 | 0.333 | 99.4 |
| Device Example 3 | HT-2-19 | | 3.0 | 25.6 | 0.666 | 0.334 | 99.4 |
| Device Example 4 | HT-2-20 | | 2.9 | 25.8 | 0.667 | 0.333 | 99.5 |
| Device Example 5 | HT-2-31 | | 3.1 | 27.4 | 0.667 | 0.333 | 99.3 |
| Device Example 6 | HT-2-43 | | 3.5 | 26.9 | 0.667 | 0.333 | 99.4 |
| Comparative | T-1 | | 3.2 | 20.1 | 0.660 | 0.340 | 98.3 |
| Example 1 | | | | | | | |
| Comparative | HT-2-19 | C-1 | 2.8 | 15.7 | 0.667 | 0.331 | 99.9 |
| Example 2 | | | | | | | |

The HOMO energy levels of the compounds comprised in the second hole transport layer of Device Examples 1 to 6 and Comparative Examples 1 and 2 are provided in Table 2 below.

TABLE 2

| | Device | Device | Device | Device | Device | Device | |
|---|---|---|---|---|---|---|---|
| | Example | Example | Example | Example | Example | Example | Comparative |
| | 1 | 2 | 3 | 4 | 5 | 6 | Example 1 |
| Second | HT-2-1 | HT-2-17 | HT-2-19 | HT-2-20 | HT-2-31 | HT-2-43 | T-1 |
| Hole | | | | | | | |
| Transport | | | | | | | |
| Layer | | | | | | | |
| HOMO | −4.798 | −4.752 | −4.748 | −4.828 | −4.859 | −4.773 | −4.469 |
| Energy | | | | | | | |
| Level | | | | | | | |
| (eV) | | | | | | | |

From Tables 1 and 2, it can be seen that Device Example 3 comprising the benzoindolocarbazole derivative of the present disclosure as a host has significantly improved luminous efficiency, while maintaining driving voltage and lifespan characteristics in equivalent or similar levels, compared to Comparative Example 2 comprising the indolocarbazole derivative as a host. Further, it can be confirmed that Device Example 3 comprising the compound having a specific HOMO energy level of the present disclosure in a hole transport zone has significantly improved luminous efficiency, while maintaining driving voltage and lifespan characteristics at equivalent or similar levels, compared to Comparative Example 1.

1. An organic electroluminescent device comprising a first electrode, a second electrode facing the first electrode, a light-emitting layer between the first electrode and the second electrode, and a hole transport zone between the first electrode and the light-emitting layer, wherein the light-emitting layer comprises a compound represented by the following formula 1: 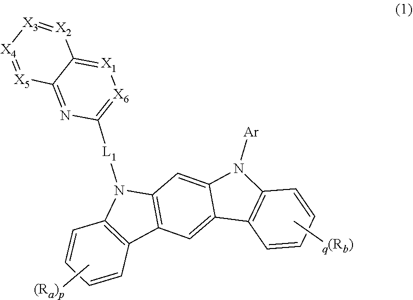
wherein,
L₁ represents a single bond, a substituted or unsubstituted (C6-C30)arylene, or a substituted or unsubstituted (5- to 30-membered)heteroarylene,
X₁ to X₆, each independently, represent N or CR_{c}, with a proviso that at least one of X₁ to X₆ represents N,
Ar represents a substituted or unsubstituted (C6-C30)aryl, or a substituted or unsubstituted (5- to 30-membered)heteroaryl,
Rₐ to R_{c}, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR_{f}R_{g}, —SiRₕRᵢRⱼ, —SRₖ, —ORᵢ, a cyano, a nitro, or a hydroxyl, with a proviso that adjacent two Rₐ's or adjacent two R_{b}'s, each independently, are linked to each other for at least one pair of the adjacent two Rₐ's and the adjacent two R_{b}'s to form at least one substituted or unsubstituted benzene ring,
R_{f} to Rᵢ, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (3- to 30-membered) alicyclic or aromatic ring, or a combination thereof, whose carbon atom(s) may be replaced with at least one heteroatom selected from nitrogen, oxygen, and sulfur,
p and q, each independently, represent an integer of 1 to 4, in which if p and q, each independently, are an integer of 2 or more, each of Rₐ and R_{b} may be the same or different, and
the heteroaryl(ene) or the heterocycloalkyl contains at least one heteroatom selected from B, N, O, S, Si, and P; and
the hole transport zone comprises an arylamine derivative containing a fluorene or a fused fluorene, and the HOMO energy level of the arylamine derivative satisfies the following equation 11:
−5.0 eV ≤HOMO ≤−4.65 eV (11).

2. The organic electroluminescent device according to claim 1, wherein formula 1 is represented by any one of the following formulas 2 to 7: 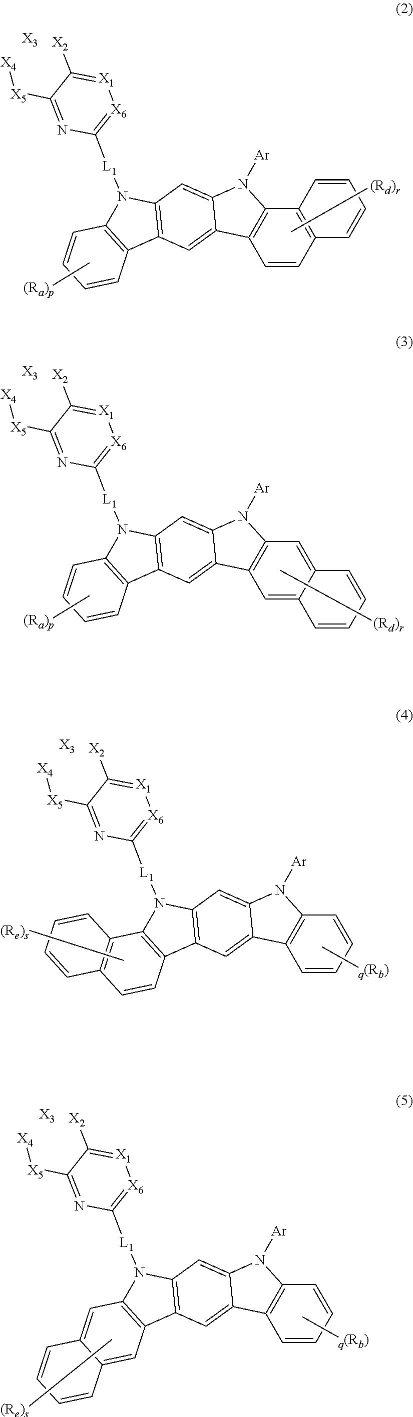 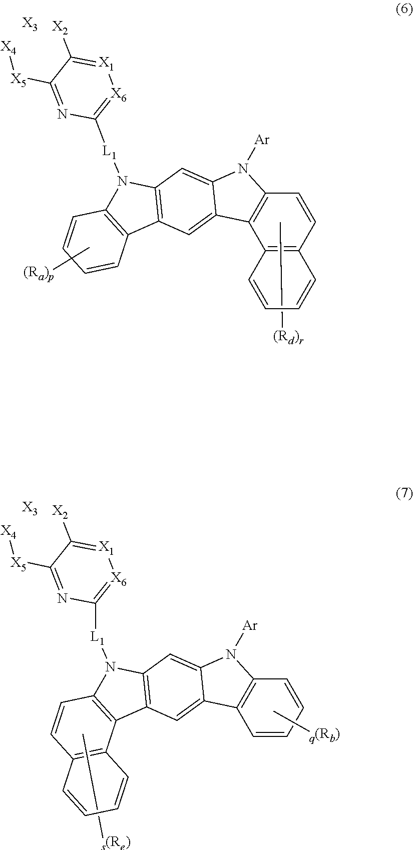
wherein,
L₁, Ar, Rₐ, R_{b}, X₁ to X₆, p and q are as defined in claim 1,
R_{d} and Rₑ, each independently, are identical to the definition of Rₐ, and
r and s, each independently, represent an integer of 1 to 6, in which if r and s, each independently, are an integer of 2 or more, each of R_{d} and Rₑ may be the same or different.

3. The organic electroluminescent device according to claim 1, wherein 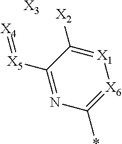
of formula 1 represents a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl, in which * represents a bonding site with L₁.

4. The organic electroluminescent device according to claim 1, wherein the arylamine derivative comprises a compound represented by the following formula 11: 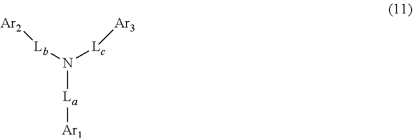
wherein,
Ar₁ to Ar₃, each independently, represent a substituted or unsubstituted (C6-C30)aryl, or a substituted or unsubstituted (5- to 30-membered)heteroaryl, with a proviso that in at least one of Ar₁ to Ar₃ is selected from the following formulas: 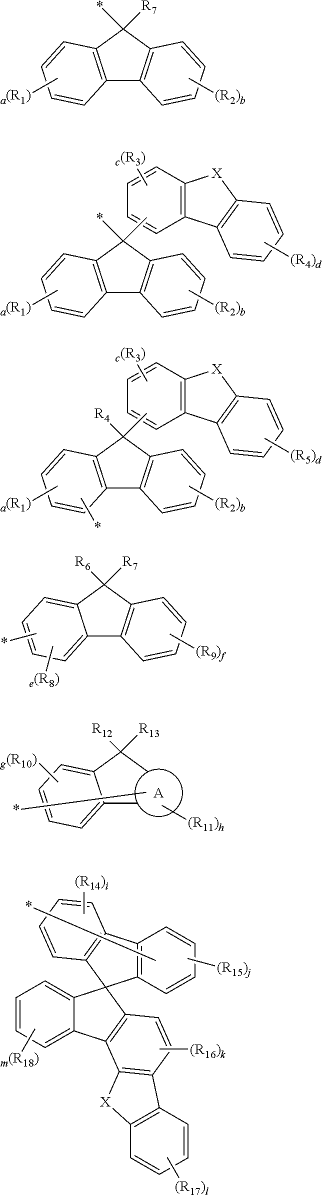 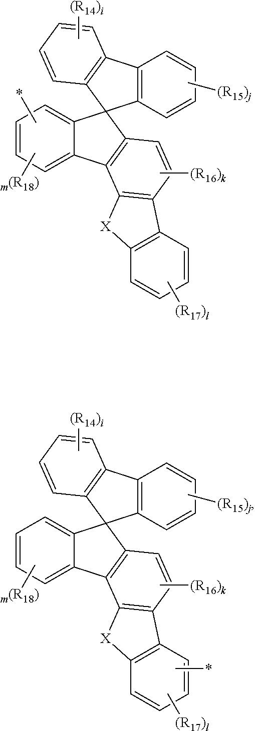
Lₐ to L_{c}, each independently, represent a single bond, or a substituted or unsubstituted (C6-C30)arylene,
X, each independently, represents O, S, or CR₁₉R₂₀,
A ring represents a substituted or unsubstituted C10 aryl,
R₁ to R₂₀, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₂₁R₂₂, —SiR₂₃R₂₄R₂₅, —SR₂₆, —OR₂₇, a cyano, a nitro, or a hydroxyl; or may be linked to an adjacent substituent to form a substituted or unsubstituted, mono- or polycyclic, (3- to 30-membered) alicyclic or aromatic ring, or a combination thereof, in which the ring includes a spiro structure and carbon atom(s) of the formed ring may be replaced with at least one heteroatom selected from nitrogen, oxygen, and sulfur,
R₂₁ to R₂₇, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (3- to 30-membered) alicyclic or aromatic ring, or a combination thereof, whose carbon atom(s) may be replaced with at least one heteroatom selected from nitrogen, oxygen, and sulfur,
a, b, d, f, g, i, j, I, and m, each independently, represent an integer of 1 to 4; c and e, each independently, represent an integer of 1 to 3; h represents an integer of 1 to 6; and k represents 1 or 2, in which if a to m, each independently, are an integer of 2 or more, each of R₁ to R₁₇ may be the same or different, and
the heteroaryl or the heterocycloalkyl contains at least one heteroatom selected from B, N, O, S, Si, and P.

5. The organic electroluminescent device according to claim 4, wherein formula 11 is represented by any one of the following formulas 12 to 18: 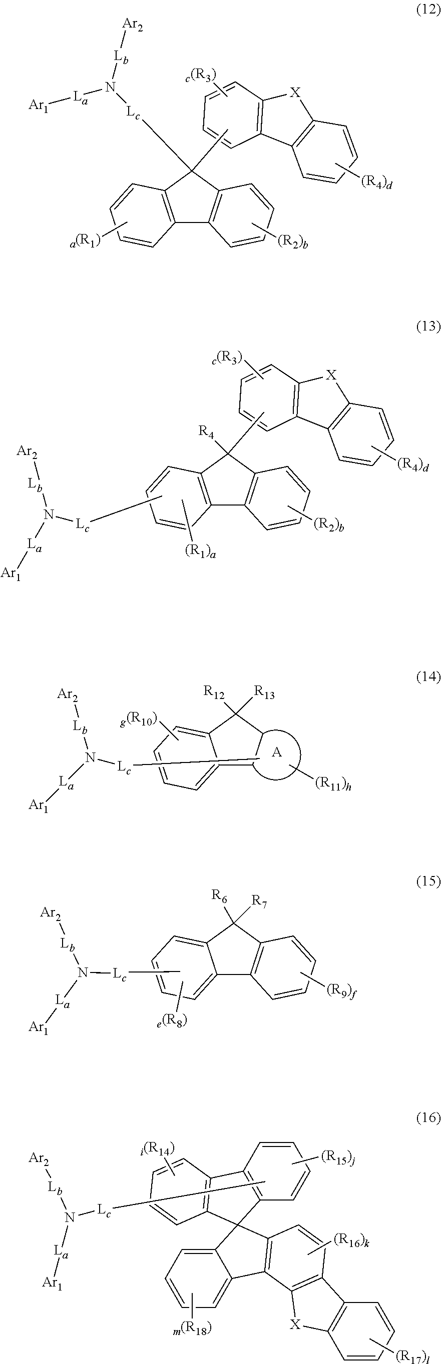 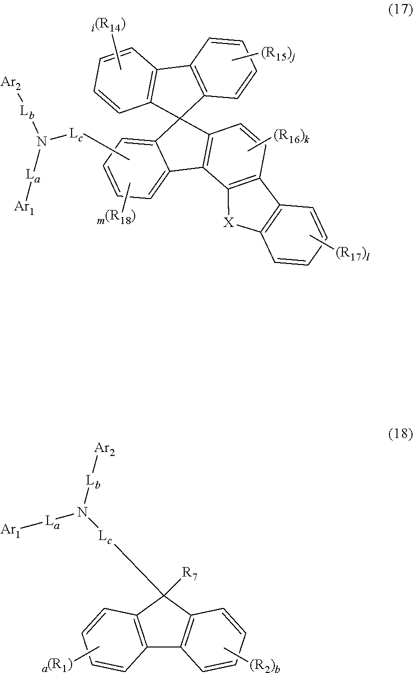
wherein, R₁ to R₁₇, a to m, Lₐ to L_{c}, Ar₁, and Ar₂ are as defined in claim 4.

6. The organic electroluminescent device according to claim 1, wherein the HOMO energy level of the arylamine derivative satisfies the following formula 12:
−5.0 eV ≤HOMO ≤−4.70 eV (12).

7. The organic electroluminescent device according to claim 1, comprising a first hole transport layer between the first electrode and the light-emitting layer, and a second hole transport layer between the first hole transport layer and the light-emitting layer, wherein the second hole transport layer comprises an arylamine derivative containing a fluorene or a fused fluorene, and the HOMO energy level of the arylamine derivative satisfies the above formula 11.

8. The organic electroluminescent device according to claim 1, wherein substituents of the substituted alkyl, the substituted aryl(ene), the substituted heteroaryl(ene), the substituted cycloalkyl, the substituted heterocycloalkyl, the substituted arylalkyl, the substituted benzene ring, and the substituted mono- or polycyclic, alicyclic or aromatic ring, or a combination thereof in L₁, Ar, Rₐ to R_{c}, and R_{f} to Rᵢ, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (5- to 30-membered)heteroaryl unsubstituted or substituted with a (C6-C30)aryl; a (C6-C30)aryl unsubstituted or substituted with a (5- to 30-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino unsubstituted or substituted with a (C1-C30)alkyl; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

9. The organic electroluminescent device according to claim 1, wherein the compound represented by formula 1 is at least one selected from the following compounds:

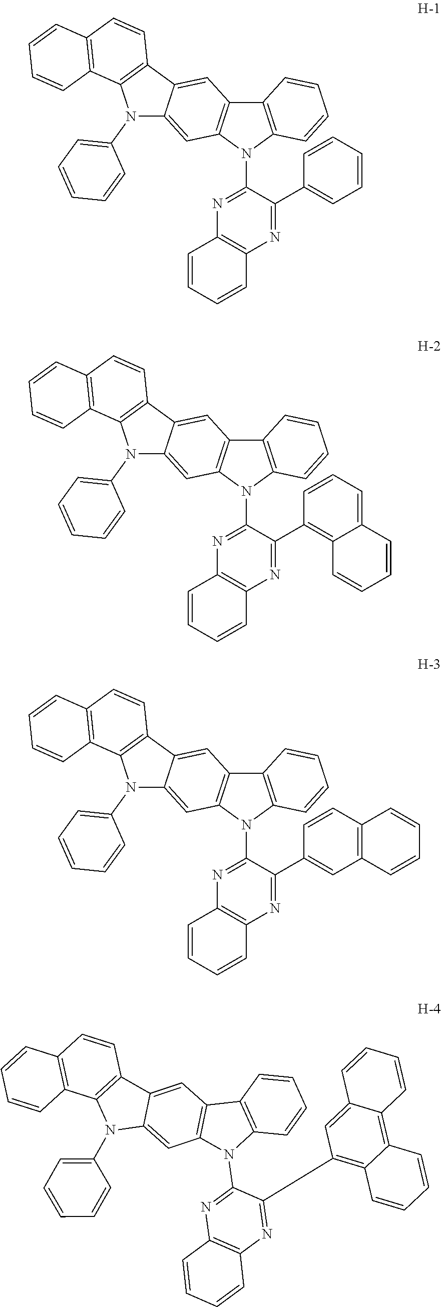 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

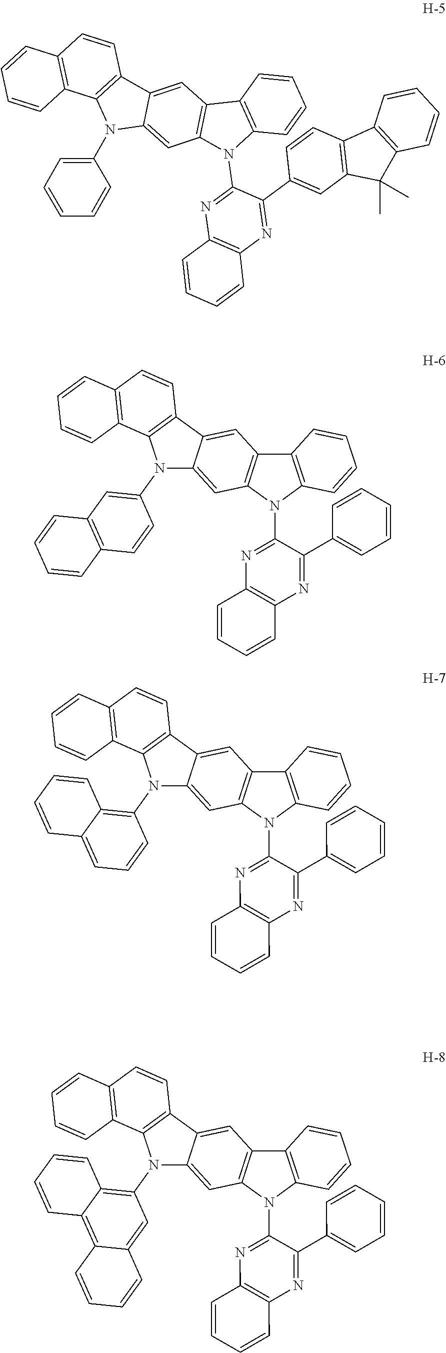 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

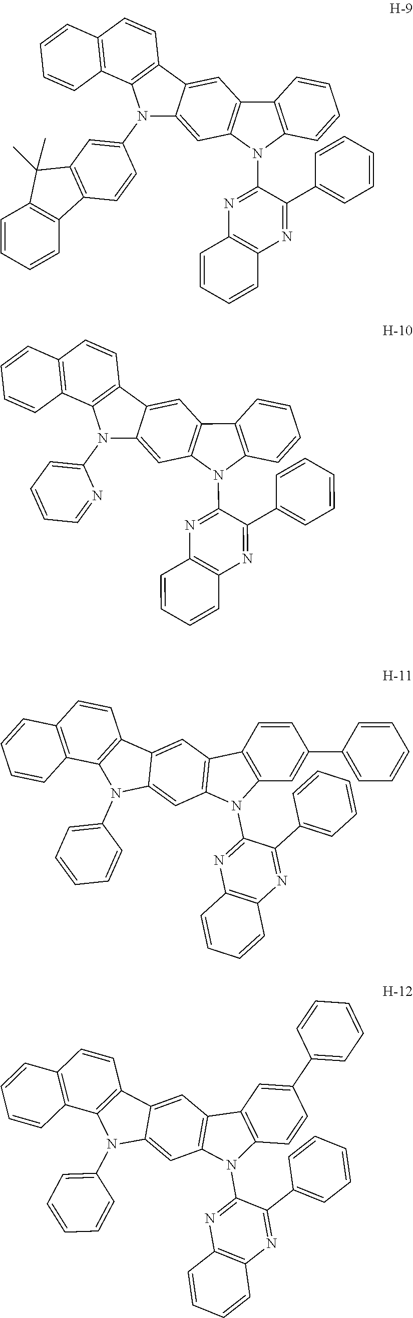 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccc5)c4cc2n3-c2nc3ccccc3nc2-c2ccccc2)cc1]

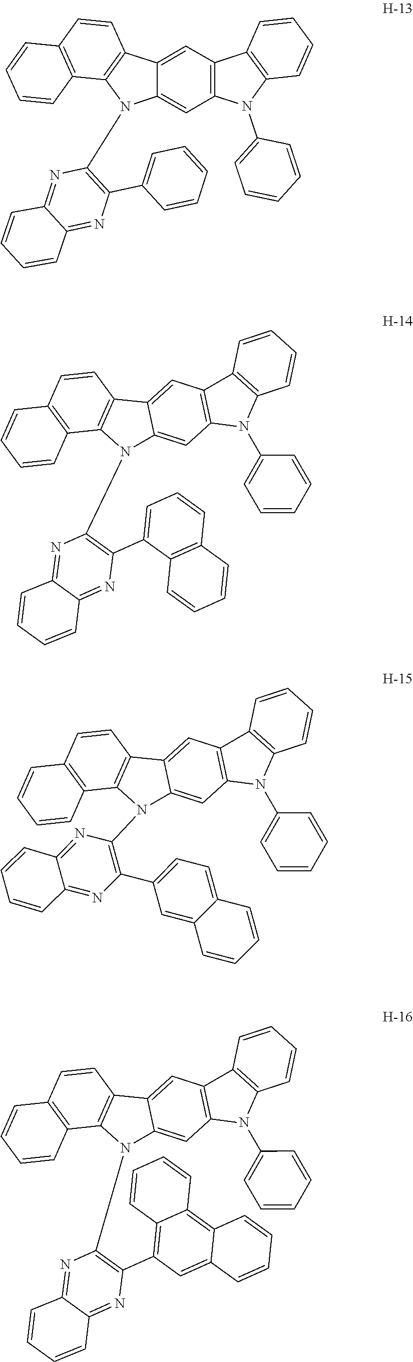 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

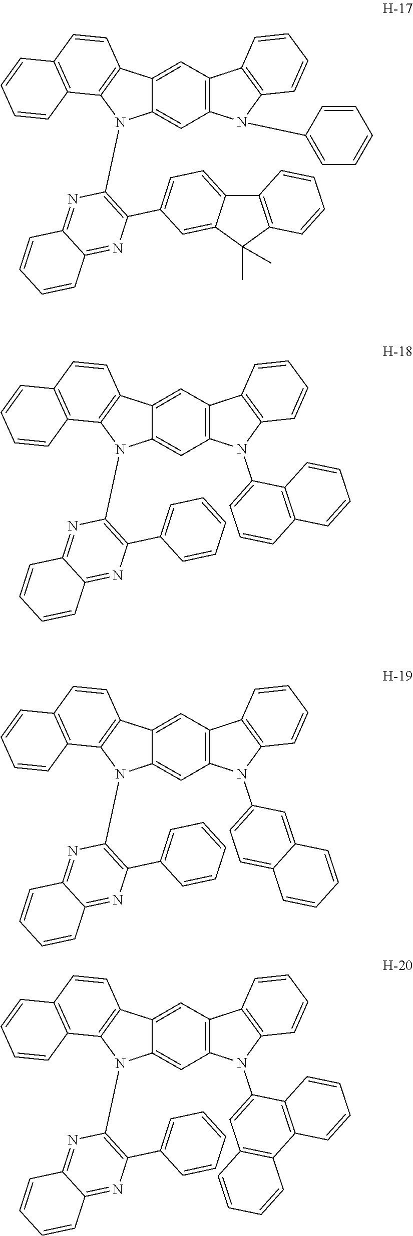

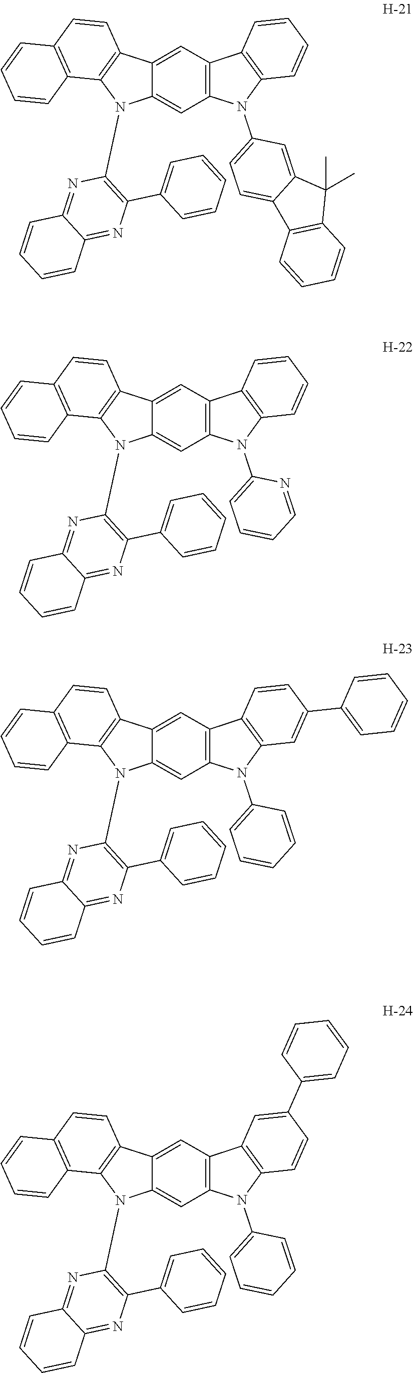 [SMILES: CC1(C)c2ccccc2-c2ccc(-n3c4ccccc4c4cc5c6ccc7ccccc7c6n(-c6nc7ccccc7nc6-c6ccccc6)c5cc43)cc21 ; c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1]

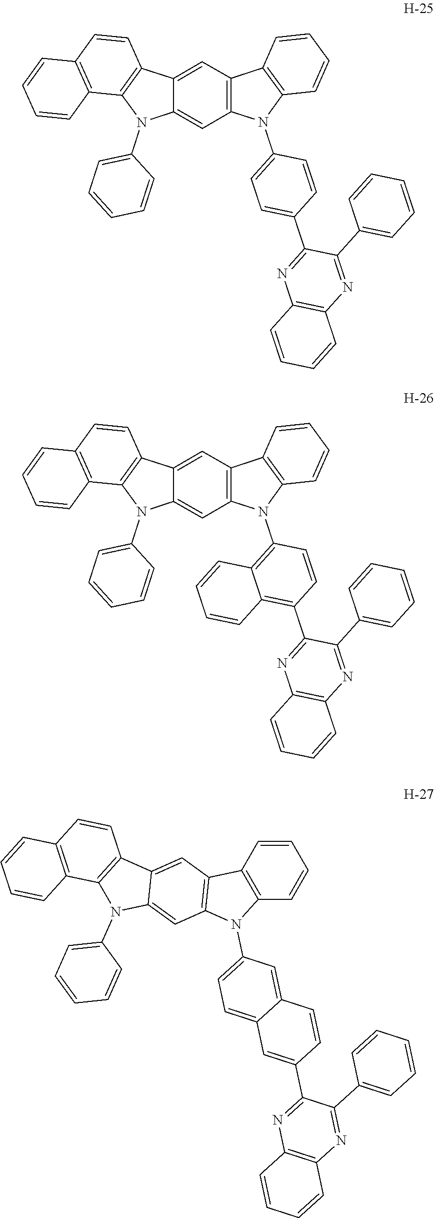 [SMILES: c1ccc(-c2nc3ccccc3nc2-c2ccc(-n3c4ccccc4c4cc5c6ccc7ccccc7c6n(-c6ccccc6)c5cc43)cc2)cc1 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1]

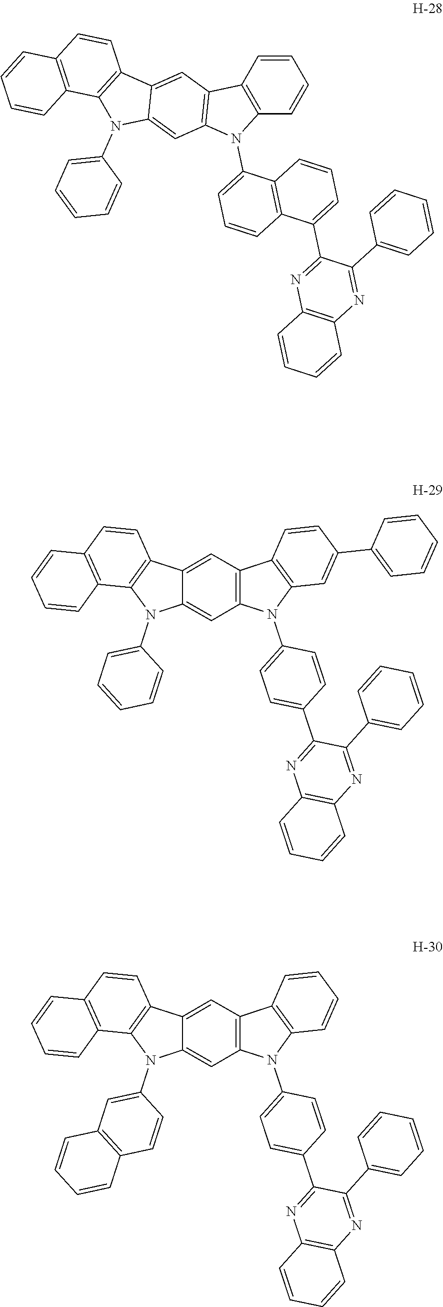 [SMILES: c1ccc(-c2nc3ccccc3nc2-c2cccc3c(-n4c5ccccc5c5cc6c7ccc8ccccc8c7n(-c7ccccc7)c6cc54)cccc23)cc1 ; c1ccc(-c2ccc3c4cc5c6ccc7ccccc7c6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6ccc7ccccc7c6n(-c6ccc7ccccc7c6)c5cc43)cc2)cc1]

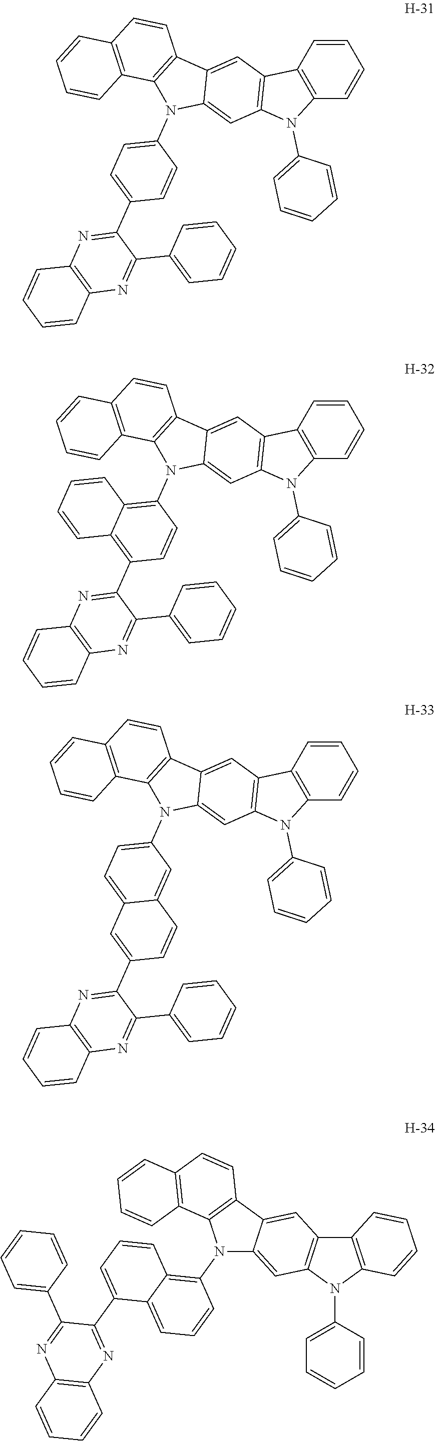 [SMILES: c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-c2ccc(-n3c4cc5c(cc4c4ccc6ccccc6c43)c3ccccc3n5-c3ccccc3)c3ccccc23)cc1 ; c1ccc(-c2nc3ccccc3nc2-c2ccc3cc(-n4c5cc6c(cc5c5ccc7ccccc7c54)c4ccccc4n6-c4ccccc4)ccc3c2)cc1 ; c1ccc(-c2nc3ccccc3nc2-c2cccc3c(-n4c5cc6c(cc5c5ccc7ccccc7c54)c4ccccc4n6-c4ccccc4)cccc23)cc1]

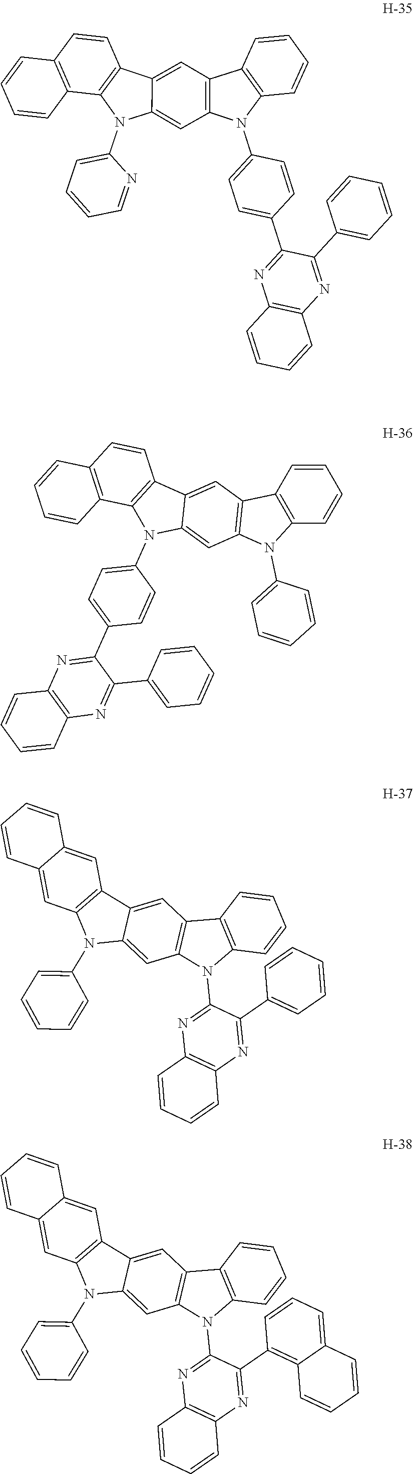 [SMILES: c1ccc(-c2nc3ccccc3nc2-c2ccc(-n3c4ccccc4c4cc5c6ccc7ccccc7c6n(-c6ccccn6)c5cc43)cc2)cc1 ; c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-n2c3ccccc3c3cc4c5cc6ccccc6cc5n(-c5ccccc5)c4cc32)cc1 ; c1ccc(-n2c3cc4ccccc4cc3c3cc4c5ccccc5n(-c5nc6ccccc6nc5-c5cccc6ccccc56)c4cc32)cc1]

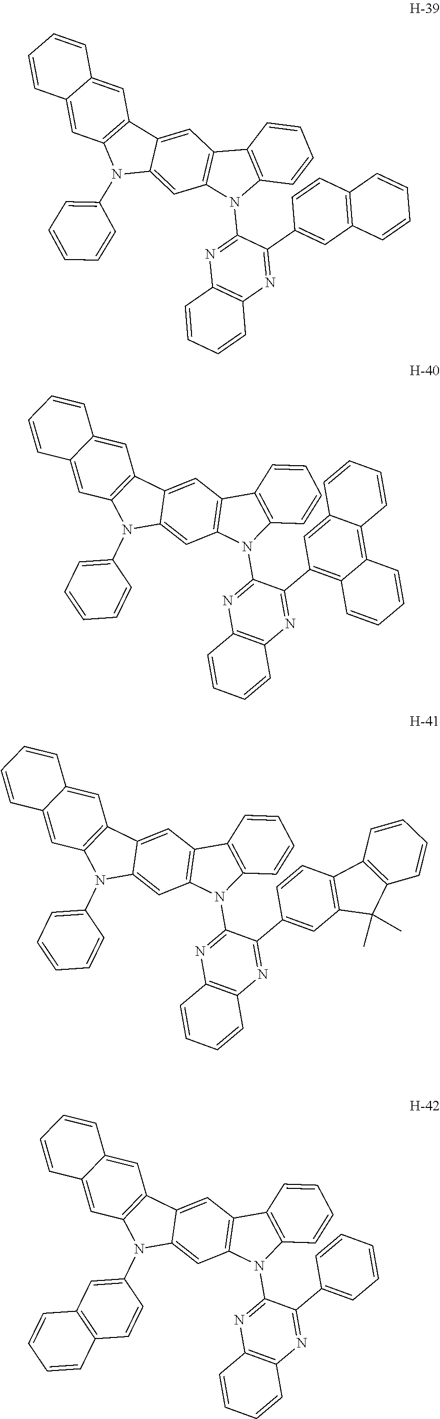 [SMILES: c1ccc(-n2c3cc4ccccc4cc3c3cc4c5ccccc5n(-c5nc6ccccc6nc5-c5ccc6ccccc6c5)c4cc32)cc1 ; c1ccc(-n2c3cc4ccccc4cc3c3cc4c5ccccc5n(-c5nc6ccccc6nc5-c5cc6ccccc6c6ccccc56)c4cc32)cc1 ; CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1]

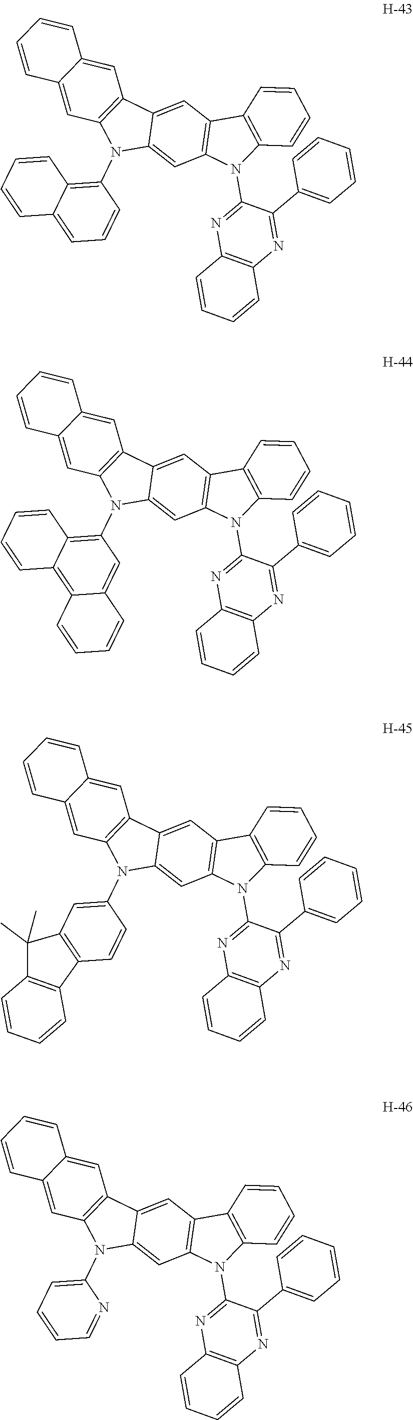 [SMILES: c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1 ; CC1(C)c2ccccc2-c2ccc(-n3c4cc5ccccc5cc4c4cc5c6ccccc6n(-c6nc7ccccc7nc6-c6ccccc6)c5cc43)cc21 ; c1ccc(-c2nc3ccccc3nc2-n2c3ccccc3c3cc4c5cc6ccccc6cc5n(-c5ccccn5)c4cc32)cc1]

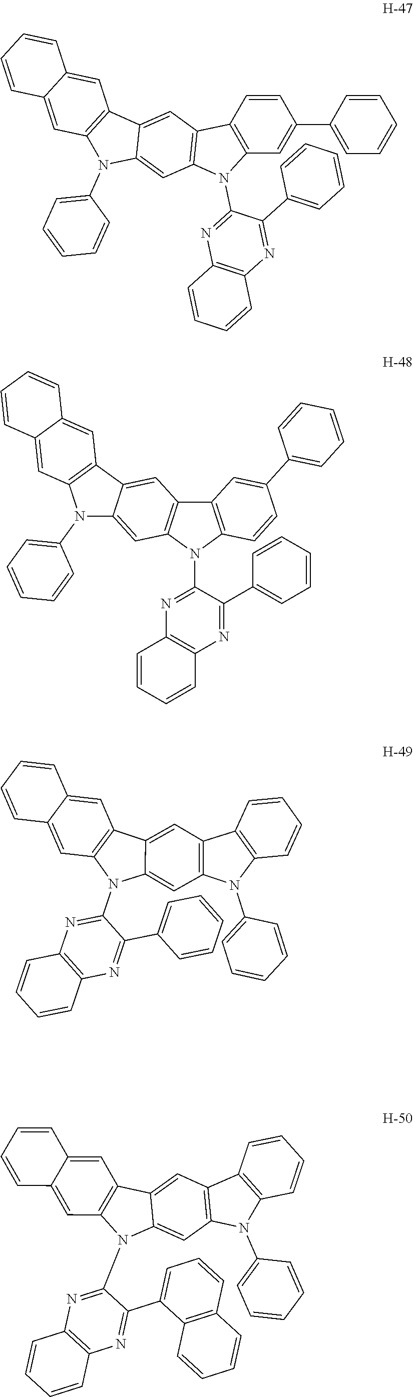 [SMILES: c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1 ; c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1]

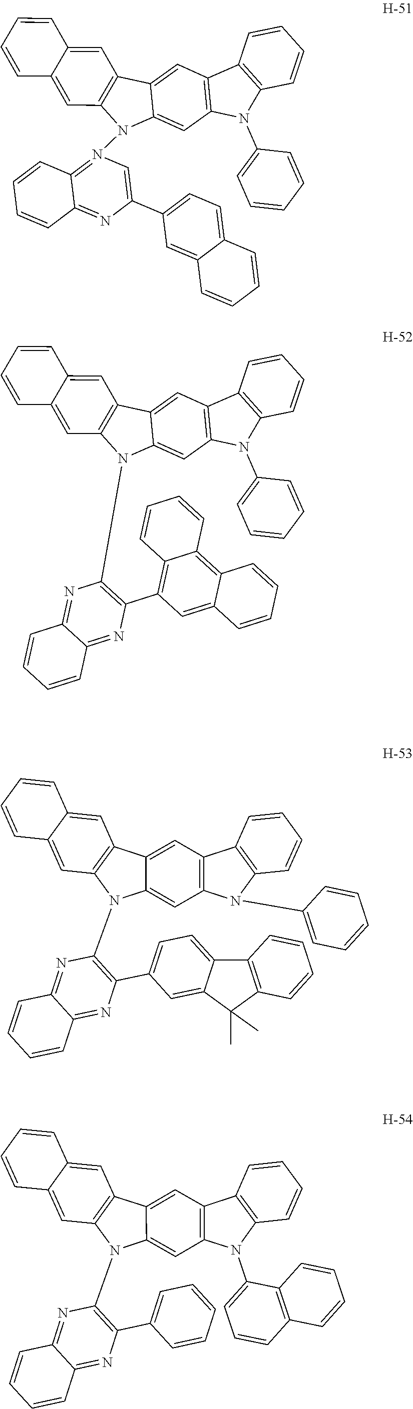

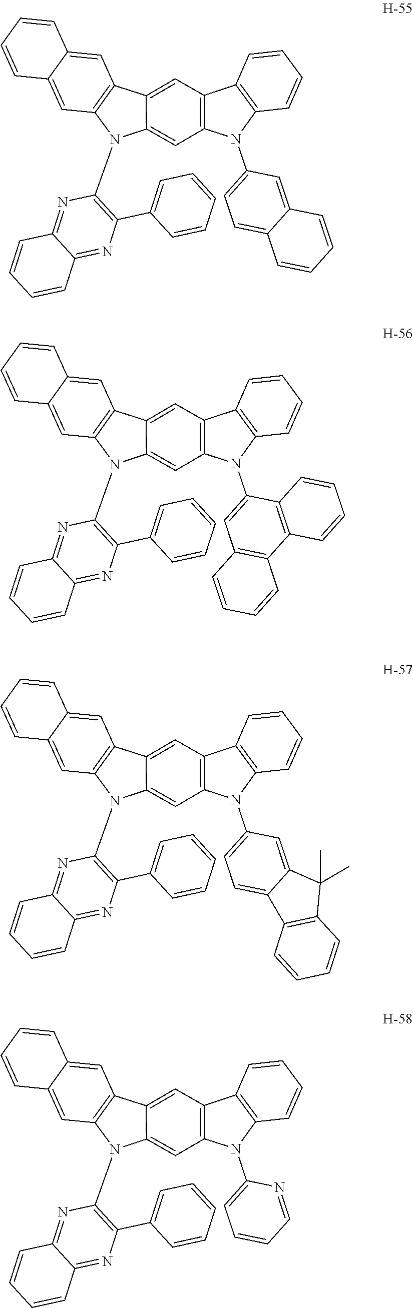 [SMILES: c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1 ; CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1]

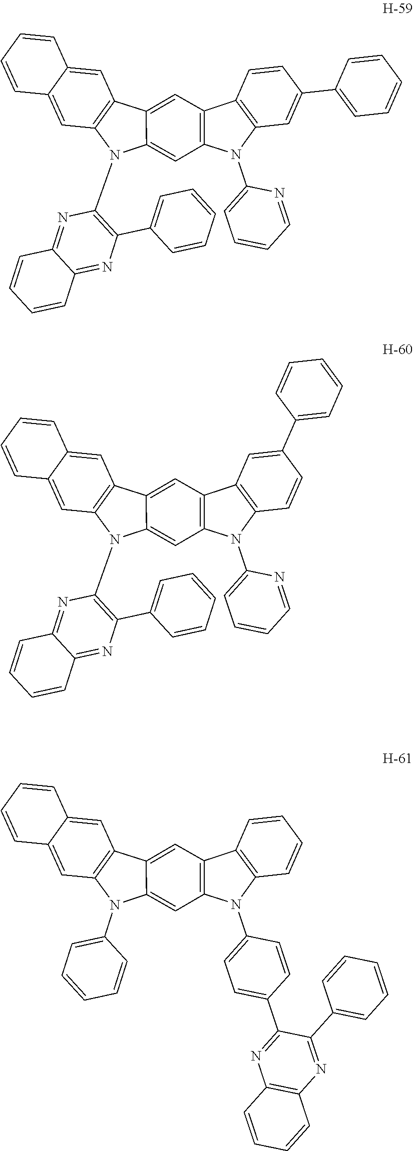 [SMILES: c1ccc(-c2ccc3c4cc5c6cc7ccccc7cc6n(-c6nc7ccccc7nc6-c6ccccc6)c5cc4n(-c4ccccn4)c3c2)cc1 ; c1ccc(-c2ccc3c(c2)c2cc4c5cc6ccccc6cc5n(-c5nc6ccccc6nc5-c5ccccc5)c4cc2n3-c2ccccn2)cc1 ; c1ccc(-c2nc3ccccc3nc2-c2ccc(-n3c4ccccc4c4cc5c6cc7ccccc7cc6n(-c6ccccc6)c5cc43)cc2)cc1]

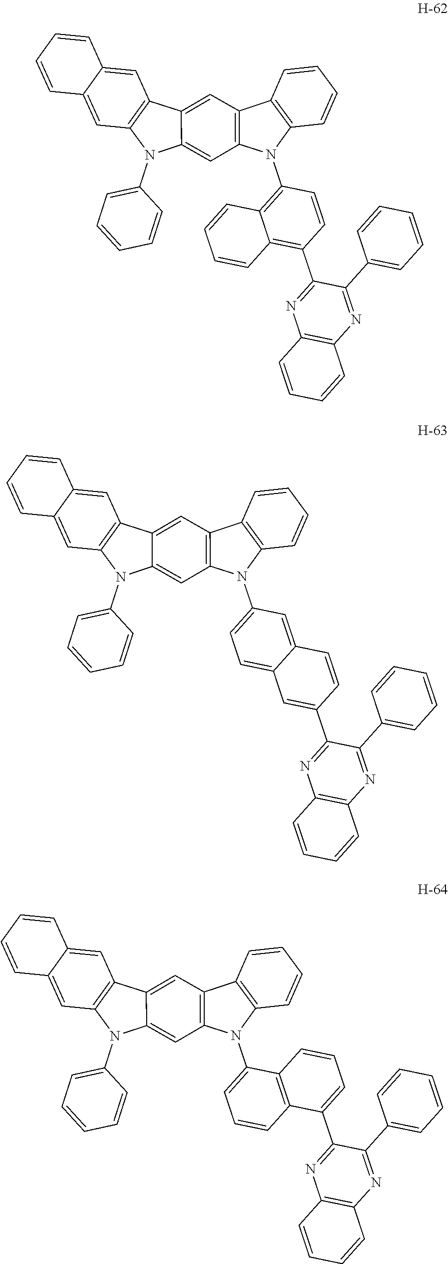 [SMILES: c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1 ; c1ccc(-c2nc3ccccc3nc2-c2cccc3c(-n4c5ccccc5c5cc6c7cc8ccccc8cc7n(-c7ccccc7)c6cc54)cccc23)cc1]

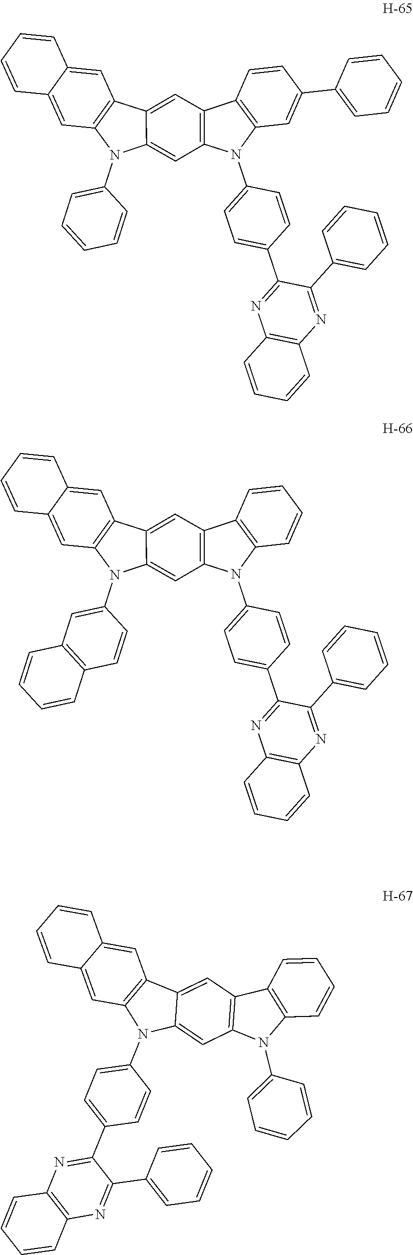 [SMILES: c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1 ; c1ccc(-c2nc3ccccc3nc2-c2ccc(-n3c4cc5ccccc5cc4c4cc5c6ccccc6n(-c6ccccc6)c5cc43)cc2)cc1]

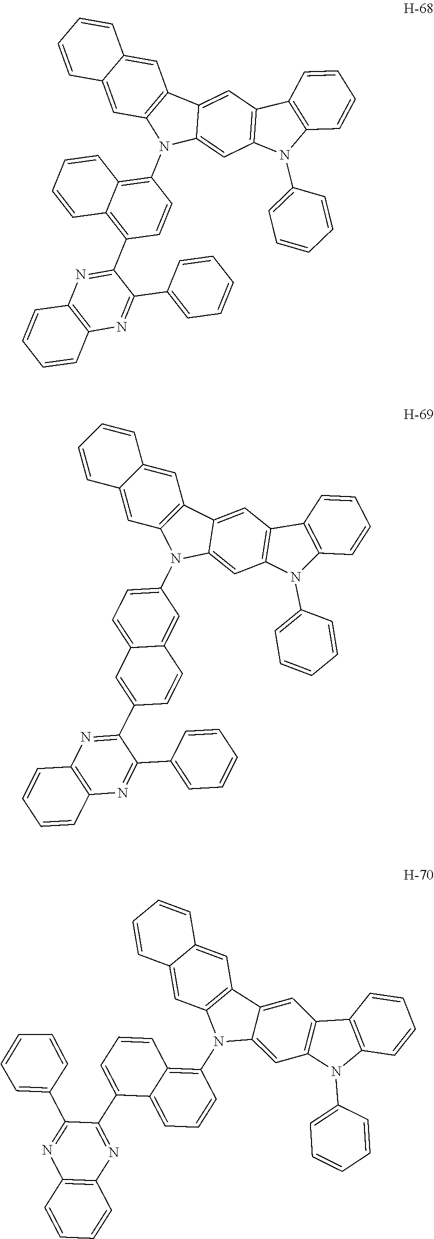 [SMILES: c1ccc(-c2nc3ccccc3nc2-c2ccc(-n3c4cc5ccccc5cc4c4cc5c6ccccc6n(-c6ccccc6)c5cc43)c3ccccc23)cc1 ; c1ccc(-c2nc3ccccc3nc2-c2ccc3cc(-n4c5cc6ccccc6cc5c5cc6c7ccccc7n(-c7ccccc7)c6cc54)ccc3c2)cc1 ; c1ccc(-c2nc3ccccc3nc2-c2cccc3c(-n4c5cc6ccccc6cc5c5cc6c7ccccc7n(-c7ccccc7)c6cc54)cccc23)cc1]

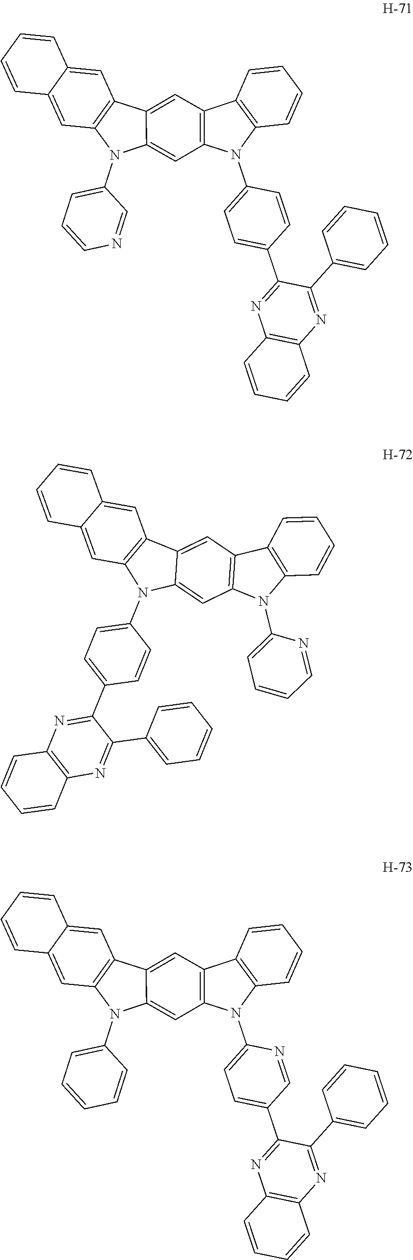 [SMILES: c1ccc(-c2nc3ccccc3nc2-c2ccc(-n3c4ccccc4c4cc5c6cc7ccccc7cc6n(-c6cccnc6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)nc2)cc1]

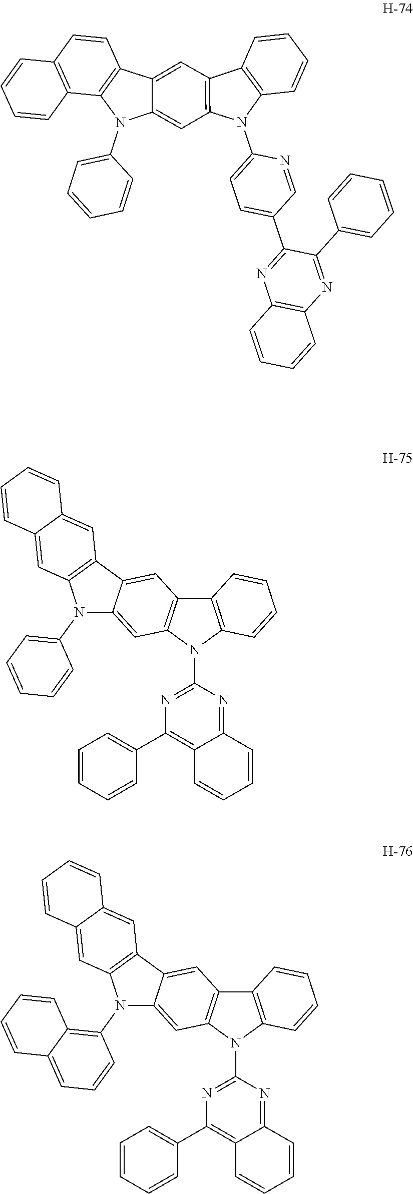 [SMILES: c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1 ; c1ccc(-c2nc(-n3c4ccccc4c4cc5c6cc7ccccc7cc6n(-c6cccc7ccccc67)c5cc43)nc3ccccc23)cc1]

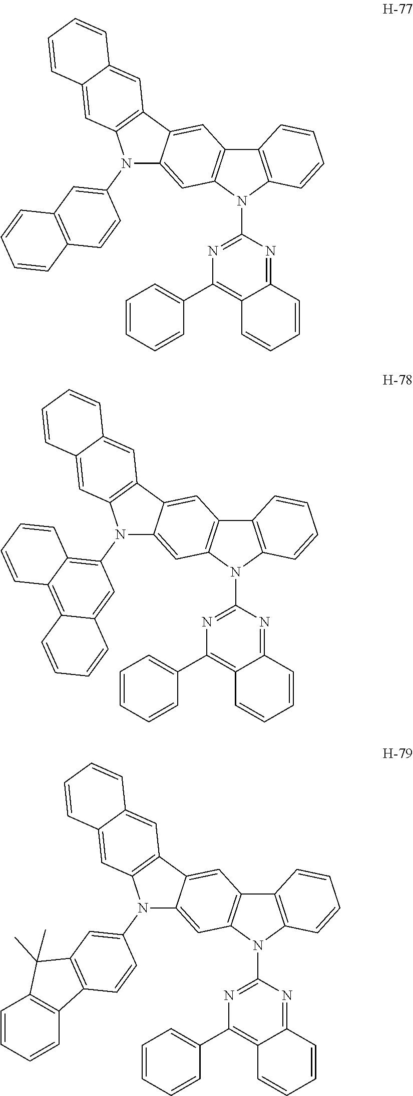 [SMILES: c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1 ; CC1(C)c2ccccc2-c2ccc(-n3c4cc5ccccc5cc4c4cc5c6ccccc6n(-c6nc(-c7ccccc7)c7ccccc7n6)c5cc43)cc21]

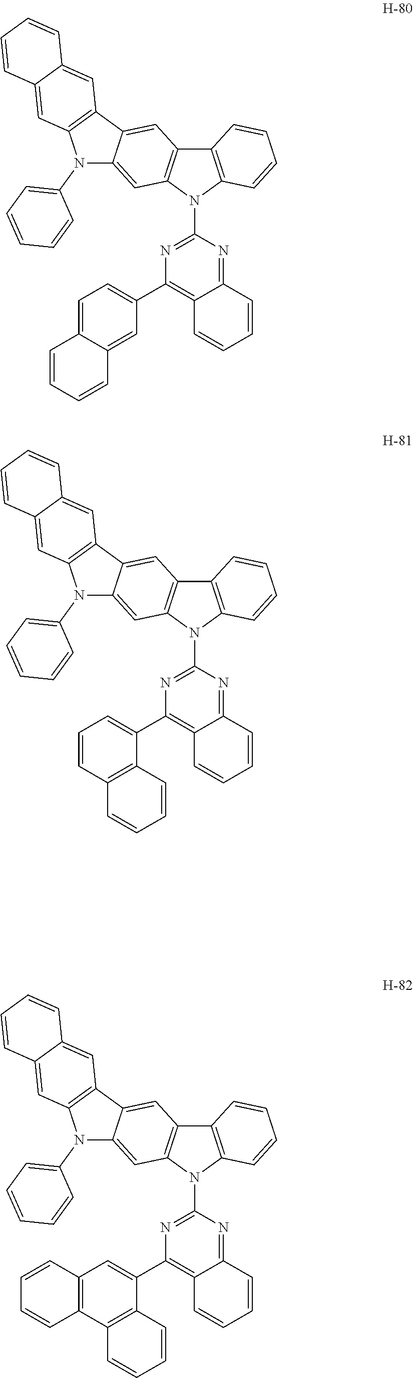 [SMILES: c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1 ; c1ccc(-n2c3cc4ccccc4cc3c3cc4c5ccccc5n(-c5nc(-c6cc7ccccc7c7ccccc67)c6ccccc6n5)c4cc32)cc1]

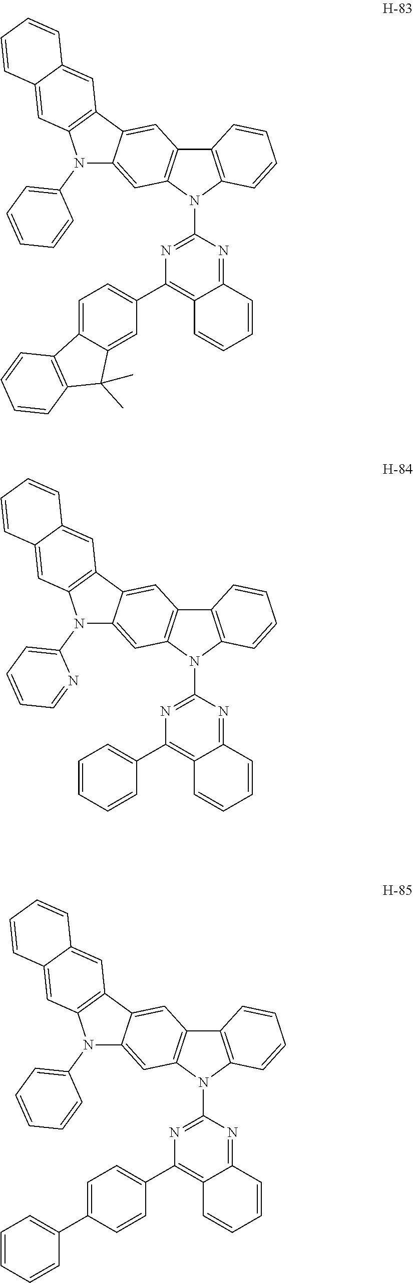 [SMILES: CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1 ; c1ccc(-c2ccc(-c3nc(-n4c5ccccc5c5cc6c7cc8ccccc8cc7n(-c7ccccc7)c6cc54)nc4ccccc34)cc2)cc1]

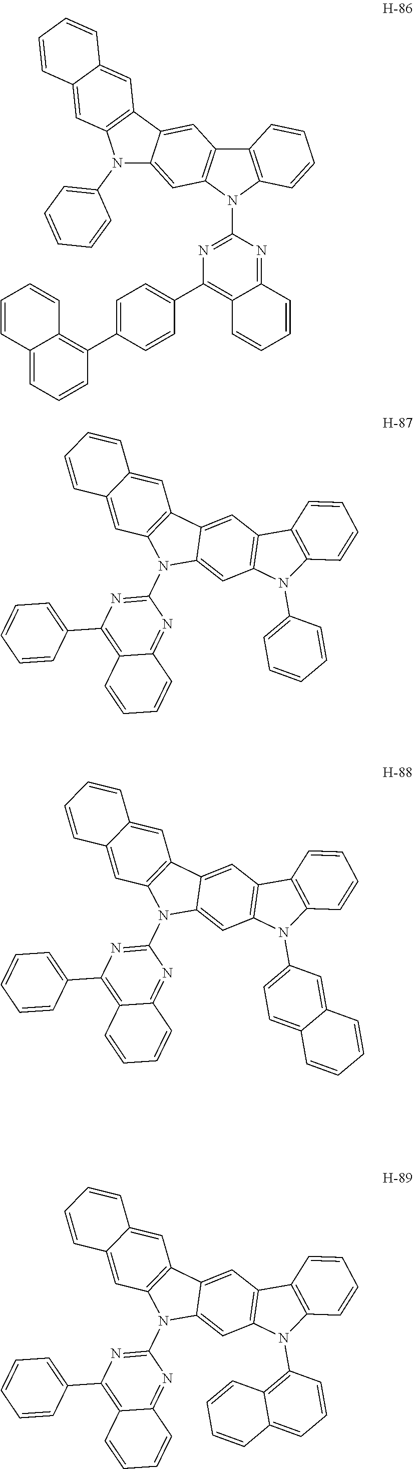

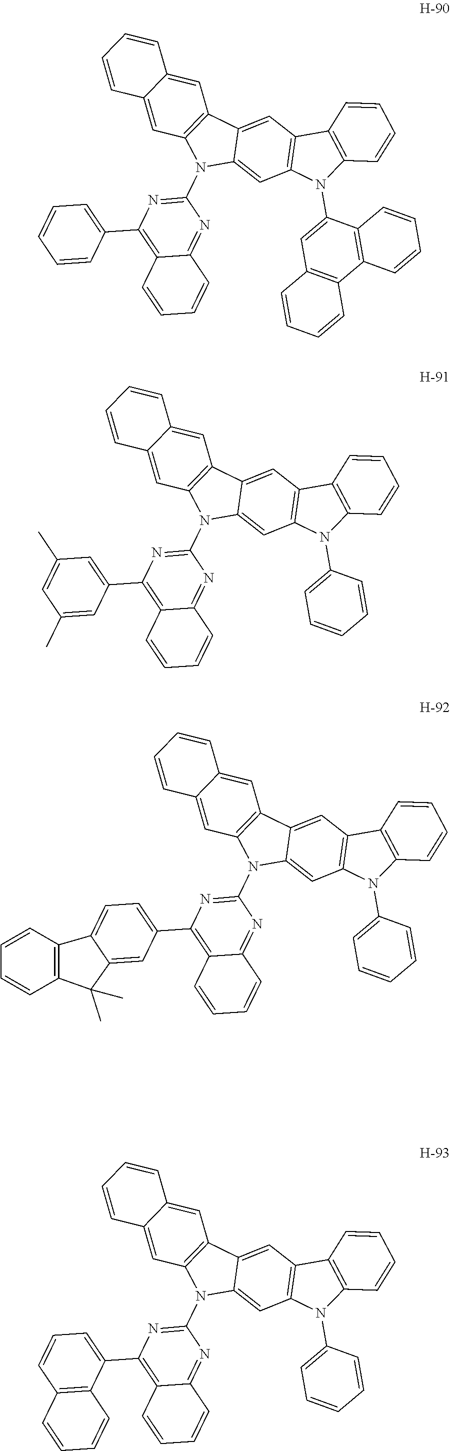 [SMILES: c1ccc(-c2nc(-n3c4cc5ccccc5cc4c4cc5c6ccccc6n(-c6cc7ccccc7c7ccccc67)c5cc43)nc3ccccc23)cc1 ; Cc1cc(C)cc(-c2nc(-n3c4cc5ccccc5cc4c4cc5c6ccccc6n(-c6ccccc6)c5cc43)nc3ccccc23)c1 ; CC1(C)c2ccccc2-c2ccc(-c3nc(-n4c5cc6ccccc6cc5c5cc6c7ccccc7n(-c7ccccc7)c6cc54)nc4ccccc34)cc21 ; c1ccc(-n2c3ccccc3c3cc4c5cc6ccccc6cc5n(-c5nc(-c6cccc7ccccc67)c6ccccc6n5)c4cc32)cc1]

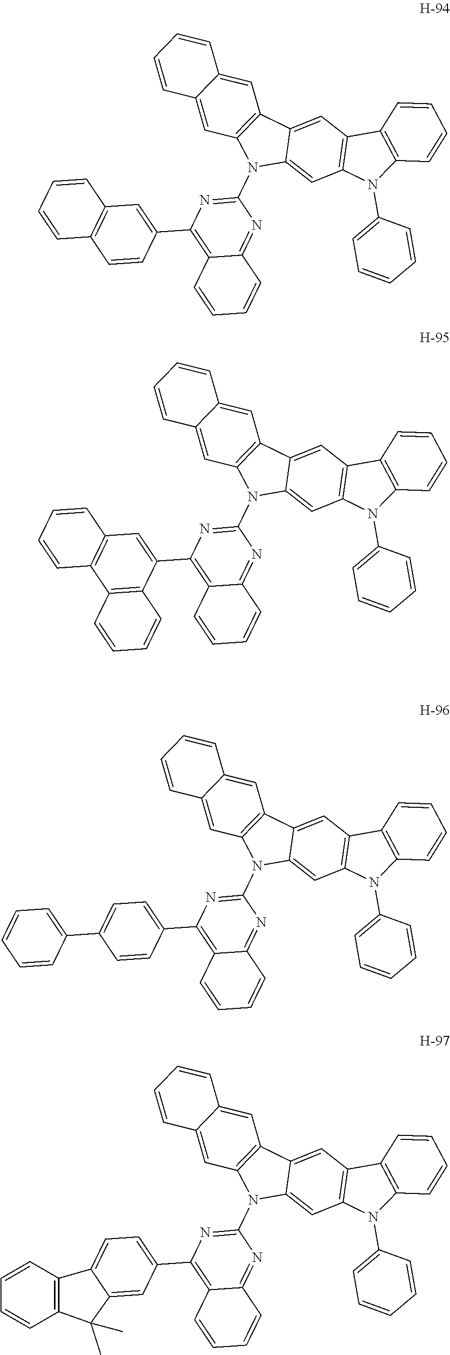 [SMILES: c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1 ; c1ccc(-c2ccc(-c3nc(-n4c5cc6ccccc6cc5c5cc6c7ccccc7n(-c7ccccc7)c6cc54)nc4ccccc34)cc2)cc1 ; CC1(C)c2ccccc2-c2ccc(-c3nc(-n4c5cc6ccccc6cc5c5cc6c7ccccc7n(-c7ccccc7)c6cc54)nc4ccccc34)cc21]

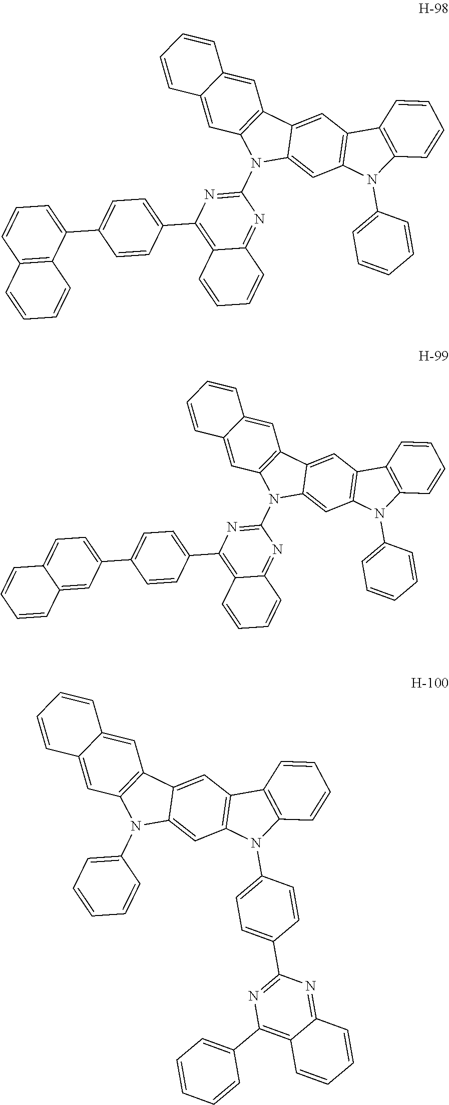 [SMILES: c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7cc8ccccc8cc7n(-c7ccccc7)c6cc54)cc3)nc3ccccc23)cc1]

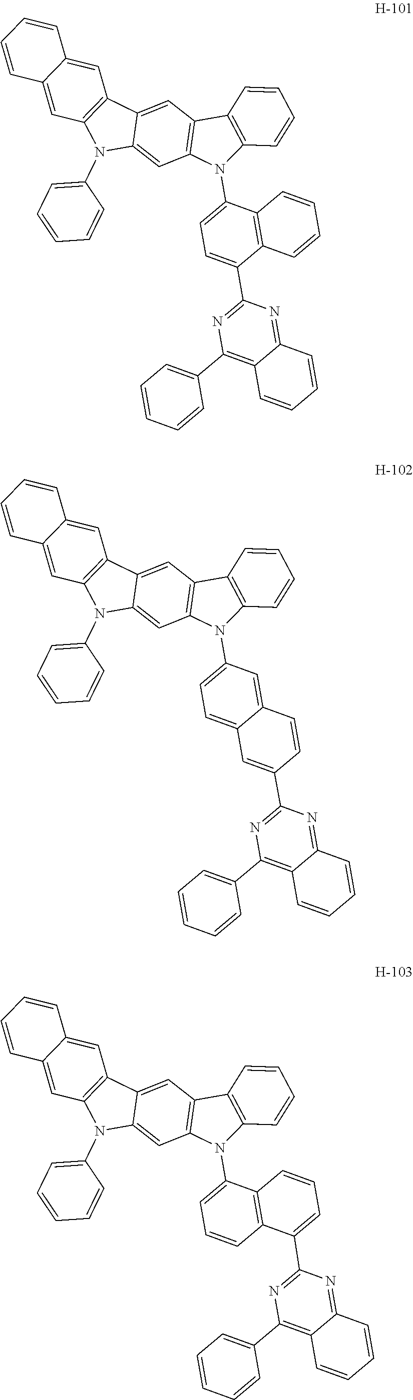 [SMILES: c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1 ; c1ccc(-c2nc(-c3cccc4c(-n5c6ccccc6c6cc7c8cc9ccccc9cc8n(-c8ccccc8)c7cc65)cccc34)nc3ccccc23)cc1]

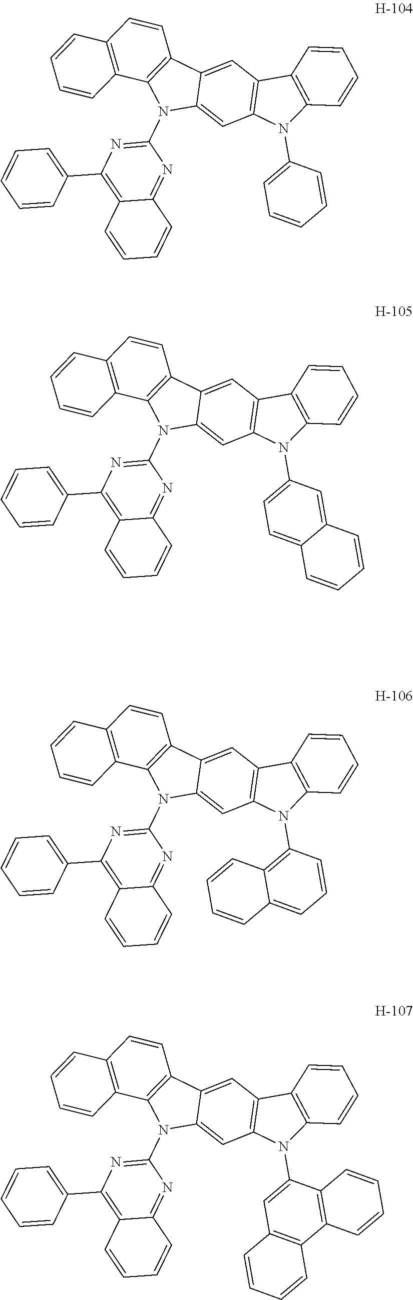 [SMILES: c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1 ; c1ccc(-c2nc(-n3c4cc5c(cc4c4ccc6ccccc6c43)c3ccccc3n5-c3cc4ccccc4c4ccccc34)nc3ccccc23)cc1]

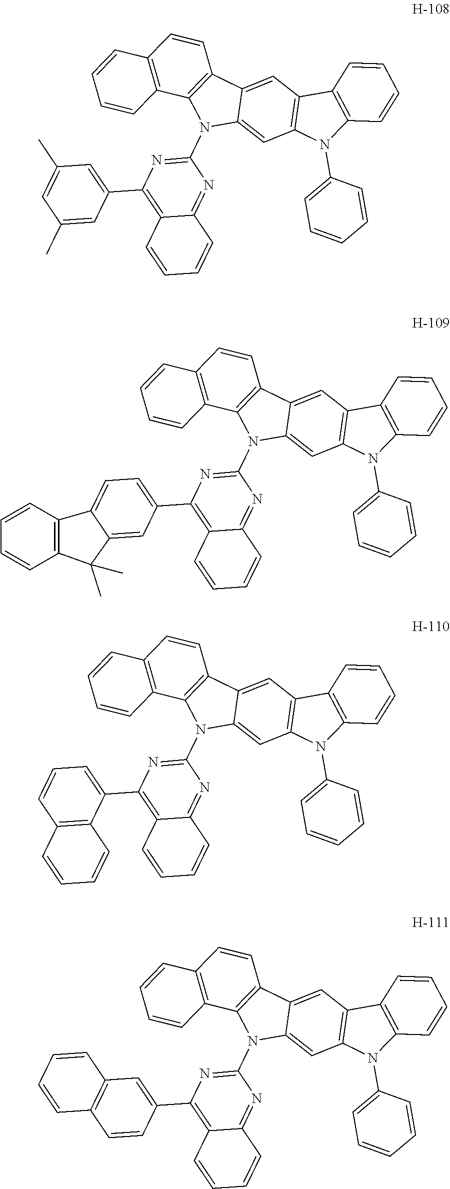 [SMILES: Cc1cc(C)cc(-c2nc(-n3c4cc5c(cc4c4ccc6ccccc6c43)c3ccccc3n5-c3ccccc3)nc3ccccc23)c1 ; CC1(C)c2ccccc2-c2ccc(-c3nc(-n4c5cc6c(cc5c5ccc7ccccc7c54)c4ccccc4n6-c4ccccc4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1 ; c1ccc(-n2c3ccccc3c3cc4c5ccc6ccccc6c5n(-c5nc(-c6ccc7ccccc7c6)c6ccccc6n5)c4cc32)cc1]

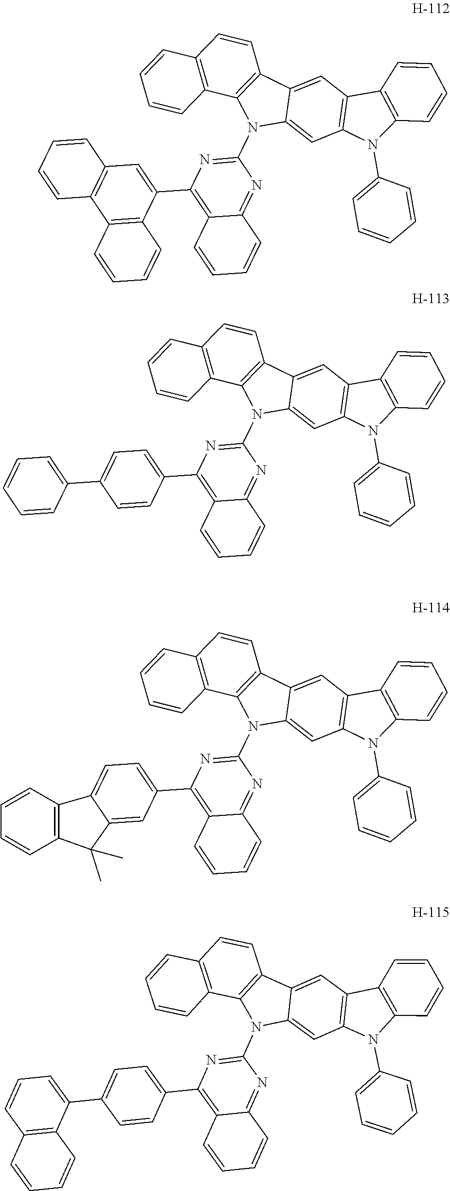 [SMILES: c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1 ; CC1(C)c2ccccc2-c2ccc(-c3nc(-n4c5cc6c(cc5c5ccc7ccccc7c54)c4ccccc4n6-c4ccccc4)nc4ccccc34)cc21 ; c1ccc(-n2c3ccccc3c3cc4c5ccc6ccccc6c5n(-c5nc(-c6ccc(-c7cccc8ccccc78)cc6)c6ccccc6n5)c4cc32)cc1]

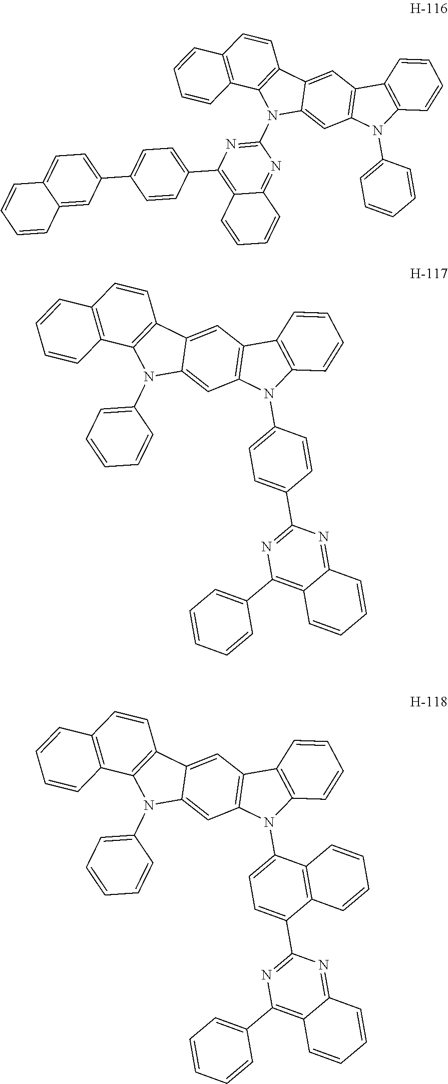 [SMILES: c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1 ; c1ccc(-c2nc(-c3ccc(-n4c5ccccc5c5cc6c7ccc8ccccc8c7n(-c7ccccc7)c6cc54)c4ccccc34)nc3ccccc23)cc1]

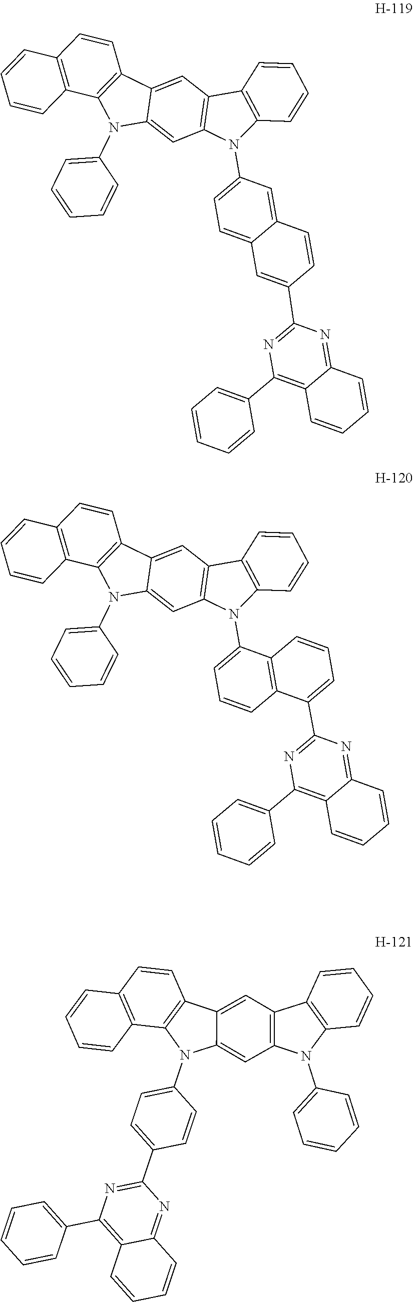 [SMILES: c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3cccc4c(-n5c6ccccc6c6cc7c8ccc9ccccc9c8n(-c8ccccc8)c7cc65)cccc34)nc3ccccc23)cc1 ; c1ccc(-c2nc(-c3ccc(-n4c5cc6c(cc5c5ccc7ccccc7c54)c4ccccc4n6-c4ccccc4)cc3)nc3ccccc23)cc1]

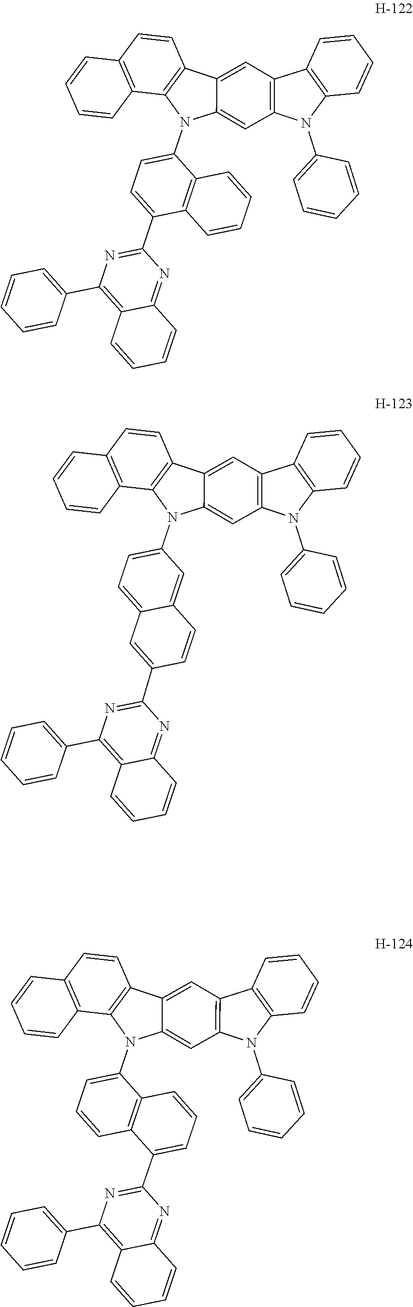 [SMILES: c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1 ; c1ccc(-c2nc(-c3cccc4c(-n5c6cc7c(cc6c6ccc8ccccc8c65)c5ccccc5n7-c5ccccc5)cccc34)nc3ccccc23)cc1]

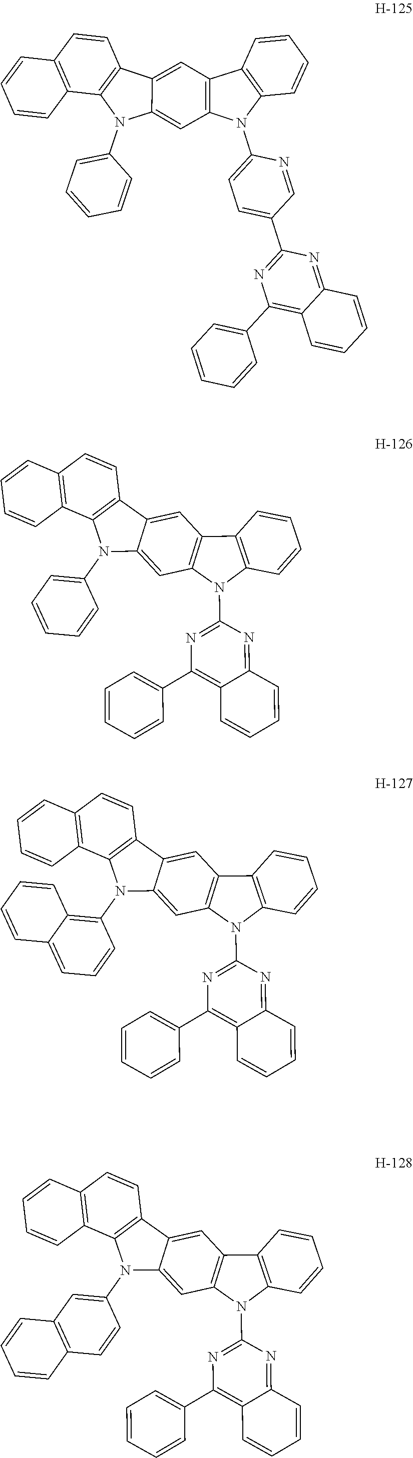 [SMILES: c1ccc(-c2nc(-c3ccc(-n4c5ccccc5c5cc6c7ccc8ccccc8c7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1 ; c1ccc(-c2nc(-n3c4ccccc4c4cc5c6ccc7ccccc7c6n(-c6cccc7ccccc67)c5cc43)nc3ccccc23)cc1 ; c1ccc(-c2nc(-n3c4ccccc4c4cc5c6ccc7ccccc7c6n(-c6ccc7ccccc7c6)c5cc43)nc3ccccc23)cc1]

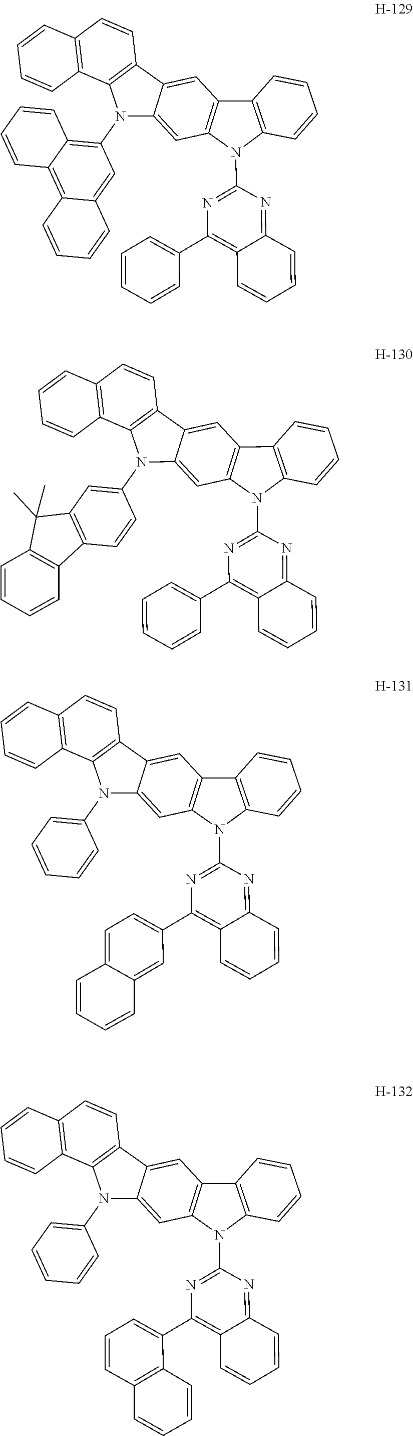 [SMILES: c1ccc(-c2nc(-n3c4ccccc4c4cc5c6ccc7ccccc7c6n(-c6cc7ccccc7c7ccccc67)c5cc43)nc3ccccc23)cc1 ; CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1 ; c1ccc(-n2c3cc4c(cc3c3ccc5ccccc5c32)c2ccccc2n4-c2nc(-c3cccc4ccccc34)c3ccccc3n2)cc1]

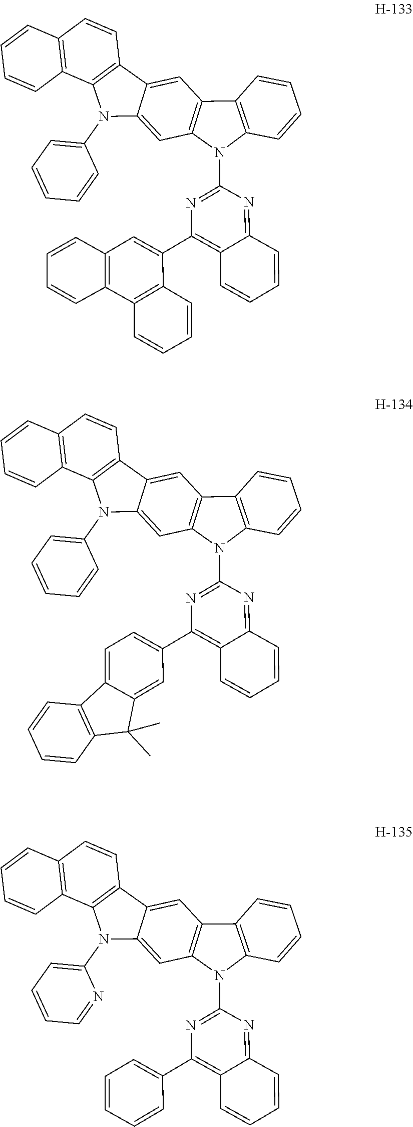 [SMILES: c1ccc(-n2c3cc4c(cc3c3ccc5ccccc5c32)c2ccccc2n4-c2nc(-c3cc4ccccc4c4ccccc34)c3ccccc3n2)cc1 ; CC1(C)c2ccccc2-c2ccc(-c3nc(-n4c5ccccc5c5cc6c7ccc8ccccc8c7n(-c7ccccc7)c6cc54)nc4ccccc34)cc21 ; c1ccc(-c2nc(-n3c4ccccc4c4cc5c6ccc7ccccc7c6n(-c6ccccn6)c5cc43)nc3ccccc23)cc1]

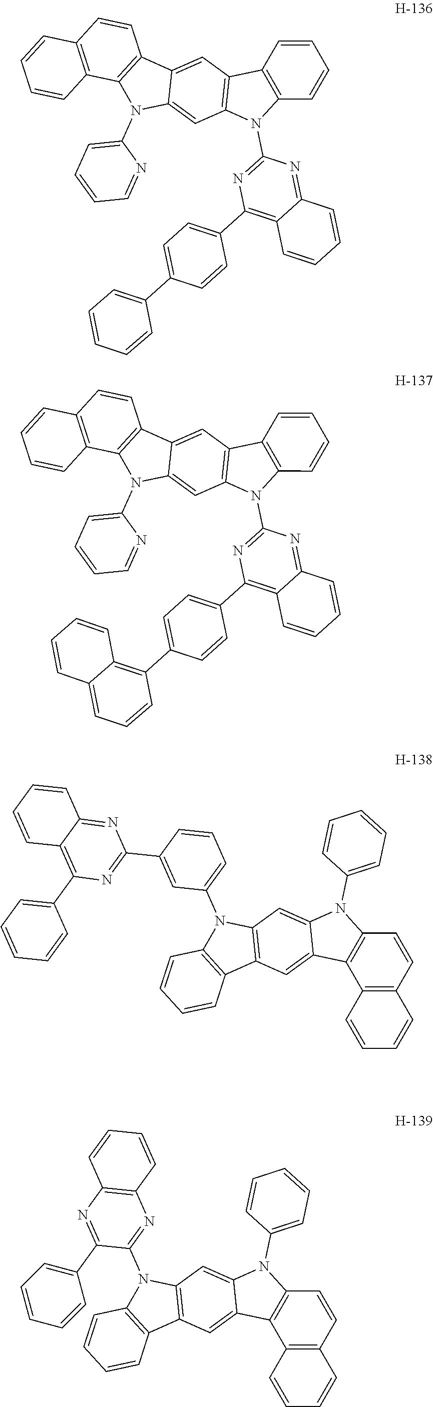

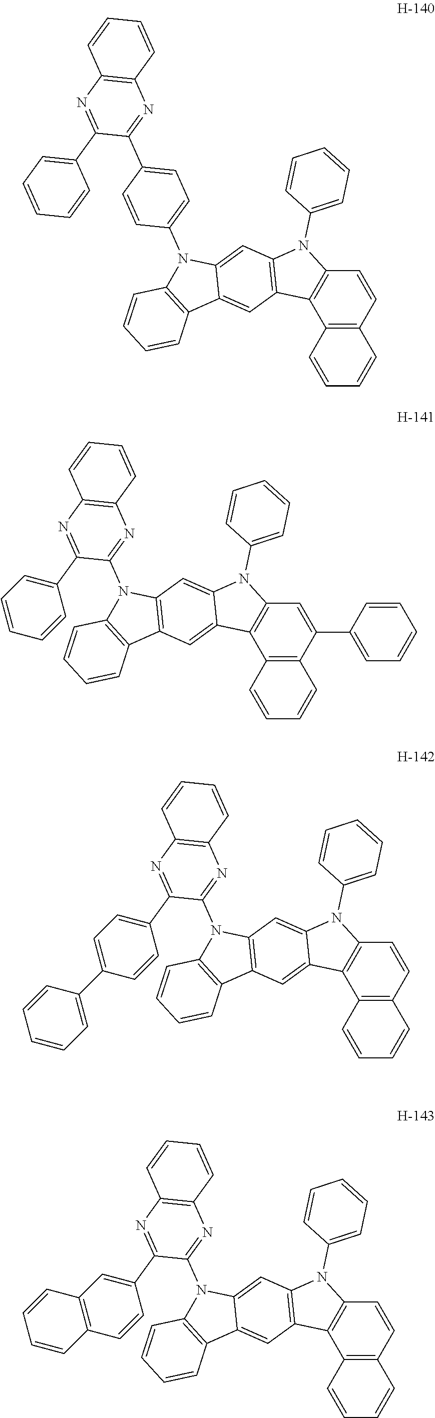 [SMILES: c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-c2ccc(-c3nc4ccccc4nc3-n3c4ccccc4c4cc5c6c7ccccc7ccc6n(-c6ccccc6)c5cc43)cc2)cc1 ; c1ccc(-n2c3cc4c(cc3c3c5ccccc5ccc32)c2ccccc2n4-c2nc3ccccc3nc2-c2ccc3ccccc3c2)cc1]

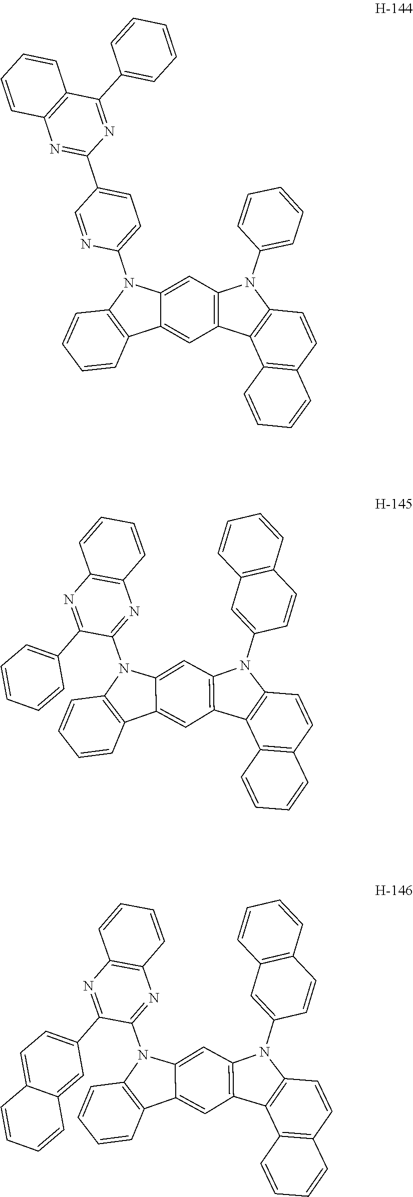 [SMILES: c1ccc(-c2nc(-c3ccc(-n4c5ccccc5c5cc6c7c8ccccc8ccc7n(-c7ccccc7)c6cc54)nc3)nc3ccccc23)cc1 ; c1ccc(-c2nc3ccccc3nc2-n2c3ccccc3c3cc4c5c6ccccc6ccc5n(-c5ccc6ccccc6c5)c4cc32)cc1 ; c1ccc2cc(-c3nc4ccccc4nc3-n3c4ccccc4c4cc5c6c7ccccc7ccc6n(-c6ccc7ccccc7c6)c5cc43)ccc2c1]

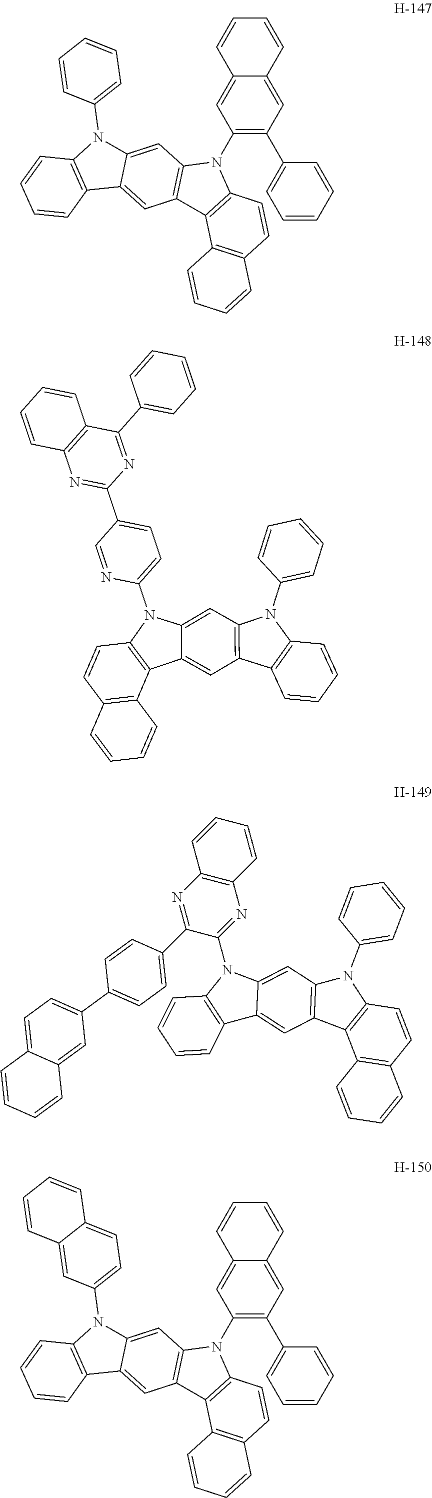 [SMILES: c1ccc(-c2cc3ccccc3cc2-n2c3cc4c(cc3c3c5ccccc5ccc32)c2ccccc2n4-c2ccccc2)cc1 ; c1ccc(-c2nc(-c3ccc(-n4c5cc6c(cc5c5c7ccccc7ccc54)c4ccccc4n6-c4ccccc4)nc3)nc3ccccc23)cc1 ; c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2cc3ccccc3cc2-n2c3cc4c(cc3c3c5ccccc5ccc32)c2ccccc2n4-c2ccc3ccccc3c2)cc1]

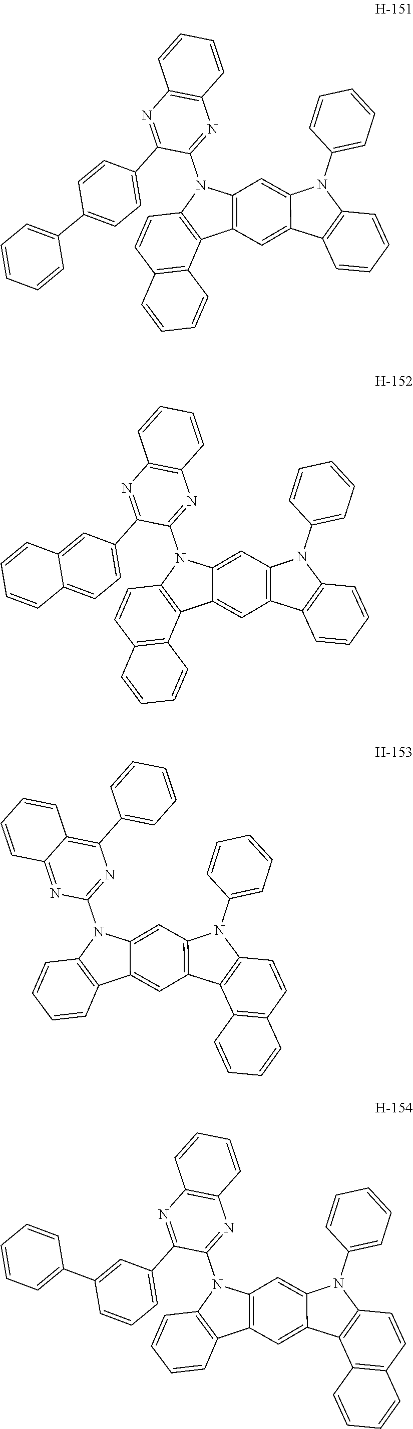 [SMILES: c1ccc(-c2ccc(-c3nc4ccccc4nc3-n3c4cc5c(cc4c4c6ccccc6ccc43)c3ccccc3n5-c3ccccc3)cc2)cc1 ; c1ccc(-n2c3ccccc3c3cc4c5c6ccccc6ccc5n(-c5nc6ccccc6nc5-c5ccc6ccccc6c5)c4cc32)cc1 ; c1ccc(-c2nc(-n3c4ccccc4c4cc5c6c7ccccc7ccc6n(-c6ccccc6)c5cc43)nc3ccccc23)cc1 ; c1ccc(-c2cccc(-c3nc4ccccc4nc3-n3c4ccccc4c4cc5c6c7ccccc7ccc6n(-c6ccccc6)c5cc43)c2)cc1]

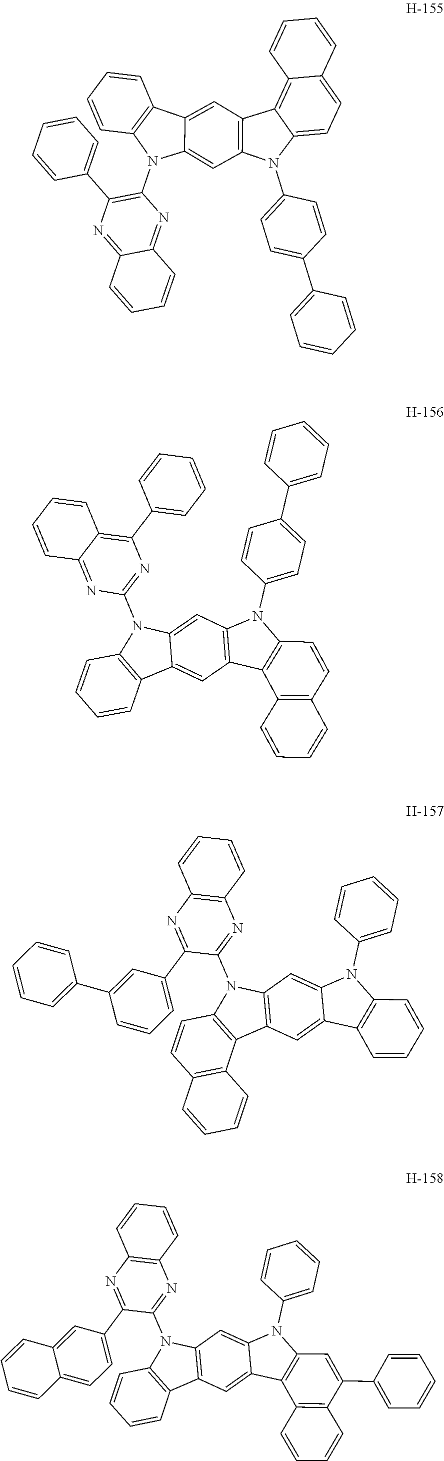 [SMILES: c1ccc(-c2ccc(-n3c4cc5c(cc4c4c6ccccc6ccc43)c3ccccc3n5-c3nc4ccccc4nc3-c3ccccc3)cc2)cc1 ; c1ccc(-c2ccc(-n3c4cc5c(cc4c4c6ccccc6ccc43)c3ccccc3n5-c3nc(-c4ccccc4)c4ccccc4n3)cc2)cc1 ; c1ccc(-c2cccc(-c3nc4ccccc4nc3-n3c4cc5c(cc4c4c6ccccc6ccc43)c3ccccc3n5-c3ccccc3)c2)cc1 ; c1ccc(-c2cc3c(c4ccccc24)c2cc4c5ccccc5n(-c5nc6ccccc6nc5-c5ccc6ccccc6c5)c4cc2n3-c2ccccc2)cc1]

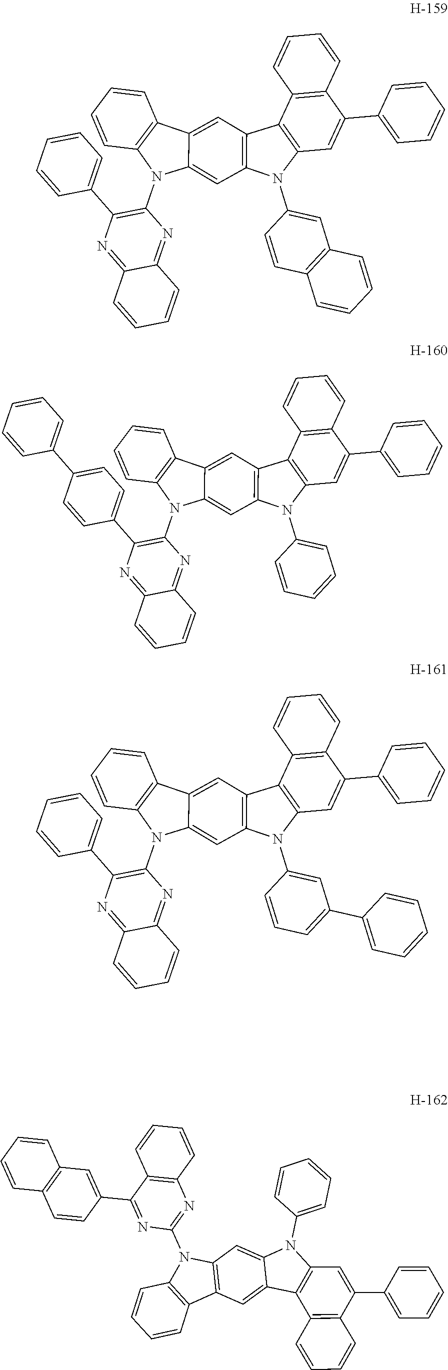 [SMILES: c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1 ; c1ccc(-c2cccc(-n3c4cc5c(cc4c4c6ccccc6c(-c6ccccc6)cc43)c3ccccc3n5-c3nc4ccccc4nc3-c3ccccc3)c2)cc1 ; c1ccc(-c2cc3c(c4ccccc24)c2cc4c5ccccc5n(-c5nc(-c6ccc7ccccc7c6)c6ccccc6n5)c4cc2n3-c2ccccc2)cc1]

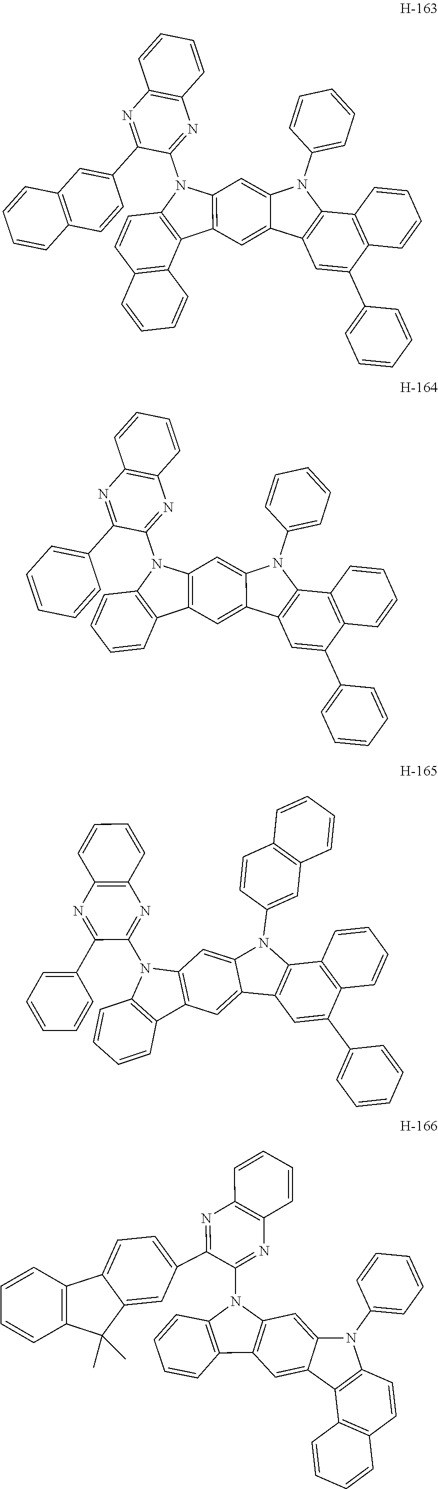 [SMILES: c1ccc(-c2cc3c4cc5c6c7ccccc7ccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1 ; c1ccc(-c2nc3ccccc3nc2-n2c3ccccc3c3cc4c5cc(-c6ccccc6)c6ccccc6c5n(-c5ccc6ccccc6c5)c4cc32)cc1 ; CC1(C)c2ccccc2-c2ccc(-c3nc4ccccc4nc3-n3c4ccccc4c4cc5c6c7ccccc7ccc6n(-c6ccccc6)c5cc43)cc21]

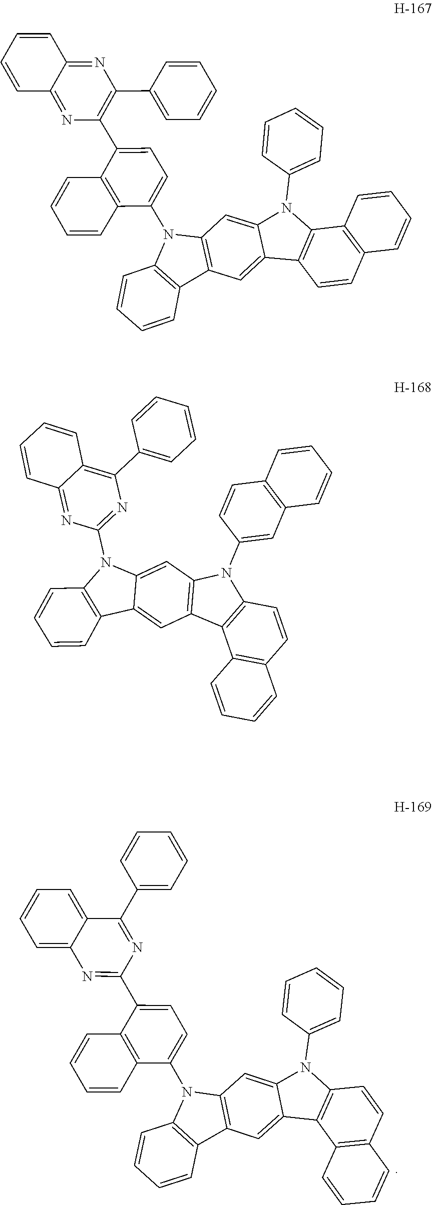 [SMILES: c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc(-n3c4ccccc4c4cc5c6c7ccccc7ccc6n(-c6ccc7ccccc7c6)c5cc43)nc3ccccc23)cc1 ; c1ccc(-c2nc(-c3ccc(-n4c5ccccc5c5cc6c7c8ccccc8ccc7n(-c7ccccc7)c6cc54)c4ccccc34)nc3ccccc23)cc1]

10. The organic electroluminescent device according to claim 1, wherein the arylamine derivative is at least one selected from the following compounds: 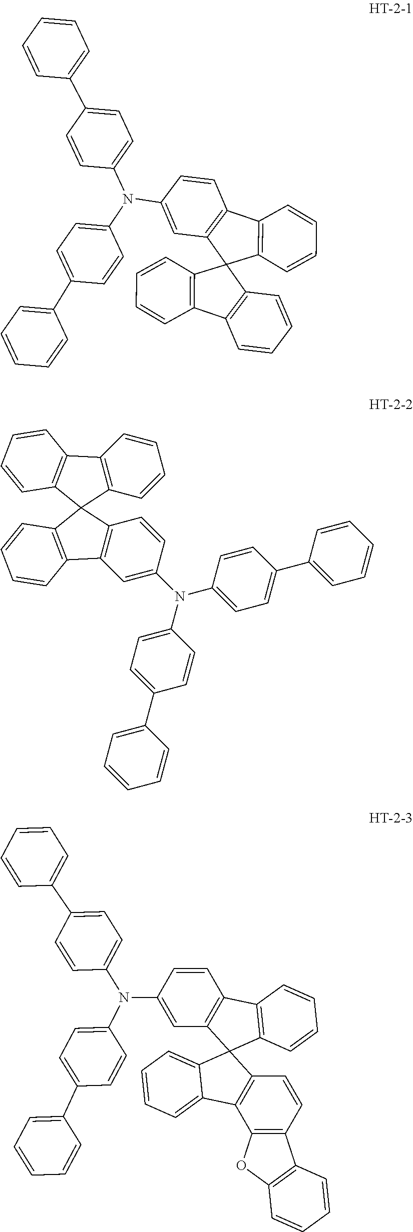 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; c1ccc(-c2ccc(N(c3ccc(-c4ccccc4)cc3)c3ccc4c(c3)C3(c5ccccc5-4)c4ccccc4-c4c3ccc3c4oc4ccccc43)cc2)cc1] 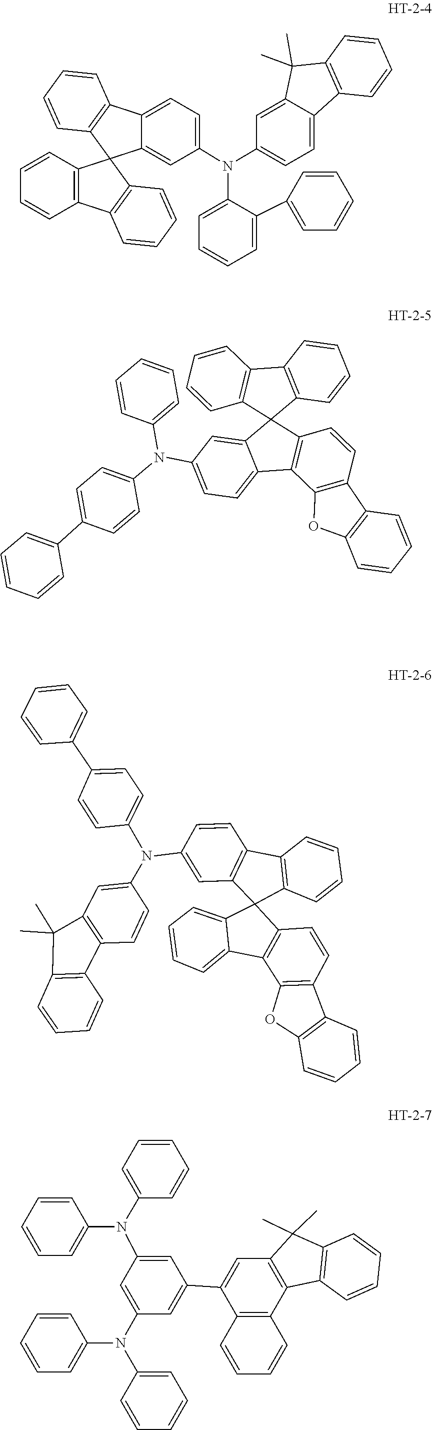 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccccc3)c3ccc4c(c3)C3(c5ccccc5-c5ccccc53)c3ccc5c(oc6ccccc65)c3-4)cc2)cc1 ; CC1(C)c2ccccc2-c2ccc(N(c3ccc(-c4ccccc4)cc3)c3ccc4c(c3)C3(c5ccccc5-4)c4ccccc4-c4c3ccc3c4oc4ccccc43)cc21 ; CC1(C)c2ccccc2-c2c1cc(-c1cc(N(c3ccccc3)c3ccccc3)cc(N(c3ccccc3)c3ccccc3)c1)c1ccccc21] 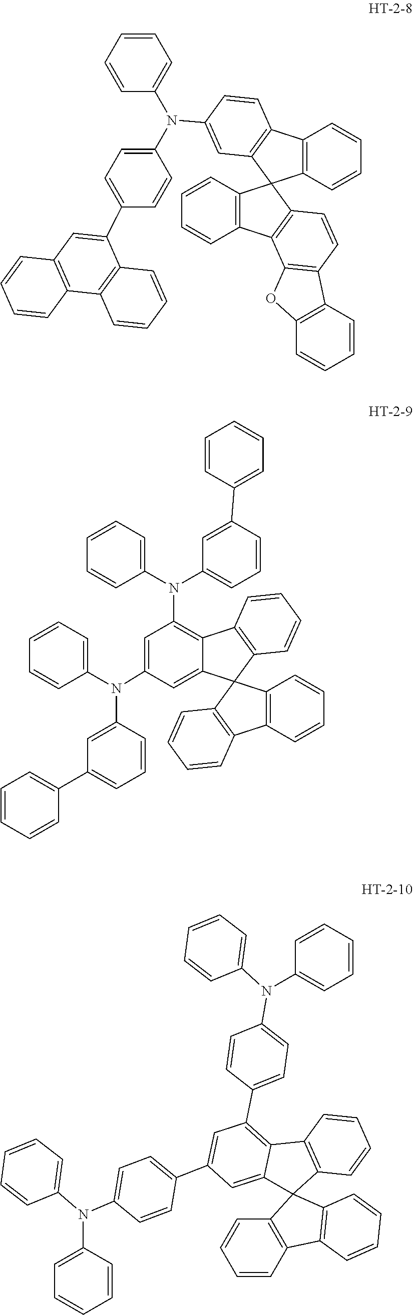 [SMILES: c1ccc(N(c2ccc(-c3cc4ccccc4c4ccccc34)cc2)c2ccc3c(c2)C2(c4ccccc4-3)c3ccccc3-c3c2ccc2c3oc3ccccc32)cc1 ; c1ccc(-c2cccc(N(c3ccccc3)c3cc(N(c4ccccc4)c4cccc(-c5ccccc5)c4)c4c(c3)C3(c5ccccc5-c5ccccc53)c3ccccc3-4)c2)cc1 ; c1ccc(N(c2ccccc2)c2ccc(-c3cc(-c4ccc(N(c5ccccc5)c5ccccc5)cc4)c4c(c3)C3(c5ccccc5-c5ccccc53)c3ccccc3-4)cc2)cc1] 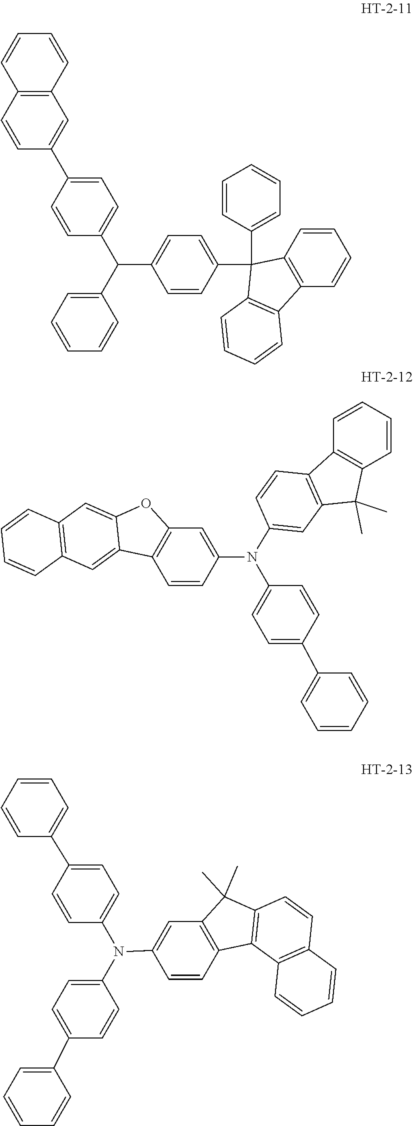 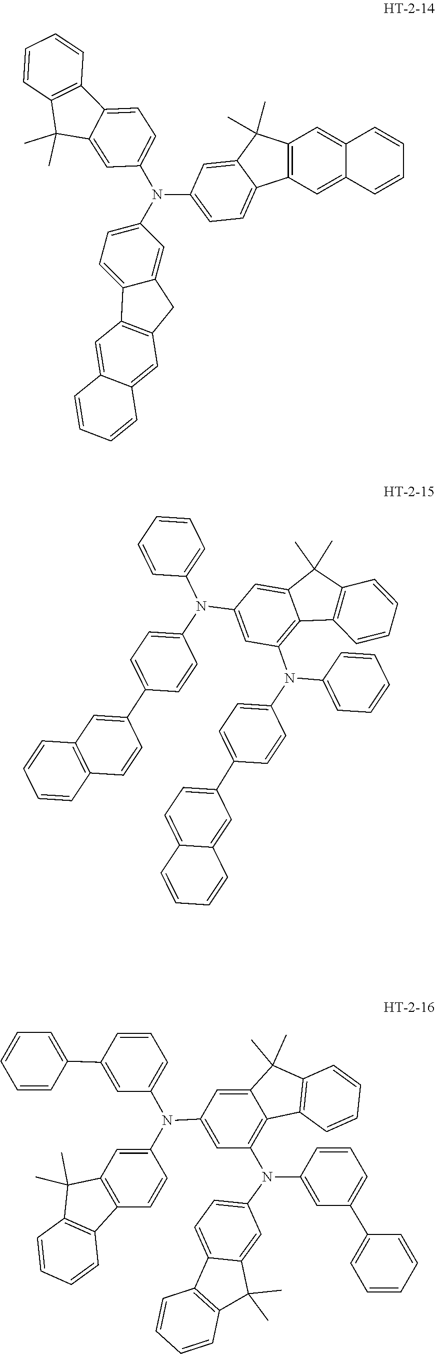 [SMILES: CC1(C)c2ccccc2-c2ccc(N(c3ccc4c(c3)Cc3cc5ccccc5cc3-4)c3ccc4c(c3)C(C)(C)c3cc5ccccc5cc3-4)cc21 ; CC1(C)c2ccccc2-c2c(N(c3ccccc3)c3ccc(-c4ccc5ccccc5c4)cc3)cc(N(c3ccccc3)c3ccc(-c4ccc5ccccc5c4)cc3)cc21 ; CC1(C)c2ccccc2-c2ccc(N(c3cccc(-c4ccccc4)c3)c3cc(N(c4cccc(-c5ccccc5)c4)c4ccc5c(c4)C(C)(C)c4ccccc4-5)c4c(c3)C(C)(C)c3ccccc3-4)cc21] 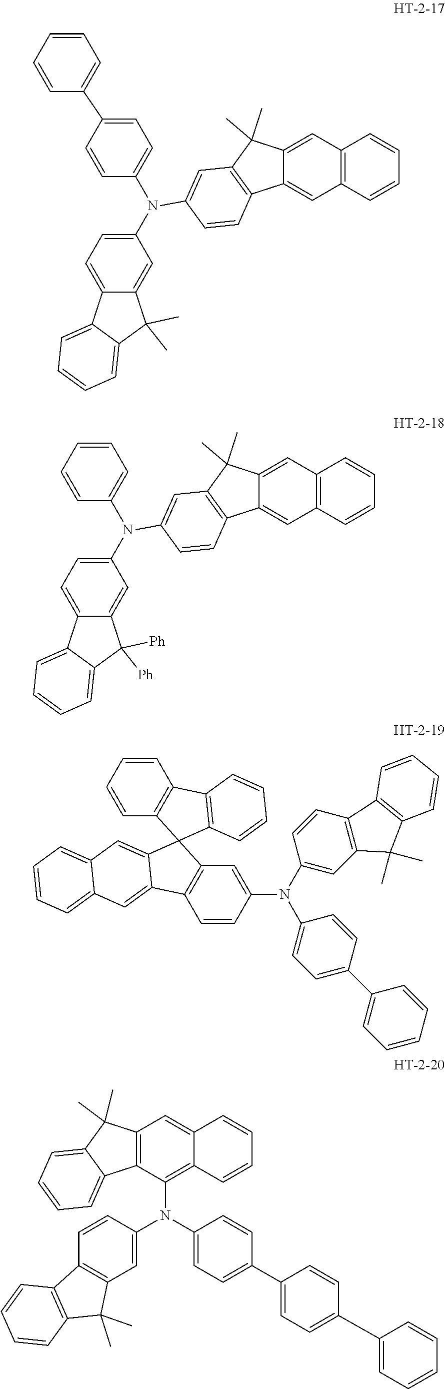 [SMILES: CC1(C)c2ccccc2-c2ccc(N(c3ccc(-c4ccccc4)cc3)c3ccc4c(c3)C(C)(C)c3cc5ccccc5cc3-4)cc21 ; CC1(C)c2cc(N(c3ccccc3)c3ccc4c(c3)C(c3ccccc3)(c3ccccc3)c3ccccc3-4)ccc2-c2cc3ccccc3cc21 ; CC1(C)c2ccccc2-c2ccc(N(c3ccc(-c4ccccc4)cc3)c3ccc4c(c3)C3(c5ccccc5-c5ccccc53)c3cc5ccccc5cc3-4)cc21 ; CC1(C)c2ccccc2-c2ccc(N(c3ccc(-c4ccc(-c5ccccc5)cc4)cc3)c3c4c(cc5ccccc35)C(C)(C)c3ccccc3-4)cc21] 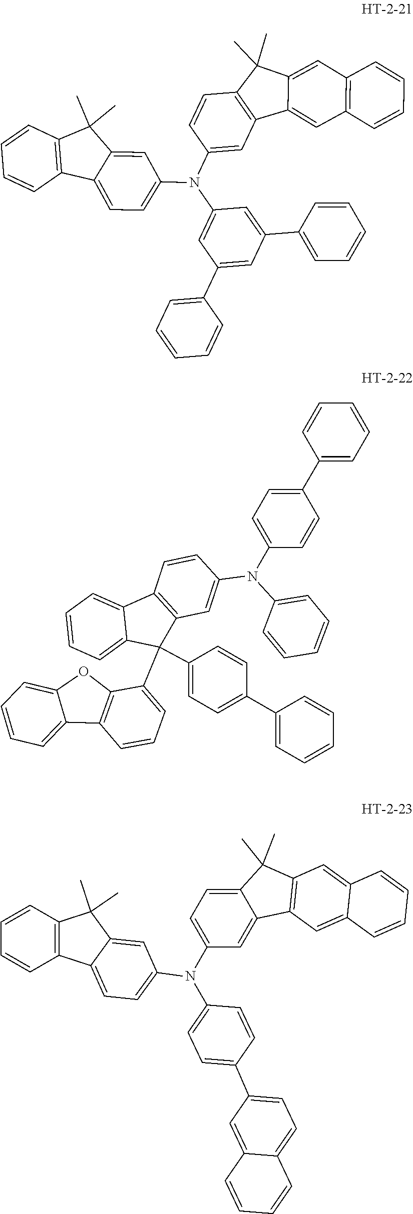 [SMILES: CC1(C)c2ccccc2-c2ccc(N(c3cc(-c4ccccc4)cc(-c4ccccc4)c3)c3ccc4c(c3)-c3cc5ccccc5cc3C4(C)C)cc21 ; c1ccc(-c2ccc(N(c3ccccc3)c3ccc4c(c3)C(c3ccc(-c5ccccc5)cc3)(c3cccc5c3oc3ccccc35)c3ccccc3-4)cc2)cc1 ; CC1(C)c2ccccc2-c2ccc(N(c3ccc(-c4ccc5ccccc5c4)cc3)c3ccc4c(c3)-c3cc5ccccc5cc3C4(C)C)cc21] 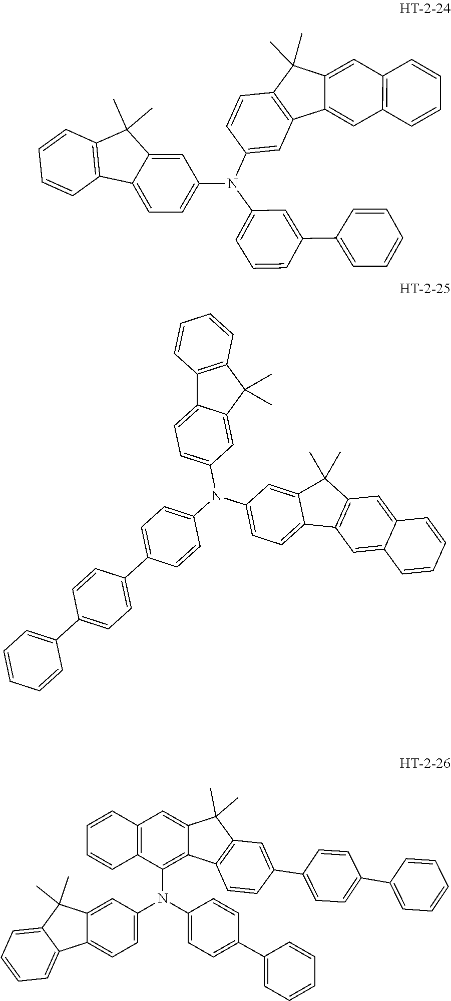 [SMILES: CC1(C)c2ccccc2-c2ccc(N(c3cccc(-c4ccccc4)c3)c3ccc4c(c3)-c3cc5ccccc5cc3C4(C)C)cc21 ; CC1(C)c2ccccc2-c2ccc(N(c3ccc(-c4ccc(-c5ccccc5)cc4)cc3)c3ccc4c(c3)C(C)(C)c3cc5ccccc5cc3-4)cc21 ; CC1(C)c2ccccc2-c2ccc(N(c3ccc(-c4ccccc4)cc3)c3c4c(cc5ccccc35)C(C)(C)c3cc(-c5ccc(-c6ccccc6)cc5)ccc3-4)cc21] 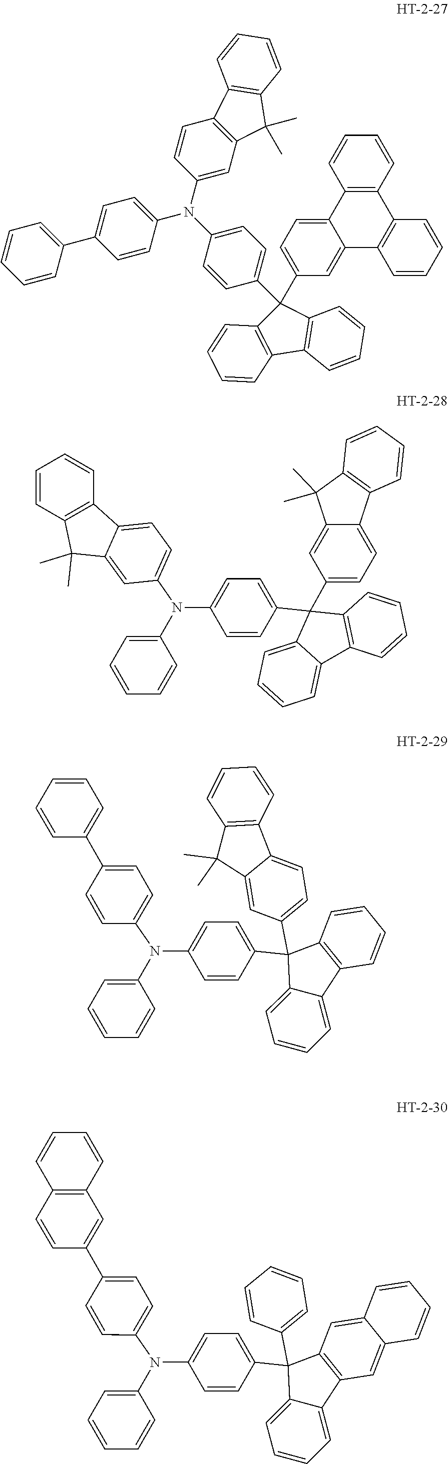 [SMILES: CC1(C)c2ccccc2-c2ccc(N(c3ccc(-c4ccccc4)cc3)c3ccc(C4(c5ccc6c7ccccc7c7ccccc7c6c5)c5ccccc5-c5ccccc54)cc3)cc21 ; CC1(C)c2ccccc2-c2ccc(N(c3ccccc3)c3ccc(C4(c5ccc6c(c5)C(C)(C)c5ccccc5-6)c5ccccc5-c5ccccc54)cc3)cc21 ; CC1(C)c2ccccc2-c2ccc(C3(c4ccc(N(c5ccccc5)c5ccc(-c6ccccc6)cc5)cc4)c4ccccc4-c4ccccc43)cc21 ; c1ccc(N(c2ccc(-c3ccc4ccccc4c3)cc2)c2ccc(C3(c4ccccc4)c4ccccc4-c4cc5ccccc5cc43)cc2)cc1] 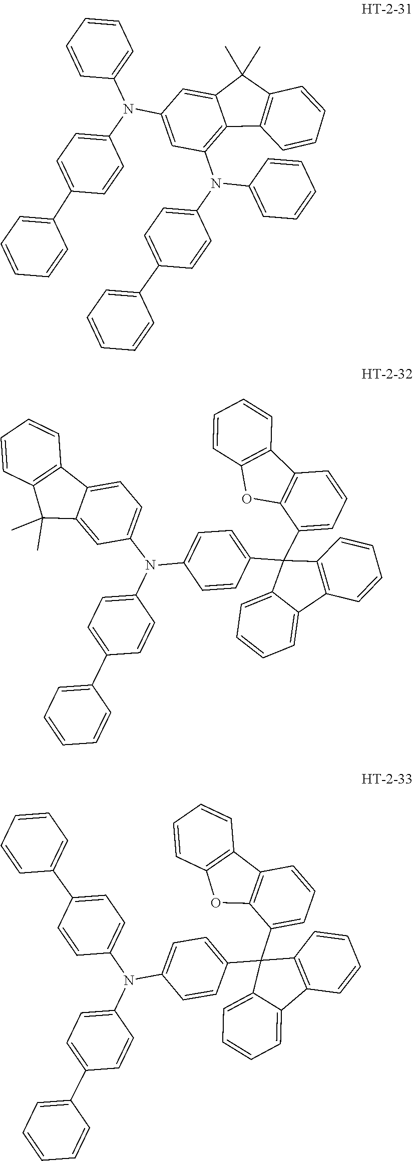 [SMILES: CC1(C)c2ccccc2-c2c(N(c3ccccc3)c3ccc(-c4ccccc4)cc3)cc(N(c3ccccc3)c3ccc(-c4ccccc4)cc3)cc21 ; CC1(C)c2ccccc2-c2ccc(N(c3ccc(-c4ccccc4)cc3)c3ccc(C4(c5cccc6c5oc5ccccc56)c5ccccc5-c5ccccc54)cc3)cc21 ; c1ccc(-c2ccc(N(c3ccc(-c4ccccc4)cc3)c3ccc(C4(c5cccc6c5oc5ccccc56)c5ccccc5-c5ccccc54)cc3)cc2)cc1] 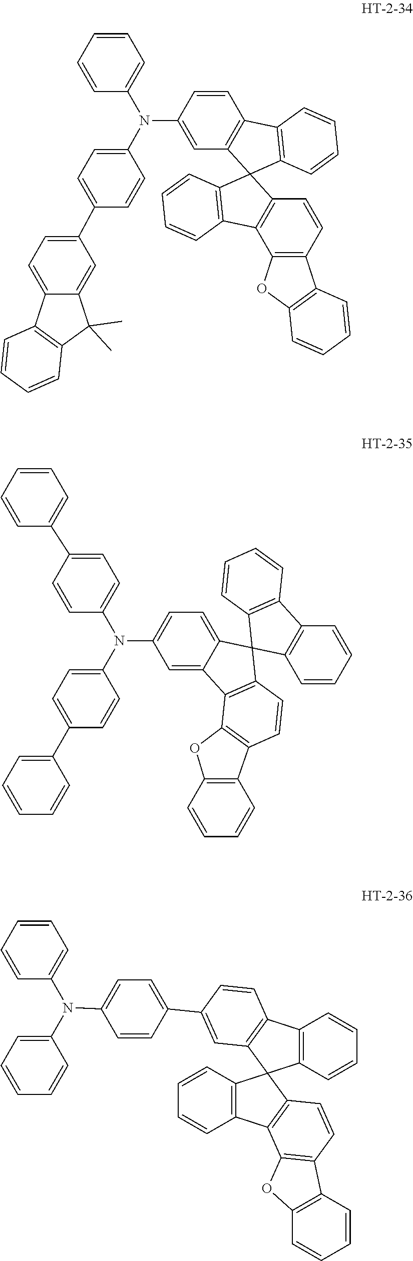 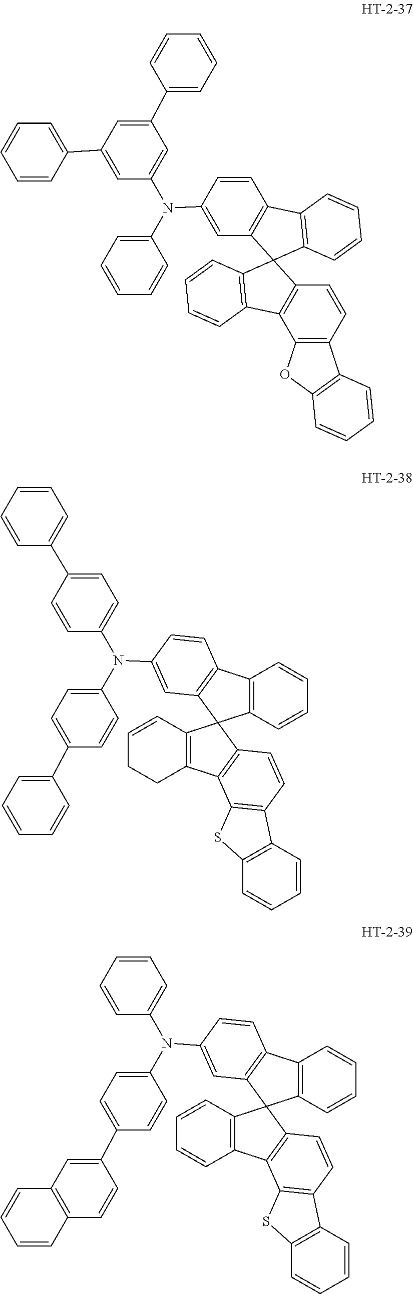 [SMILES: c1ccc(-c2cc(-c3ccccc3)cc(N(c3ccccc3)c3ccc4c(c3)C3(c5ccccc5-4)c4ccccc4-c4c3ccc3c4oc4ccccc43)c2)cc1 ; C1=CC2=C(CC1)c1c(ccc3c1sc1ccccc13)C21c2ccccc2-c2ccc(N(c3ccc(-c4ccccc4)cc3)c3ccc(-c4ccccc4)cc3)cc21 ; c1ccc(N(c2ccc(-c3ccc4ccccc4c3)cc2)c2ccc3c(c2)C2(c4ccccc4-3)c3ccccc3-c3c2ccc2c3sc3ccccc32)cc1] 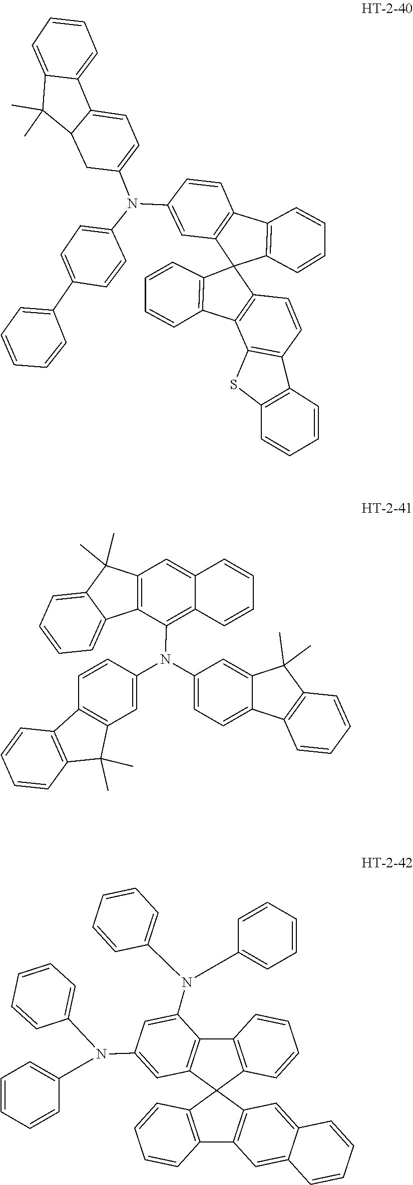 [SMILES: CC1(C)c2ccccc2C2=CC=C(N(c3ccc(-c4ccccc4)cc3)c3ccc4c(c3)C3(c5ccccc5-4)c4ccccc4-c4c3ccc3c4sc4ccccc43)CC21 ; CC1(C)c2ccccc2-c2ccc(N(c3ccc4c(c3)C(C)(C)c3ccccc3-4)c3c4c(cc5ccccc35)C(C)(C)c3ccccc3-4)cc21 ; c1ccc(N(c2ccccc2)c2cc(N(c3ccccc3)c3ccccc3)c3c(c2)C2(c4ccccc4-c4cc5ccccc5cc42)c2ccccc2-3)cc1] 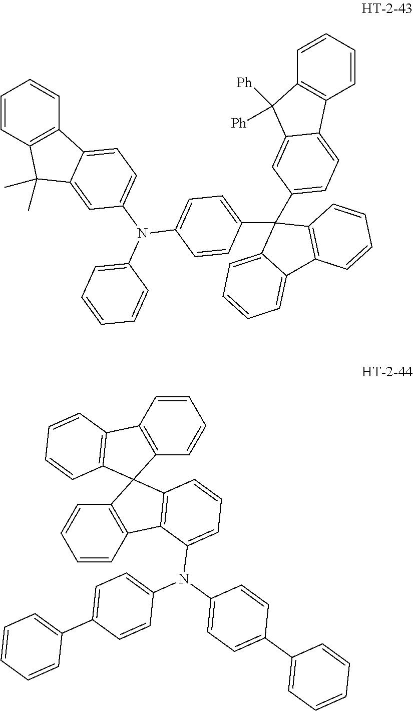 [SMILES: CC1(C)c2ccccc2-c2ccc(N(c3ccccc3)c3ccc(C4(c5ccc6c(c5)C(c5ccccc5)(c5ccccc5)c5ccccc5-6)c5ccccc5-c5ccccc54)cc3)cc21 ; c1ccc(-c2ccc(N(c3ccc(-c4ccccc4)cc3)c3cccc4c3-c3ccccc3C43c4ccccc4-c4ccccc43)cc2)cc1] 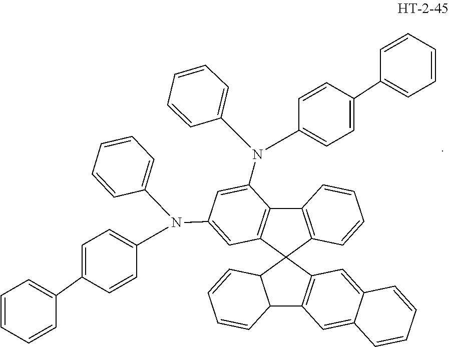 [SMILES: C1=CC2c3cc4ccccc4cc3C3(c4ccccc4-c4c(N(c5ccccc5)c5ccc(-c6ccccc6)cc5)cc(N(c5ccccc5)c5ccc(-c6ccccc6)cc5)cc43)C2C=C1]
